(19) United States
(12) Patent Application Publication
(10) Pub. No.: US 2023/0384485 A1
(43) Pub. Date: Nov. 30, 2023

(54) COLORING COMPOSITION, CURED FILM, LIGHT SHIELDING FILM, COLOR FILTER, OPTICAL ELEMENT, SOLID-STATE IMAGING ELEMENT, INFRARED SENSOR, AND HEADLIGHT UNIT

(71) Applicant: FUJIFILM Corporation, Tokyo (JP)

(72) Inventors: Norifumi YOKOYAMA, Shizuoka (JP); Kyohei ARAYAMA, Shizuoka (JP); Takahiro OYA, Shizuoka (JP)

(73) Assignee: FUJIFILM Corporation, Tokyo (JP)

(21) Appl. No.: 18/450,368

(22) Filed: Aug. 15, 2023

Related U.S. Application Data
(63) Continuation of application No. PCT/JP2022/001750, filed on Jan. 19, 2022.

(30) Foreign Application Priority Data
Feb. 19, 2021 (JP) 2021-025055

(51) Int. Cl. G02B 1/111; C08K 3/28; G02B 5/20; C08F 20/16; G02B 1/12

(52) U.S. Cl. CPC G02B 1/111; C08K 3/28; G02B 5/208; C08F 20/16; G02B 1/12

(57) ABSTRACT

There are provided a coloring composition, which makes it possible to form a cured film having a high color value and excellent adhesiveness to a base material, and provided a cured film, a light shielding film, a color filter, an optical element, a solid-state imaging element, an infrared sensor, and a headlight unit. The coloring composition according to the present invention contains a pigment, a solvent, and a resin having a constitutional unit A having a polymerizable group, a constitutional unit B having a phenolic hydroxyl group, and a constitutional unit C having an acidic group, where a content of the pigment is 15% by mass or more with respect to a total solid content.

### CROSS-REFERENCE TO RELATED APPLICATIONS

This application is a Continuation of PCT International Application No. PCT/JP2022/001750 filed on Jan. 19, 2022, which claims priority under 35 U.S.C. § 119(a) to Japanese Patent Application No. 2021-025055 filed on Feb. 19, 2021. The above applications are hereby expressly incorporated by reference, in their entirety, into the present application.

### BACKGROUND OF THE INVENTION

### 1. Field of the Invention

The present invention relates to a coloring composition, a cured film, a light shielding film, a color filter, an optical element, a solid-state imaging element, an infrared sensor, and a headlight unit.

### 2. Description of the Related Art

A colored film called a is provided in a color filter that is used in a liquid crystal display device for the intended purpose of, for example, shielding light between colored pixels to enhance contrast.

In addition, currently, a compact and thin imaging unit is mounted on a mobile terminal of electronic apparatus such as a mobile phone and a personal digital assistant (PDA). A light shielding film is provided in a solid-state imaging element such as a charge coupled device (CCD) image sensor and a complementary metal-oxide semiconductor (CMOS) image sensor for the intended purpose of, for example, preventing the generation of noise and improving image quality.

For example, JP1998-254133A (JP-H10-254133A) discloses a radiation-sensitive coloring composition containing a copolymer consisting of a predetermined monomer, a radiation-sensitive compound, and a pigment.

### SUMMARY OF THE INVENTION

As a result of studying the coloring composition (the radiation-sensitive coloring composition) disclosed in JP1998-254133A (JP-H10-254133A), the inventors of the present invention confirmed that in a cured film formed from the coloring composition, it is difficult to achieve both a high color value (a high color depth) and the adhesiveness to a base material.

Therefore, an object of the present invention is to provide a coloring composition that makes it possible to form a cured film having a high color value and excellent adhesiveness to a base material. In addition, another object thereof is to provide a cured film formed from the photosensitive composition, a light shielding film, a color filter, an optical element, a solid-state imaging element, an infrared sensor, and a headlight unit.

As a result of carrying out extensive investigations, the inventors of the present invention have found that the above objects can be achieved by the following configuration and have completed the present invention.

[1] A coloring composition comprising:
a pigment;
a solvent; and
a resin having a constitutional unit A having a polymerizable group, a constitutional unit B having a phenolic hydroxyl group, and a constitutional unit C having an acidic group,
in which a content of the pigment is 15% by mass or more with respect to a total solid content of the coloring composition.

[2] The coloring composition according to [1], in which the constitutional unit A is a constitutional unit represented by Formula 1,

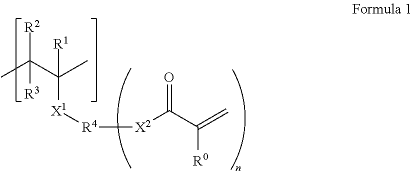

in Formula 1, R¹ to R³ each independently represent a hydrogen atom or an alkyl group,
X¹ represents —COO—, —CONR—, or an arylene group,
R represents a hydrogen atom, an alkyl group, or an aryl group,
R⁴ represents an (n+1)-valent linking group,
X² represents an oxygen atom or —NR^{A}—,
R^{A} represents a hydrogen atom, an alkyl group, or an aryl group,
R⁰ represents a hydrogen atom or an alkyl group, and
n represents an integer of 1 or more.

[3] The coloring composition according to [1] or [2], in which the constitutional unit B is a constitutional unit represented by Formula 2,

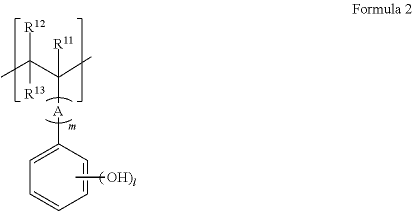

in Formula 2, R¹¹ to R¹³ each independently represent a hydrogen atom or an alkyl group,
A represents —COO—, —CONR′—, —COO—R″—, —CONR′—R″—, or an arylene group,
R′ represents a hydrogen atom, an alkyl group, or an aryl group,
R″ represents a divalent linking group,
m represents 0 or 1, and
l represents an integer of 1 to 5.

[4] The coloring composition according to any one of [1] to [3], in which the constitutional unit A includes a constitutional unit represented by Formula 3,

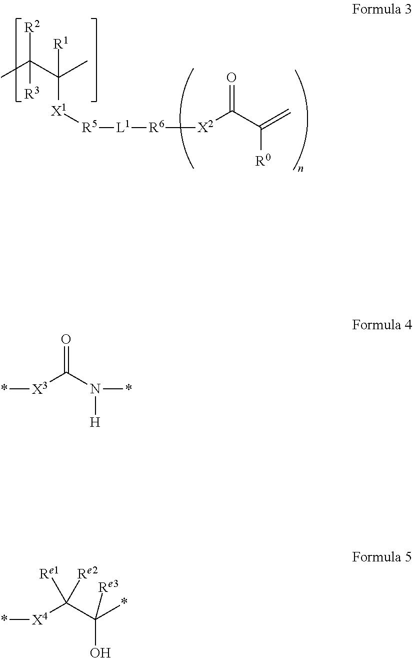

in Formula 3, R¹ to R³ each independently represent a hydrogen atom or an alkyl group,
X¹ represents —COO—, —CONR—, or an arylene group, where R represents a hydrogen atom, an alkyl group, or an aryl group,
R⁵ represents a divalent linking group,
L¹ represents a group represented by Formula 4 or Formula 5,
R⁶ represents an (n+1)-valent linking group,
X² represents an oxygen atom or —NR^{A}—,
R^{A} represents a hydrogen atom, an alkyl group, or an aryl group,
R⁰ represents a hydrogen atom or an alkyl group, and
n represents an integer of 1 or more,
in Formula 4, X³ represents an oxygen atom or —NH—, and
* represents a bonding position,
in Formula 5, X⁴ represents an oxygen atom or —COO—,
R^{e1} to R^{e3} each independently represent a hydrogen atom or an alkyl group,
at least two of R^{e1} to R^{e3} may be bonded to each other to form a ring, and
* represents a bonding position.

[5] The coloring composition according to any one of [1] to [4], in which the constitutional unit A includes a constitutional unit represented by Formula 6,

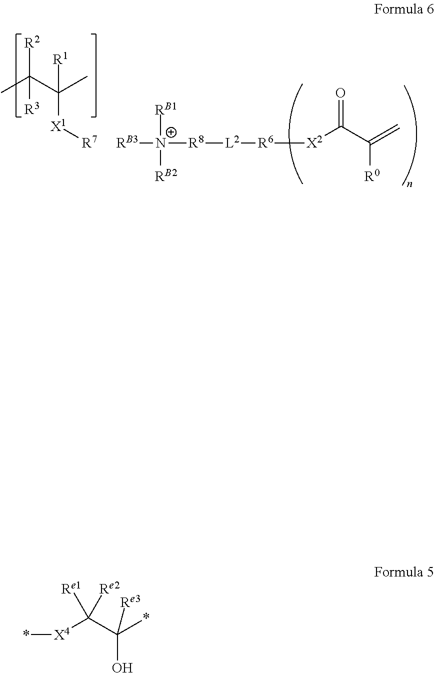

in Formula 6, R¹ to R³ each independently represent a hydrogen atom or an alkyl group,
X¹ represents —COO—, —CONR—, or an arylene group,
R represents a hydrogen atom, an alkyl group, or an aryl group,
R⁷ represents a structure including a group in which one proton is dissociated from an acid group,
R¹ represents a divalent linking group,
L² represents a group represented by Formula 5,
R⁶ represents an (n+1)-valent linking group,
X² represents an oxygen atom or —NR^{A}—,
R^{A} represents a hydrogen atom, an alkyl group, or an aryl group,
n represents an integer of 1 or more,
R^{B1} to R^{B3} each independently represent a hydrogen atom, an alkyl group, or an aryl group, and
R⁰ represents a hydrogen atom or an alkyl group,
in Formula 5, X⁴ represents an oxygen atom or —COO—,
R^{e1} to R^{e3} each independently represent a hydrogen atom or an alkyl group, and
at least two of R^{e1} to R^{e3} may be bonded to each other to form a ring.

[6] The coloring composition according to [5], in which in the constitutional unit A, a content of the constitutional unit represented by Formula 6 is 10 mol % or more.

[7] The coloring composition according to any one of [1] to [6], in which the constitutional unit B is a constitutional unit represented by Formula 7,

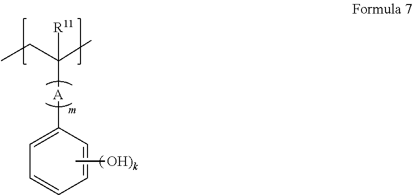

in Formula 7, R″ represents a hydrogen atom or an alkyl group,
A represents —COO—, —CONR′—, —COO—R″—, —CONR′—R″—, or an arylene group,
R′ represents a hydrogen atom, an alkyl group, or an aryl group,
R″ represents a divalent linking group,
m represents 0 or 1, and
k represents an integer of 1 to 3.

[8] The coloring composition according to any one of [1] to [7], in which the constitutional unit B is one or more selected from the group consisting of a constitutional unit represented by Formula 8, a constitutional unit represented by Formula 9, and a constitutional unit represented by Formula 10

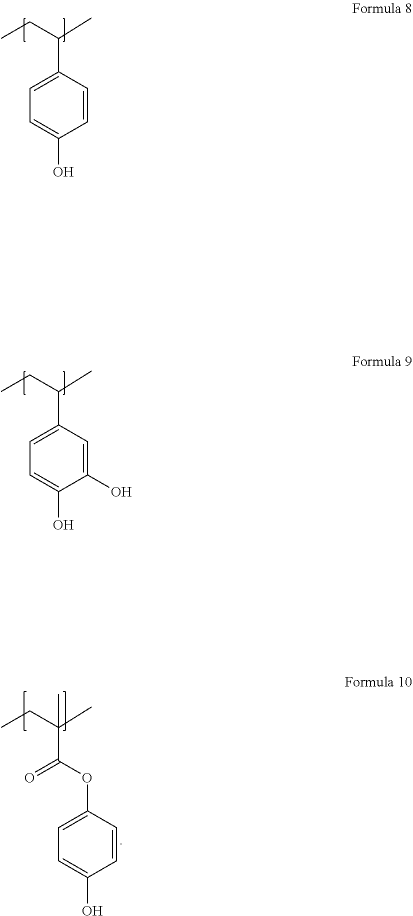

[9] The coloring composition according to any one of [1] to [8], in which the pigment includes one or more selected from the group consisting of carbon black, titanium black, zirconium nitride, and zirconium oxynitride.

[10] The coloring composition according to any one of [1] to [9], in which the resin further has a constitutional unit D represented by Formula D,

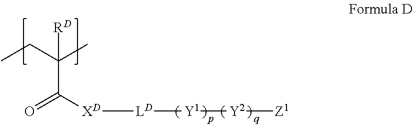

in Formula D, R^{D} represents a hydrogen atom or an alkyl group,
X^{D} represents an oxygen atom or —NR^{C}—,
R^{C} represents a hydrogen atom, an alkyl group, or an aryl group,
L^{D} represents a single bond or a divalent linking group,
Y¹ and Y² each independently represent an alkyleneoxy group or an alkylenecarbonyloxy group,
Z¹ represents an aliphatic hydrocarbon group having 1 to 20 carbon atoms or an aromatic hydrocarbon group having 6 to 20 carbon atoms, and
p and q each independently represent an integer of 0 or more,
provided that a value of p+q is 1 or more.

[11] A cured film that is formed from the coloring composition according to any one of [1] to [10].

[12] A light shielding film comprising:
the cured film according to [11].

[13] A color filter comprising:
the cured film according to [11].

[14] An optical element comprising:
the cured film according to [11].

[15] A solid-state imaging element comprising:
the cured film according to [11].

[16] An infrared sensor comprising:
the cured film according to [11].

[17] A headlight unit for a vehicle, comprising:
a light source; and
a light shielding unit that shields at least a part of light emitted from the light source,
in which the light shielding unit includes the cured film according to [11].

According to the present invention, it is possible to provide a coloring composition that makes it possible to form a cured film having a high color value and excellent adhesiveness to a base material. In addition, the present invention can also provide a cured film formed from the coloring composition, a light shielding film, a color filter, an optical element, a solid-state imaging element, an infrared sensor, and a headlight unit.

### BRIEF DESCRIPTION OF THE DRAWINGS

FIG. 1 is a schematic cross-sectional view illustrating an example of a configuration of a solid-state imaging device.

FIG. 2 is a schematic cross-sectional view illustrating an imaging unit included in the solid-state imaging device illustrated in FIG. 1 in an enlarged manner.

FIG. 3 is a schematic cross-sectional view illustrating an example of a configuration of an infrared sensor.

FIG. 4 is a schematic view illustrating an example of a configuration of a headlight unit.

FIG. 5 is a schematic perspective view illustrating an example of a configuration of a light shielding unit of the headlight unit.

FIG. 6 is a schematic view illustrating an example of a light distribution pattern formed by the light shielding unit of the headlight unit.

FIG. 7 is a schematic view illustrating another example of the light distribution pattern formed by the light shielding unit of the headlight unit.

### DESCRIPTION OF THE PREFERRED EMBODIMENTS

Hereinafter, the contents of the present specification will be described in detail. The following description of configuration requirements is based on representative embodiments of the present specification; however, the present specification is not limited thereto.

In the present specification, “to” indicating a numerical value range is used to mean that numerical values described before and after “to” are included as a lower limit value and an upper limit value, respectively.

In the numerical value ranges described stepwise in the present specification, the upper limit value or the lower limit value described in one numerical value range may be substituted with the upper limit value or the lower limit value of the numerical value range described stepwise in other stages. Furthermore, with regard to the numerical value ranges described in the present specification, the upper limit value or the lower limit value of the numerical value range may be substituted for the values disclosed in Examples.

In addition, in describing a group (an atomic group) in the present specification, the description which does not indicate substituted or unsubstituted includes not only a group having no substituent but also a group having a substituent. For example, the “alkyl group” includes not only an alkyl group having no substituent (an unsubstituted alkyl group) but also an alkyl group having a substituent (a substituted alkyl group).

In the present specification, “Me” indicates a methyl group, “Et” indicates an ethyl group, “Pr” indicates a propyl group, “Bu” indicates a butyl group, and “Ph” indicates a phenyl group, respectively, unless otherwise specified.

In the present specification, “(meth)acryl” is a term that is used in a concept including both acrylic and methacryl, and “(meth)acryloyl” is a term that is used in a concept including both acryloyl and methacryloyl.

In addition, in the present specification, the term “step” includes not only an independent step but also a step that cannot be clearly distinguished from other steps, as long as the intended purpose of the step is achieved.

In addition, in the present specification, a combination of two or more preferred aspects is a more preferred aspect.

In addition, in the present specification, the weight-average molecular weight (Mw) and the number-average molecular weight (Mn) are polystyrene-equivalent values that are measured under the following conditions unless otherwise specified.

“Apparatus: HLC-8220GPC (manufactured by Tosoh Corporation), detector: a differential refractometer (RI detector), pre-column TSK GUARD COLUMN MP (XL) 6 mm×40 mm (manufactured by Tosoh Corporation), sample side column: four columns of TSK-GEL Multipore-HXL-M 7.8 mm×300 mm, which are directly connected (all manufactured by Tosoh Corporation), reference side column: the same as the sample side column, constant-temperature tank temperature: 40° C., mobile phase: tetrahydrofuran, flow rate of sample side mobile phase: 1.0 mL/min, flow rate of reference side mobile phase: 0.3 mL/min, sample concentration: 0.1% by mass, sample injection amount: 100 μL, data collection time: 16 minutes to 46 minutes after sample injection, and sampling pitch: 300 msec”

In addition, “actinic rays” or “radiation” in the present specification means, for example, a bright line spectrum of a mercury lamp such as a g-line, an h-line, or an i-line, far ultraviolet rays typified by an excimer laser, extreme ultraviolet rays (EUV light, X-rays, electron beams (EB), or the like. In addition, in the present invention, light means actinic rays or radiation.

Further, unless otherwise specified, “exposure” in the present specification includes not only exposure by a mercury lamp, far ultraviolet rays typified by an excimer laser, extreme ultraviolet rays, X-rays, EUV light, or the like, but also the exposure includes drawing by particle beams such as electron beams and ion beams.

In the present specification, a “monomeric substance” and a “monomer” have the same definition.

In the present specification, “ppm” means “parts per million (10⁻⁶)”, “ppb” means “parts per billion (10⁻⁹)”, and “ppt” means “parts per trillion (10¹²)”.

A bonding direction of a divalent group described in the present specification is not limited unless otherwise specified. For example, in a case where Y is an ester group (—COO—) in a compound represented by the general formula of “X—Y—Z”, the compound may be “X—O—CO—Z” or “X—CO—O—Z”.

In the present specification, the “color value” means the color depth, and the high color value means that the OD value is high with respect to light in the entire wavelength range of 400 to 1,100 nm.

[Coloring Composition (Composition)]

The coloring composition according to the embodiment of the present invention (hereinafter, also simply referred to as a “composition”) contains a pigment, a solvent, and a resin (hereinafter, also referred to as a “specific resin”) having a constitutional unit A having a polymerizable group, a constitutional unit B having a phenolic hydroxyl group, and a constitutional unit C having an acidic group, and the content of the pigment is 15% by mass or more with respect to the total solid content of the composition.

It is noted that the “solid content” of the composition means components forming a cured film and means all components except a solvent in a case where the composition contains the solvent (an organic solvent, water, or the like). In addition, in a case where the components are components forming a cured film, the components are considered to be solid contents even in a case where the components are liquid components.

The mechanism by which the objects of the present invention are achieved with the composition having the constitution described above is not necessarily clear; however, the inventors of the present invention conceive as follows.

That is, in the composition according to the embodiment of the present invention, the content of the pigment is 15% by mass or more with respect to the total solid content of the composition, and thus the color value of the cured film to be formed is high.

In addition, the specific resin contained in the composition has a constitutional unit A having a polymerizable group and a constitutional unit B having a phenolic hydroxyl group. Since the constitutional unit A has a polymerizable group, the specific resins can be polymerized with each other, or the specific resin can be polymerized with a polymerizable compound that is added as desired, a network of covalent bonds can be formed in the cured film. In addition, the phenolic hydroxyl group of the constitutional unit B causes, in the cured film, hydrogen bonding due to the phenolic hydroxyl group, a stacking interaction between aromatic rings, and the like. The cured film formed from the composition according to the embodiment of the present invention has firm physical properties due to the synergistic contribution of such elements, and thus it is conceived that due to the firmness of the cured film, the cured film is hardly peeled off from the base material on which the cured film is formed, and the adhesiveness of the cured film is improved.

In addition, the composition according to the embodiment of the present invention also has a good development residue suppressibility.

Hereinafter, a case where at least one of the facts that the composition makes it possible to form a cured film having a higher color value, that the composition makes it possible to form a cured film having more excellent adhesiveness, or that the composition has excellent development residue suppressibility is satisfied is also referred to as that the effect of the present invention is more excellent.

Hereinafter, components contained in the composition according to the embodiment of the present invention will be described.

[Resin (Specific Resin)]

<Constitutional Unit A>

The composition according to the embodiment of the present invention contains a specific resin, and the specific resin has a constitutional unit A.

The constitutional unit A is a constitutional unit having a polymerizable group.

Examples of the polymerizable group include an ethylenically unsaturated group (a (meth)acryloyl group, a vinyl group, a styryl group, or the like), and a cyclic ether group (for example, an epoxy group or an oxetanyl group).

Among them, the polymerizable group is preferably an ethylenically unsaturated group and more preferably a (meth)acryloyl group.

The number of polymerizable groups contained in the constitutional unit A is 1 or more, preferably 1 to 6, and more preferably 1.

In the constitutional unit A, one kind of polymerizable group may be used alone, or two or more kinds thereof may be used.

The constitutional unit A is preferably a constitutional unit represented by Formula 1.

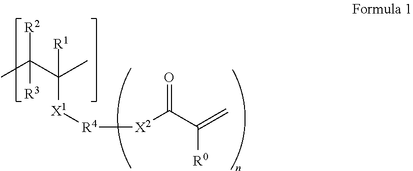

In Formula 1, R¹ to R³ each independently represent a hydrogen atom or an alkyl group.

The alkyl group may be linear or branched, and it preferably has 1 to 6 carbon atoms.

Among the above, R¹ is preferably a hydrogen atom or an alkyl group.

R² and R³ is preferably a hydrogen atom.

In Formula 1, X¹ represents —COO—, —CONR—, or an arylene group,

The arylene group may be monocyclic or polycyclic, and it preferably has 6 to 15 carbon atoms.

R in —CONR— represents a hydrogen atom, an alkyl group, or an aryl group.

The alkyl group, which can be represented by R of —CONR—, may be linear or branched, and it preferably has 1 to 6 carbon atoms.

The aryl group, which can be represented by R of —CONR—, may be monocyclic or polycyclic, and it preferably has 6 to 15 carbon atoms.

In Formula 1, R⁴ represents an (n+1)-valent linking group.

Examples of the linking group include an ether group, a carbonyl group, an ester group, a thioether, —SO₂—, —NR^{X}— (where R^{X} is a hydrogen atom or a substituent such as an alkyl group), an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), a trivalent group represented by “—N<”, a trivalent group represented by “—CR^{Y}<” (R^{Y} is a hydrogen atom or a substituent such as an alkyl group), a tetravalent group represented by “>C<”, an aromatic ring group (for example, an aromatic ring group having 5 to 15 ring member atoms), an alicyclic group (for example, an alicyclic group having 3 to 15 carbon atoms), a non-aromatic heterocyclic group (for example, a non-aromatic heterocyclic group having 3 to 15 ring member atoms), an onium structure-containing group, and groups obtained by combining these.

The onium structure-containing group is a group having an anionic moiety and a cationic moiety.

The anionic moiety preferably has a structure containing a group in which protons (for example, 1 to 3 protons) are dissociated from the acid group. Examples of the acid group include a carboxy group, a sulfonic acid group, a phosphonic acid group, and a phosphoric acid group.

Examples of the cationic moiety include an ammonium cation. In a case where the cationic moiety is an ammonium cation, the cationic moiety is a partial structure containing a cationic nitrogen atom (>N+<). The cationic moiety may have a partial structure represented by “N⁺R^{C}₃—”. R^{c}'s each independently represent a hydrogen atom or a substituent, and it is preferably a hydrogen atom, an alkyl group (for example, an alkyl group having 1 to 20 carbon atoms), or an aryl group (for example, an aryl group having 6 to 15 carbon atoms).

R⁴ is preferably a group having a total number of atoms of 1 to 200, more preferably a group having a total number of atoms of 2 to 100, and still more preferably a group having a total number of atoms of 2 to 60.

In Formula 1, X² represents an oxygen atom or —NR^{A}—. R^{A} represents a hydrogen atom, an alkyl group, or an aryl group.

The alkyl group may be linear or branched, and it preferably has 1 to 6 carbon atoms.

The aryl group may be monocyclic or polycyclic, and it preferably has 6 to 15 carbon atoms.

R⁰ represents a hydrogen atom or an alkyl group.

The alkyl group may be linear or branched, and it preferably has 1 to 6 carbon atoms.

In Formula 1, n represents an integer of 1 or more.
n is preferably an integer of 1 to 6 and more preferably 1.

The value of n specified in Formula 1 is the same as the value of n in the (n+1)-valent linking group represented by R⁴.

In a case where a plurality of X²'s are present in Formula 1, the plurality of X²'s are each independent, and they may be the same or different from each other.

In a case where a plurality of R⁰'s are present in Formula 1, the plurality of R⁰'s are each independent, and they may be the same or different from each other.

The constitutional unit A preferably includes a constitutional unit represented by Formula 3.

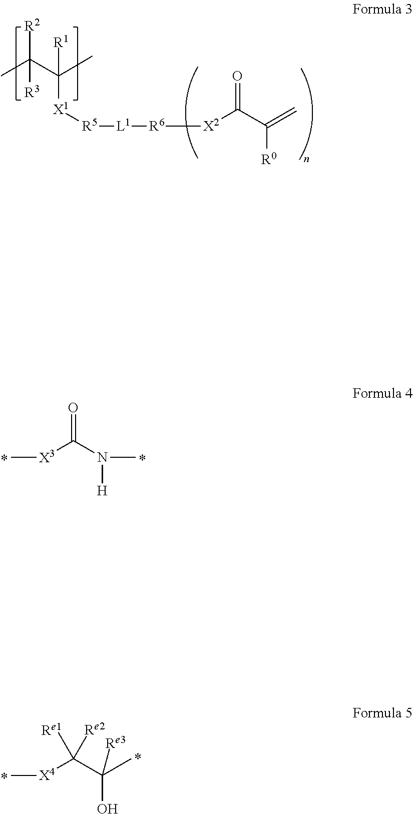

In Formula 3, R¹ to R³ each independently represent a hydrogen atom or an alkyl group.

In Formula 3, X¹ represents —COO—, —CONR—, or an arylene group, where R represents a hydrogen atom, an alkyl group, or an aryl group.

In Formula 3, X² represents an oxygen atom or —NR^{A}—. R^{A} represents a hydrogen atom, an alkyl group, or an aryl group.

In Formula 3, n represents an integer of 1 or more.

In Formula 3, R⁰ represents a hydrogen atom or an alkyl group.

R¹ to R³, X¹, X², R⁰, and n in Formula 3 are the same as R¹ to R³, X¹, X², R⁰, and n in Formula 1, respectively.

The value of n specified in Formula 3 is the same as the value of n in the (n+1)-valent linking group represented by R⁶ described later.

In a case where a plurality of X²'s are present in Formula 3, the plurality of X²'s are each independent, and they may be the same or different from each other.

In a case where a plurality of R⁰'s are present in Formula 3, the plurality of R⁰'s are each independent, and they may be the same or different from each other.

In Formula 3, R⁵ represents a divalent linking group.

Examples of the divalent linking group include an ether group, a carbonyl group, an ester group, a thioether group, —SO₂—, —NR^{X}— (where R^{X} is a hydrogen atom or a substituent such as an alkyl group), a divalent hydrocarbon group (for example, an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), an arylene group (for example, an arylene group having 6 to 15 carbon atoms), and an alicyclic group (for example, an alicyclic group having 3 to 15 carbon atoms)), a divalent heterocyclic group (for example, a divalent heterocyclic group having 3 to 15 ring member atoms), a heteroarylene group (for example, a heteroarylene group having 5 to 15 ring member atoms), and groups obtained by combining these.

In addition, examples of R⁵ include a divalent linking group among the (n+1)-valent linking groups represented by R⁴.

Among them, R⁵ is preferably a divalent hydrocarbon group or a group obtained by bonding one or more (for example, 2 to 10) divalent hydrocarbon groups to a total of one or more (for example, 2 to 10) groups selected from the group consisting of an ether group, a carbonyl group, and an ester group.

In addition, it is also preferable that R⁵ includes a group shown below, and it is also preferable that R⁵ is the group itself shown below. It is noted that in the group shown below, * represents a bonding position.

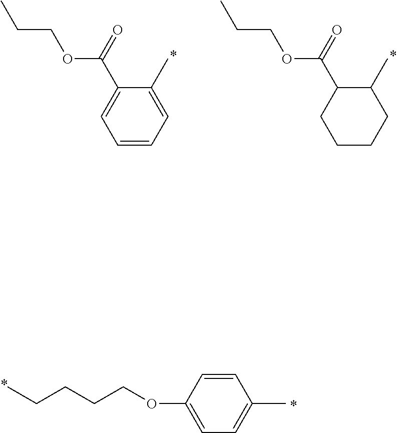

R⁵ is preferably a group having a total number of atoms of 2 to 60, more preferably a group having a total number of atoms of 2 to 50, and still more preferably a group having a total number of atoms of 2 to 40.

In Formula 3, L¹ represents a group represented by Formula 4 or Formula 5.

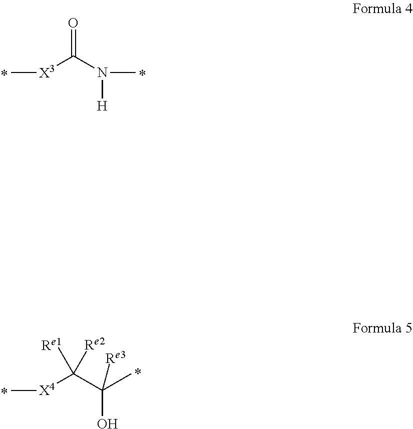

In Formula 4, X³ represents an oxygen atom or —NH—.

In Formula 4, * represents a bonding position.

In Formula 4, one of * on the left side or * on the right side is the bonding position with respect to R⁵, and the other is the bonding position with respect to R⁶.

In Formula 5, X⁴ represents an oxygen atom or —COO—.

In the above —COO—, it is preferable that the carbonyl carbon in —COO— is present on a side opposite to —C(R^{e1})(R^{e2})—.

In Formula 5, R^{e1} to R^{e3} each independently represent a hydrogen atom or an alkyl group. The alkyl group may be linear or branched, and it preferably has 1 to 6 carbon atoms.

At least two of R^{e1} to R^{e3} may be bonded to each other to form a ring. The ring may be monocyclic or polycyclic, and it preferably has 3 to 15 carbon atoms.

In Formula 5, * represents a bonding position.

In Formula 5, one of * on the left side or * on the right side is the bonding position with respect to R⁵, and the other is the bonding position with respect to R⁶.

In Formula 3, R⁶ represents an (n+1)-valent linking group.

Examples of the linking group include an ether group, a carbonyl group, an ester group, a thioether, —SO₂—, —NR^{X}— (where R^{X} is a hydrogen atom or a substituent such as an alkyl group), an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), a trivalent group represented by “—N<”, a trivalent group represented by “—CR^{Y}<” (R^{Y} is a hydrogen atom or a substituent such as an alkyl group), a tetravalent group represented by “>C<”, an aromatic ring group (for example, an aromatic ring group having 5 to 15 ring member atoms), an alicyclic group (for example, an alicyclic group having 3 to 15 carbon atoms), a non-aromatic heterocyclic group (for example, a non-aromatic heterocyclic group having 3 to 15 ring member atoms), and groups obtained by combining these.

Among them, R⁶ is preferably a divalent linking group, and it is preferably an alkylene group or a group obtained by bonding one or more (for example, 2 to 10) alkylene groups to a total of one or more (for example, 2 to 10) groups selected from the group consisting of an ether group, a carbonyl group, and an ester group.

R⁶ is preferably a group having a total number of atoms of 2 to 40, more preferably a group having a total number of atoms of 2 to 30, and still more preferably a group having a total number of atoms of 2 to 20.

Hereinafter, the constitutional unit represented by Formula 3 will be exemplified. Hereinafter, m represents an integer of 2 or more (for example, 2 to 10), and n represents an integer of 1 or more (for example, 1 to 10).

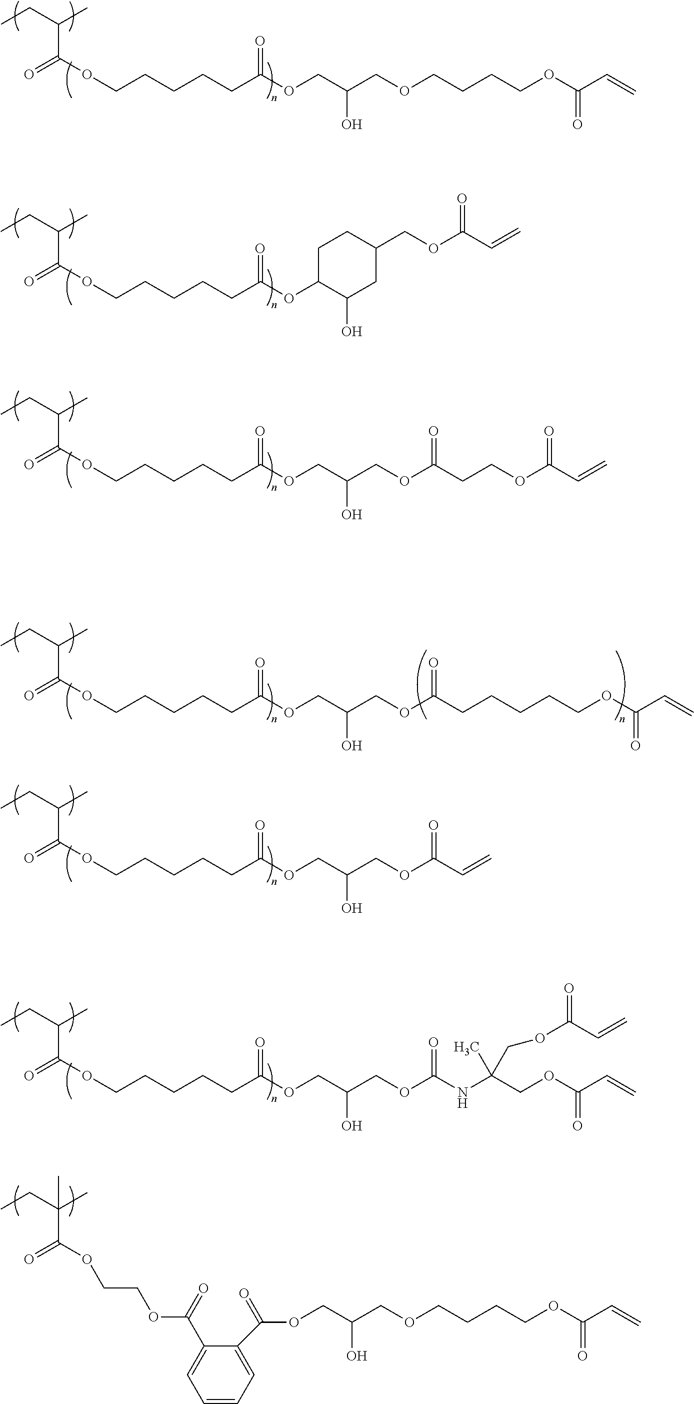

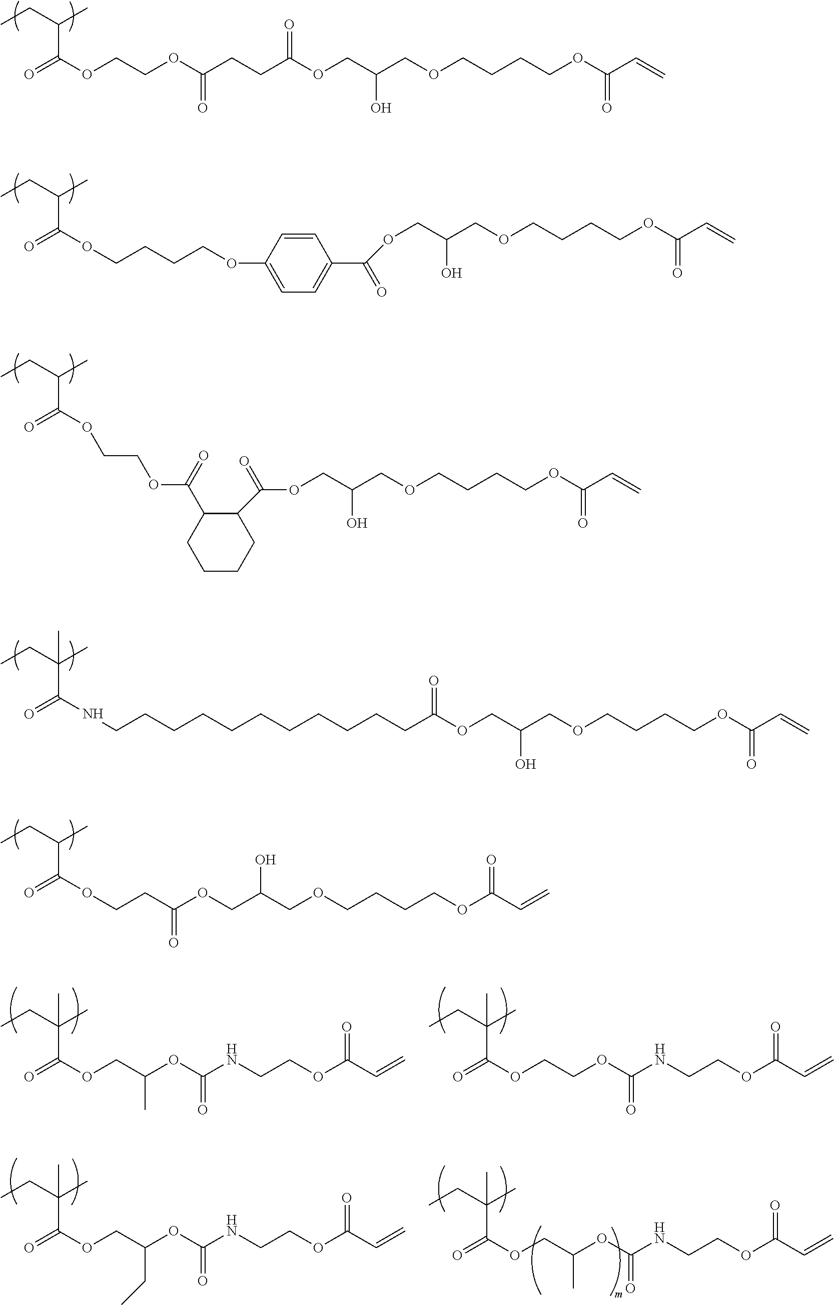

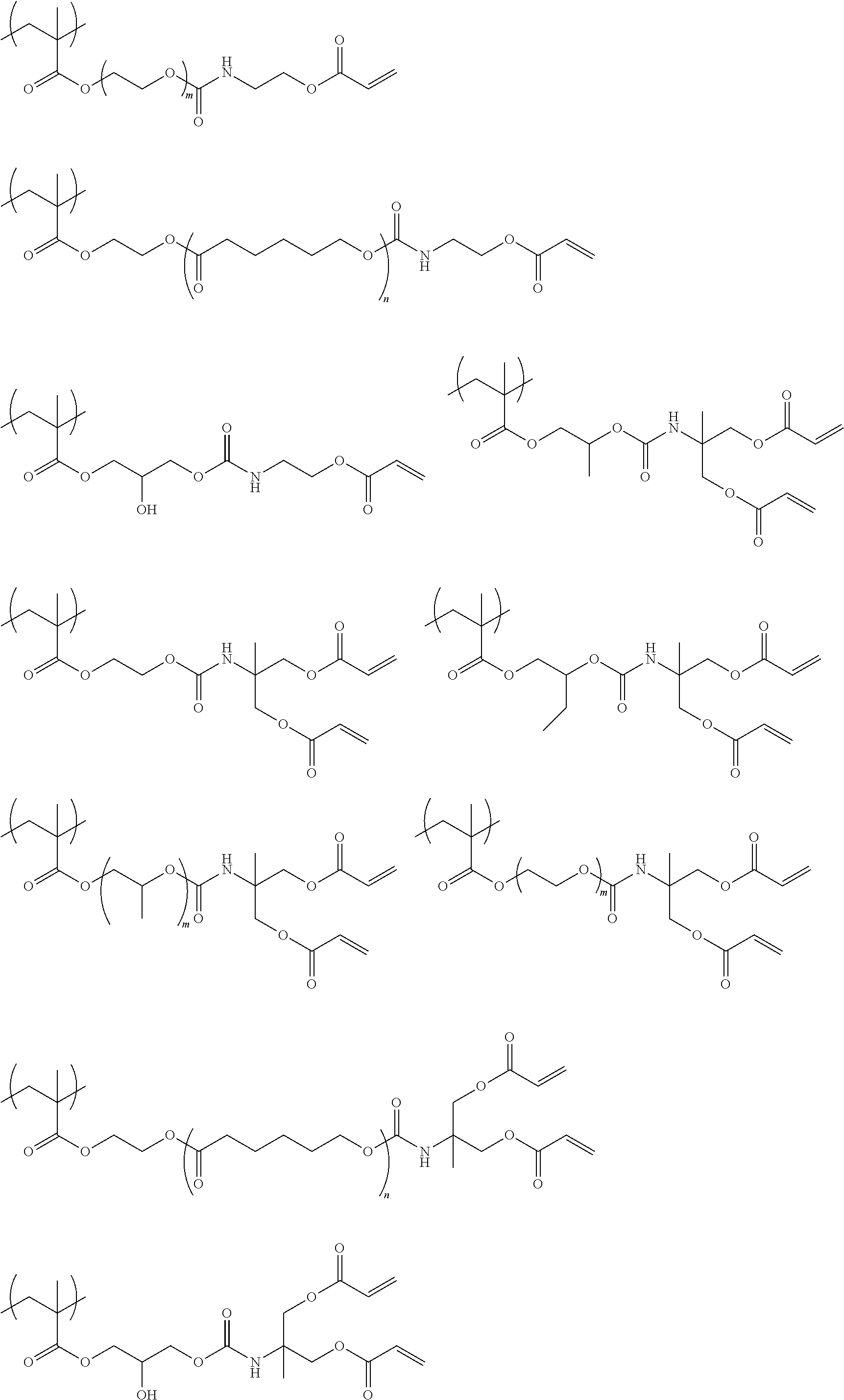

It is also preferable that the constitutional unit A includes a constitutional unit having an onium structure-containing group.

For example, the constitutional unit A also preferably includes a constitutional unit represented by Formula 6.

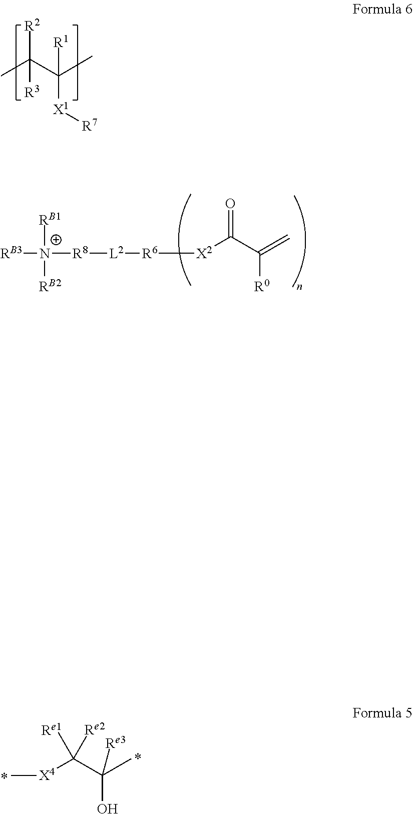

In Formula 6, R¹ to R³ each independently represent a hydrogen atom or an alkyl group.

In Formula 6, X¹ represents —COO—, —CONR—, or an arylene group, where R represents a hydrogen atom, an alkyl group, or an aryl group.

In Formula 6, X² represents an oxygen atom or —NR^{A}—. R^{A} represents a hydrogen atom, an alkyl group, or an aryl group.

In Formula 6, n represents an integer of 1 or more.

In Formula 6, R⁰ represents a hydrogen atom or an alkyl group.

R¹ to R³, X, X², R⁰, and n in Formula 6 are the same as R¹ to R³, X¹, X², R⁰, and n in Formula 1, respectively.

In Formula 6, R⁶ represents an (n+1)-valent linking group.

R⁶ in Formula 6 is the same as R⁶ in Formula 3.

The value of n specified in Formula 6 is the same as the value of n in the (n+1)-valent linking group represented by R⁶.

In a case where a plurality of X²'s are present in Formula 6, the plurality of X²'s are each independent, and they may be the same or different from each other.

In a case where a plurality of R⁰'s are present in Formula 6, the plurality of R⁰'s are each independent, and they may be the same or different from each other.

In Formula 6, L² represents a group represented by Formula 5.

In Formula 5, X⁴ represents an oxygen atom or —COO—.

In Formula 5, R^{e1} to R^{e3} each independently represent a hydrogen atom or an alkyl group. At least two of R^{e1} to R^{e3} may be bonded to each other to form a ring.

The group represented by Formula 5, which is represented by L² in Formula 6, is the same as the group represented by Formula 5, which can be represented by L¹ in Formula 3.

However, in Formula 5 represented by L², one of * on the left side or * on the right side is the bonding position with respect to R¹, and the other is the bonding position with respect to R⁶.

In Formula 6, R⁷ represents a structure including a group in which one proton is dissociated from an acid group.

Examples of the acid group include a carboxy group, a sulfonic acid group, a phosphonic acid group, and a phosphoric acid group.

Specific examples of the group in which one proton is dissociated from an acid group include —COO—, —SO₃—, —OPO₃H—, and —PO₃H—, where —COO— is preferable.

Among them, R⁷ is preferably a group represented by “-(a divalent linking group)-(a group in which one proton is dissociated from an acid group)”.

Examples of the divalent linking group include an ether group, a carbonyl group, an ester group, a thioether group, —SO₂—, —NR^{X}— (where R^{X} is a hydrogen atom or a substituent such as an alkyl group), a divalent hydrocarbon group (for example, an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), an arylene group (for example, an arylene group having 6 to 15 carbon atoms), or an alicyclic group (for example, an alicyclic group having 3 to 15 carbon atoms)), a divalent heterocyclic group (for example, a non-aromatic heterocyclic group having 3 to 15 ring member atoms), a heteroarylene group (for example, a heteroarylene group having 5 to 15 ring member atoms), and groups obtained by combining these.

The divalent linking group is preferably an alkylene group or a group obtained by bonding one or more (for example, 2 to 10) alkylene groups to a total of one or more (for example, 2 to 10) groups selected from the group consisting of an ether group, a carbonyl group, and an ester group.

In Formula 6, R¹ represents a divalent linking group.

Examples of the divalent linking group include an ether group, a carbonyl group, an ester group, a thioether group, —SO₂—, —NR^{X}— (where R^{X} is a hydrogen atom or a substituent such as an alkyl group), a divalent hydrocarbon group (for example, an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), an arylene group (for example, an arylene group having 6 to 15 carbon atoms), or an alicyclic group (for example, an alicyclic group having 3 to 15 carbon atoms)), a divalent heterocyclic group (for example, a non-aromatic heterocyclic group having 3 to 15 ring member atoms), a heteroarylene group (for example, a heteroarylene group having 5 to 15 ring member atoms), and groups obtained by combining these.

Among them, R¹ is preferably an alkylene group.

In Formula 6, R^{B1} to R^{B3} each independently represent a hydrogen atom, an alkyl group, or an aryl group.

The alkyl group may be linear or branched, and it preferably has 1 to 20 carbon atoms.

The aryl group may be monocyclic or polycyclic, and it preferably has 6 to 15 carbon atoms.

The content of the constitutional unit A (preferably the constitutional unit represented by Formula 6) having an onium structure-containing group is preferably 0.5 mol % or more, more preferably 10 mol % or more, and still more preferably 20 mol % or more, with respect to the entire constitutional unit A (preferably the constitutional unit represented by Formula 1) in the specific resin. The upper limit of the content is 100 mol % or less, preferably 85 mol % or less, and more preferably 70 mol % or less.

In a case where the composition contains two or more kinds of specific resins, the above-described content may be a content with respect to the constitutional unit A in two or more kinds of all specific resins or may be one or more kinds (one kind to all kinds) of two or more kinds thereof.

A method of introducing the constitutional unit A into the specific resin is not limited, and examples thereof include the following methods (1) to (8).

(1) A method of subjecting a compound having an epoxy group and an ethylenically unsaturated group to an addition reaction with a constitutional unit having a carboxy group in a resin.

(2) A method of subjecting a compound having an epoxy group and an ethylenically unsaturated group to an addition reaction with a constitutional unit having a carboxy group in a resin and further subjecting a compound having an isocyanate group and an ethylenically unsaturated group to an addition reaction with a generated alcohol moiety.

(3) A method of subjecting a compound having an oxetane group and an ethylenically unsaturated group to an addition reaction with a constitutional unit having a carboxy group in a resin.

(4) A method of subjecting a compound having a leaving group (for example, a halogenated alkyl group) and an ethylenically unsaturated group to a substitution reaction with a constitutional unit having a carboxy group in a resin.

(5) A method of subjecting a compound having a hydroxyalkyl group and an ethylenically unsaturated group to a condensation reaction with a constitutional unit having a carboxy group in a resin.

(6) A method of subjecting a compound having an isocyanate group and an ethylenically unsaturated group to an addition reaction with a constitutional unit having a hydroxy group in a resin.

(7) A method of subjecting a carboxylic acid chloride to a substitution reaction with a constitutional unit having a hydroxy group in a resin.

(8) A method of subjecting a constitutional unit having a halogenated alkyl group in a resin to a dehalogenated hydrogenation reaction in the presence of a base.

Among them, the method (1) is preferable as the method of forming the constitutional unit A.

In a case where the addition reaction of the method (1) is carried out in the presence of a tertiary amine catalyst, a part or the whole of the tertiary amine catalyst is incorporated into a part or the whole of the formed constitutional unit A, in a form of a salt, whereby an onium structure-containing group can be introduced.

In all the constitutional units A that has been formed, the proportion of the constitutional unit A into which an onium structure-containing group is introduced can be appropriately adjusted by changing the kind and amount of the catalyst, the adding amount of the compound having an epoxy group and an ethylenically unsaturated group, and the like.

The tertiary amine catalyst is preferably a compound represented by N(R^{A})(R^{B})(R^{C}). R^{A} to R^{C} each independently represent an alkyl group (preferably having 1 to 20 carbon atoms), an aryl group (preferably having 6 to 20 carbon atoms), or an aralkyl group (preferably having 7 to 20 carbon atoms). Examples of the substituent which may be contained in the alkyl group, the aryl group, and the aralkyl group include a hydroxyl group.

One kind of the constitutional unit A may be used alone, or two or more kinds thereof may be used.

The content of the constitutional unit A (preferably the content of the constitutional unit represented by Formula 1, and more preferably the total content of the constitutional unit represented by Formula 3 and the constitutional unit represented by Formula 6) is preferably 1% to 80% by mass and more preferably 3% to 70% by mass with respect to all the constitutional units of the specific resin.

<Constitutional Unit B>

The specific resin has a constitutional unit B.

The constitutional unit B is a constitutional unit having a phenolic hydroxyl group.

It is noted that it is preferable that the constitutional unit having a polymerizable group is not included in the constitutional unit B even in a case where the constitutional unit has a phenolic hydroxyl group.

The phenolic hydroxyl group contained in the constitutional unit B is a hydroxyl group that is directly bonded to an aromatic hydrocarbon ring (a benzene ring, a naphthalene ring, or the like). The aromatic hydrocarbon ring may be a monocyclic ring or a polycyclic ring, and it preferably has 6 to 15 carbon atoms. As long as the hydroxyl group in the phenolic hydroxyl group is directly bonded to the aromatic hydrocarbon ring moiety, the aromatic hydrocarbon ring may be fused with a ring (an aromatic heterocyclic ring, a non-aromatic heterocyclic ring, an alicyclic ring, or the like) other than the aromatic hydrocarbon ring or may have a substituent other than the hydroxyl group.

The number of phenolic hydroxyl groups contained in the constitutional unit B is 1 or more, preferably 1 to 7, more preferably 1 to 5, and still more preferably 1 to 3.

Examples of the constitutional unit B include a constitutional unit represented by Formula 2-1.

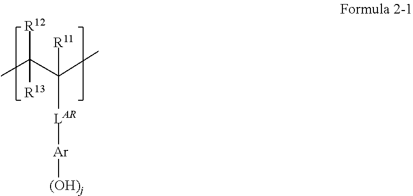

In Formula 2-1, R¹¹ to R¹³ each independently represent a hydrogen atom or an alkyl group.

The alkyl group may be linear or branched, and it preferably has 1 to 6 carbon atoms.

In Formula 2-1, L^{AR} represents a single bond or a divalent linking group.

Examples of the divalent linking group include an ether group, a carbonyl group, an ester group, a thioether group, —SO₂—, —NR^{X}— (where R^{X} is a hydrogen atom or a substituent such as an alkyl group), a divalent hydrocarbon group (for example, an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), an arylene group (for example, an arylene group having 6 to 15 carbon atoms), or an alicyclic group (for example, an alicyclic group having 3 to 15 carbon atoms)), a divalent heterocyclic group (for example, a non-aromatic heterocyclic group having 3 to 15 ring member atoms), a heteroarylene group (for example, a heteroarylene group having 5 to 15 ring member atoms), and groups obtained by combining these.

In Formula 2-1, Ar represents a (j+1)-valent aromatic hydrocarbon ring group.

The aromatic hydrocarbon ring group may be a monocyclic ring or a polycyclic ring, and it preferably has 6 to 15 carbon atoms.

The aromatic hydrocarbon ring in the aromatic hydrocarbon ring group may be fused with a ring (an aromatic heterocyclic ring, a non-aromatic heterocyclic ring, an alicyclic ring, or the like) other than the aromatic hydrocarbon ring or may have a substituent other than the hydroxyl group. However, the j pieces of OH are bonded to the aromatic hydrocarbon ring moiety in the aromatic hydrocarbon ring group. It is also preferable that the L^{AR} is bonded to the aromatic hydrocarbon ring moiety in the aromatic hydrocarbon ring group.

The aromatic hydrocarbon ring group is preferably a benzene ring group or a naphthalene ring group, and more preferably a benzene ring group.

In Formula 2-1, j represents an integer of 1 or more, and it is preferably an integer of 1 to 7, more preferably an integer of 1 to 5, and still more preferably an integer of 1 to 3.

The constitutional unit B is preferably a constitutional unit represented by Formula 2.

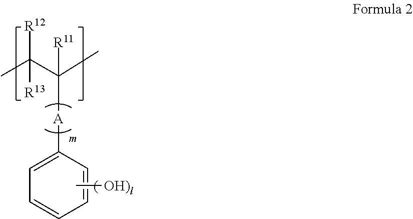

In Formula 2, R¹¹ to R¹³ each independently represent a hydrogen atom or an alkyl group.

The alkyl group may be linear or branched, and it preferably has 1 to 6 carbon atoms.

In Formula 2, A represents —COO—, —CONR′—, —COO—R″—, —CONR′—R″—, or an arylene group.

The arylene group may be monocyclic or polycyclic, and it preferably has 6 to 15 carbon atoms.

R′ in —CONR′— and —CONR′—R″— represents a hydrogen atom, an alkyl group, or an aryl group. The alkyl group may be linear or branched, and it preferably has 1 to 6 carbon atoms. The aryl group may be monocyclic or polycyclic, and it preferably has 6 to 15 carbon atoms.

R″ in —COO—R″— and —CONR′—R″-represents a divalent linking group.

Examples of the divalent linking group include an ether group, a carbonyl group, an ester group, a thioether group, —SO₂—, —NR^{X}— (where R^{X} is a hydrogen atom or a substituent such as an alkyl group), a divalent hydrocarbon group (for example, an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), an arylene group (for example, an arylene group having 6 to 15 carbon atoms), or an alicyclic group (for example, an alicyclic group having 3 to 15 carbon atoms)), a divalent heterocyclic group (for example, a non-aromatic heterocyclic group having 3 to 15 ring member atoms), a heteroarylene group (for example, a heteroarylene group having 5 to 15 ring member atoms), and groups obtained by combining these.

In Formula 2, m represents 0 or 1.

In Formula 2, 1 represents an integer of 1 to 5. 1 is preferably an integer of 1 to 3.

The constitutional unit B is more preferably a constitutional unit represented by Formula 7.

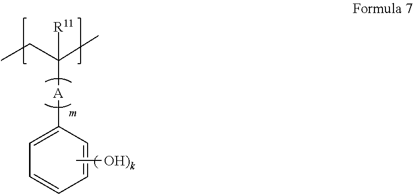

In Formula 7, R¹¹ represents a hydrogen atom or an alkyl group.

In Formula 7, A represents —COO—, —CONR′—, —COO—R″—, —CONR′—R″—, or an arylene group. R′ represents a hydrogen atom, an alkyl group, or an aryl group. R″ represents a divalent linking group,

In Formula 7, m represents 0 or 1.

R^{D1}, A, and m in Formula 7 are the same as R¹¹, A, and m in Formula 2, respectively.

In Formula 7, k represents an integer of 1 to 3.

Among the above, the constitutional unit B is preferably one or more selected from the group consisting of a constitutional unit represented by Formula 8, a constitutional unit represented by Formula 9, and a constitutional unit represented by Formula 10.

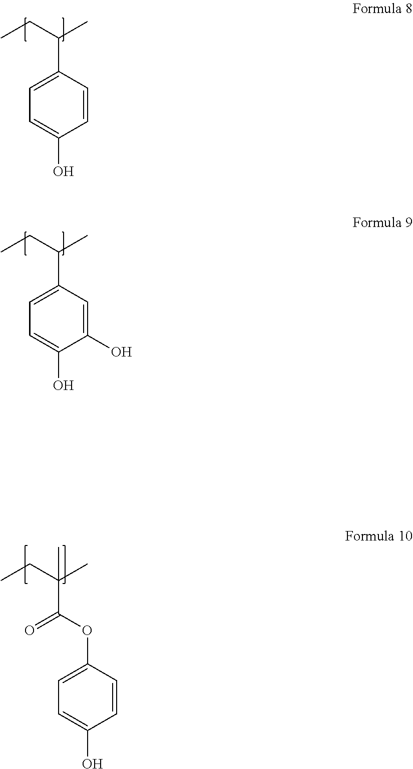

One kind of the constitutional unit B may be used alone, or two or more kinds thereof may be used.

The content of the constitutional unit B (preferably the content of the constitutional unit represented by Formula 2-1, more preferably the content of the constitutional unit represented by Formula 2, still more preferably the content of the constitutional unit represented by Formula 7, and particularly preferably the total content of the constitutional units represented by Formulae 8 to 10) is preferably 0.1% to 40% by mass and more preferably 0.5% to 15% by mass with respect to all the constitutional units of the specific resin.

<Constitutional Unit C>

The specific resin has a constitutional unit C.

The constitutional unit C is a constitutional unit having an acidic group.

The acidic group in the constitutional unit C does not include a phenolic hydroxyl group.

In addition, it is preferable that the constitutional unit having a polymerizable group is not included in the constitutional unit C even in a case where it is a constitutional unit having an acidic group. It is preferable that the constitutional unit having a phenolic hydroxyl group is not included in the constitutional unit C even in a case where it is a constitutional unit having an acidic group.

Examples of the acidic group include a carboxy group, a sulfonic acid group, a phosphonic acid group, and a phosphoric acid group.

The number of acidic groups contained in the constitutional unit C is 1 or more, preferably 1 to 7, more preferably 1 to 5, and still more preferably 1 to 3.

The constitutional unit C is preferably a repeating unit represented by Formula C.

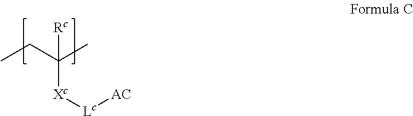

In Formula C, R⁰ represents a hydrogen atom or an alkyl group.

The alkyl group may be linear or branched, and it preferably has 1 to 6 carbon atoms.

In Formula C, X^{c} represents a single bond, —COO—, —CONR^{B}—, or an arylene group.

The arylene group may be monocyclic or polycyclic, and it preferably has 6 to 15 carbon atoms.

R^{B} in —CONR^{B}— represents a hydrogen atom, an alkyl group, or an aryl group. The alkyl group may be linear or branched, and it preferably has 1 to 6 carbon atoms. The aryl group may be monocyclic or polycyclic, and it preferably has 6 to 15 carbon atoms.

In Formula C, L^{c} represents a group obtained by bonding a total of 2 or more (for example, 2 to 10) groups selected from the group consisting of an aliphatic hydrocarbon group having 1 to 20 carbon atoms, an arylene group having 6 to 20 carbon atoms, an aliphatic hydrocarbon group having 1 to 20 carbon atoms, and an arylene group having 6 to 20 carbon atoms, to a total of one or more (for example, 1 to 9) groups selected from the group consisting of an ether group and an ester group.

Examples of the aliphatic hydrocarbon group include an alkylene group and a cycloalkylene group.

In addition, in a case where X^{c} is a single bond or an arylene group, L^{c} may be a single bond.

In Formula C, AC represents an acidic group.

Examples of the acidic group include a carboxy group, a sulfonic acid group, a phosphonic acid group, and a phosphoric acid group.

Hereinafter, the constitutional unit C will be exemplified. In the following structures, n represents an integer of 1 or more (for example, 1 to 10).

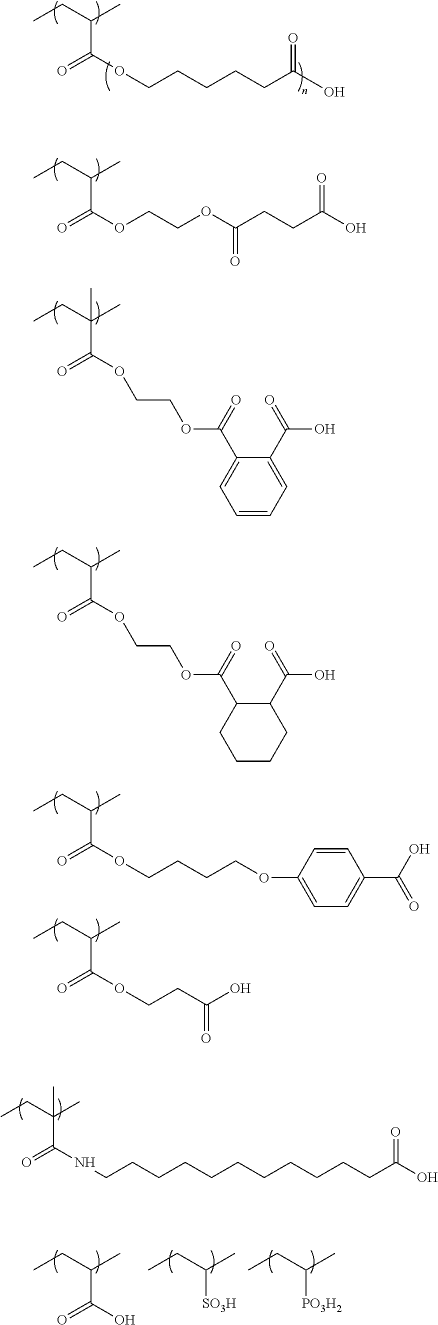

One kind of the constitutional unit C may be used alone, or two or more kinds thereof may be used.

The content of the constitutional unit C (preferably the content of the constitutional unit represented by Formula C) is preferably 1% to 80% by mass and more preferably 3% to 70% by mass with respect to all the constitutional units of the specific resin.

<Constitutional Unit D>

The specific resin preferably has a constitutional unit D as a constitutional unit that does not correspond to any one of the constitutional units A to C.

The constitutional unit D is a constitutional unit represented by Formula D.

It is noted that the constitutional unit D is a group that does not have any one of a polymerizable group, a phenolic hydroxyl group, or an acidic group.

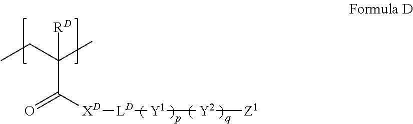

In Formula D, R^{D} represents a hydrogen atom or an alkyl group.

The alkyl group may be linear or branched, and it preferably has 1 to 6 carbon atoms.

In Formula D, X^{D} represents an oxygen atom or —NR^{C}—. R^{C} represents a hydrogen atom, an alkyl group, or an aryl group.

The alkyl group may be linear or branched, and it preferably has 1 to 6 carbon atoms.

The aryl group may be monocyclic or polycyclic, and it preferably has 6 to 15 carbon atoms.

In Formula D, L^{D} represents a single bond or a divalent linking group.

Examples of the divalent linking group include an ether group, a carbonyl group, an ester group, a thioether group, —SO₂—, —NR^{X}— (where R^{X} is a hydrogen atom or a substituent such as an alkyl group), a divalent hydrocarbon group (for example, an alkylene group (for example, an alkylene group having 1 to 10 carbon atoms), an alkenylene group (for example, an alkenylene group having 2 to 12 carbon atoms), an alkynylene group (for example, an alkynylene group having 2 to 12 carbon atoms), an arylene group (for example, an arylene group having 6 to 15 carbon atoms), or an alicyclic group (for example, an alicyclic group having 3 to 15 carbon atoms)), a divalent heterocyclic group (for example, a non-aromatic heterocyclic group having 3 to 15 ring member atoms), a heteroarylene group (for example, a heteroarylene group having 5 to 15 ring member atoms), and groups obtained by combining these.

L^{D} is preferably a group having a total number of atoms of 2 to 30, more preferably a group having a total number of atoms of 3 to 20, and still more preferably a group having a total number of atoms of 4 to 10.

Further, L^{D} is preferably a group having a urethane group (—O—CO—NH—) or a urea group (—NH—CO—NH—), and it is more preferably a group obtained by bonding an alkylene group (for example, an alkylene group having 1 to 10 carbon atoms) to urethane or a urea group.

In Formula D, Y¹ and Y² each independently represent an alkyleneoxy group or an alkylenecarbonyloxy group.

The alkyleneoxy group preferably has 1 to 30 carbon atoms, more preferably has 2 to 9 carbon atoms, and still more preferably has 4 to 7 carbon atoms.

The alkylenecarbonyloxy group preferably has 2 to 30 carbon atoms, more preferably has 3 to 10 carbon atoms, and still more preferably has 5 to 8 carbon atoms.

The alkylene group portion of the alkyleneoxy group and the alkylenecarbonyloxy group may be linear or branched.

Y¹ and Y² may be the same as or different from each other.

In Formula D, Z¹ represents an aliphatic hydrocarbon group having 1 to 20 carbon atoms (a linear or branched alkyl group or the like) or an aryl group having 6 to 20 carbon atoms.

The aliphatic hydrocarbon group may be linear, may be branched, or may form a ring structure in a part or the whole thereof. The aliphatic hydrocarbon group is preferably an alkyl group. The alkyl group may be linear or branched.

The aliphatic hydrocarbon group has 1 to 20 carbon atoms, preferably 4 to 20 carbon atoms, and more preferably 6 to 20 carbon atoms.

The aryl group may be monocyclic or polycyclic, and it preferably has 6 to 15 carbon atoms. It is also preferable that the aryl group further has an aliphatic hydrocarbon group having 1 to 20 carbon atoms, as a substituent.

In Formula D, p and q each independently represent an integer of 0 or more.
p is preferably an integer of 1 to 50, more preferably an integer of 2 to 30, and still more preferably an integer of 3 to 20.
q is preferably an integer of 0 to 50, more preferably an integer of 0 to 30, and still more preferably an integer of 0 to 20.

The value of p+q is 1 or more (for example, 1 to 100).

Hereinafter, the constitutional unit D will be exemplified.

In the following structures, n represents an integer of 1 or more (for example, 1 to 10). a and b each independently represent an integer of 0 or more (for example, 0 to 10), and a+b is an integer of 1 or more (for example, 1 to 20). m represents an integer of 1 or more (for example, 1 to 20). R represents a hydrogen atom or a methyl group.

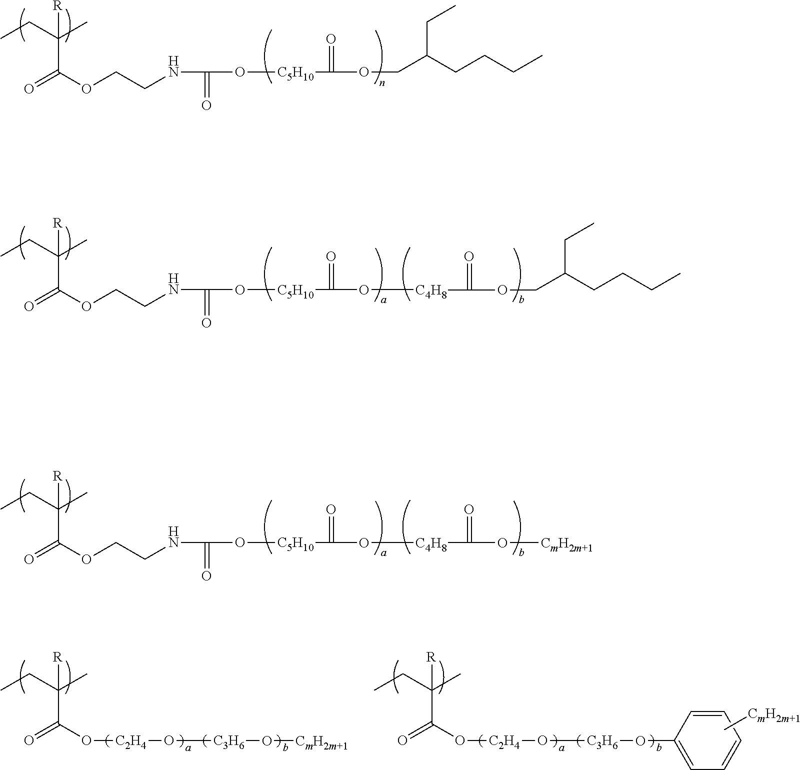

One kind of the constitutional unit D may be used alone, or two or more kinds thereof may be used.

The content of the constitutional unit D is preferably 1% to 60% by mass and more preferably 3% to 30% by mass with respect to all the constitutional units of the specific resin.

<Constitutional Unit E>

The specific resin may have a constitutional unit E.

The constitutional unit E is another constitutional unit that does not correspond to any of the above-described constitutional units A to D.

The constitutional unit E is not particularly limited, and examples thereof include known constitutional units.

Examples of the constitutional unit E include a constitutional unit represented by Formula E.

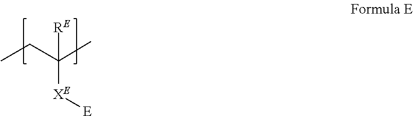

In Formula E, R^{E} represents a hydrogen atom or an alkyl group.

The alkyl group may be linear or branched, and it preferably has 1 to 6 carbon atoms.

In Formula E, X^{E} represents —COO—, —CONR—, or an arylene group.

The arylene group may be monocyclic or polycyclic, and it preferably has 6 to 15 carbon atoms.

R in —CONR— represents a hydrogen atom, an alkyl group, or an aryl group.

The alkyl group, which can be represented by R of —CONR—, may be linear or branched, and it preferably has 1 to 6 carbon atoms.

The aryl group, which can be represented by R of —CONR—, may be monocyclic or polycyclic, and it preferably has 6 to 15 carbon atoms.

In Formula E, E represents a monovalent organic group having 1 to 42 carbon atoms.

The organic group may be linear, may be branched, or may form a ring structure in a part or the whole thereof.

The organic group is preferably an alkyl group, a cycloalkyl group, an aryl group, or a group (an arylalkyl group, an alkylcycloalkyl group, or the like) consisting of a combination thereof. In addition, it is also preferable that these groups have, as a substituent, a hydroxyl group which is not a phenolic hydroxyl group.

The alkyl group may be linear or branched, and it preferably has 1 to 6 carbon atoms.

The cycloalkyl group may be monocyclic or polycyclic, and it preferably has 3 to 15 carbon atoms.

The aryl group may be monocyclic or polycyclic, and it preferably has 6 to 15 carbon atoms.

The constitutional unit represented by Formula E does not correspond to any one of the constitutional units A to D.

One kind of the constitutional unit E may be used alone, or two or more kinds thereof may be used.

In a case where the constitutional unit E (preferably a constitutional unit represented by Formula E) is contained in the specific resin, the content thereof is preferably 1% to 80% by mass and more preferably 3% to 70% by mass with respect to all the constitutional units of the specific resin.

The weight-average molecular weight (Mw) of the specific resin is preferably 1,000 or more, more preferably 5,000 or more, and still more preferably 10,000 or more. The Mw of the specific resin is preferably 200,000 or less, more preferably 100,000 or less, and still more preferably 50,000 or less.

The ethylenically unsaturated bond value of the specific resin is preferably 0.01 to 2.5 mmol/g, more preferably 0.1 to 2.2 mmol/g, and still more preferably 0.3 to 2.0 mmol/g.

The ethylenically unsaturated bond value of the specific resin indicates the molar amount of the ethylenically unsaturated group per 1 g of the solid content of the specific resin. It can be determined by extracting a low molecular weight component (a) of the ethylenically unsaturated group portion (for example, acrylic acid in the case where the constitutional unit represented by Formula 1 has an acryloxy group) from the specific resin by an alkali treatment, measuring the content thereof by high performance liquid chromatography (HPLC), and calculating the ethylenically unsaturated bond value from the following expression based on the measured value. Specifically, 0.1 g of a measurement sample is dissolved in a tetrahydrofuran/methanol mixed solution (50 mL/15 mL), 10 mL of a 4 mol/L sodium hydroxide aqueous solution is added thereto, and the resultant mixture is subjected to a reaction at 40° C. for 2 hours. The reaction solution is neutralized with 10.2 mL of a 4 mol/L methanesulfonic acid aqueous solution, a mixed solution to which 5 mL of ion exchange water and 2 mL of methanol have been added is subsequently transferred to a 100 mL volumetric flask, and the volume is adjusted with methanol to prepare an HPLC measurement sample, which is subsequently measured under the following conditions. It is noted that the content of the low molecular weight component (a) can be calculated from a separately created calibration curve of the low molecular weight component (a), and the ethylenically unsaturated bond value can be calculated from the following expression.

Calculation Expression for Ethylenically Unsaturated Bond Value

Ethylene unsaturated bond value [mmol/g]=(content [ppm] of low molecular weight component (a)/molecular weight [g/mol] of low molecular weight component (a))/(weighed value [g] of polymer as liquid preparation×(concentration [%] of solid contents of polymer solution/100)×10)

HPLC Measurement Conditions

Measuring instrument: Agilent-1200 (manufactured by Agilent Technologies, Inc.)
Column: Synergi 4u Polar-RP 80A, manufactured by Phenomenex Inc., 250 mm×4.60 mm (inner diameter)+guard column
Column temperature: 40° C.
Analysis time: 15 minutes
Flow rate: 1.0 mL/min (maximum liquid feeding pressure: 182 bar)
Injection amount: 5 μL
Detection wavelength: 210 nm
Eluant: tetrahydrofuran (for HPLC without stabilizer)/buffer solution (ion exchange aqueous solution containing 0.2 vol % phosphorus acid and 0.2 vol % triethylamine)=55/45 (vol %)

The acid value of the specific resin is preferably 10 to 250 mgKOH/g, more preferably 30 to 200 mgKOH/g, and still more preferably 60 to 150 mgKOH/g.

The acid value is determined by neutralization titration using a sodium hydroxide aqueous solution. Specifically, it is determined by titrating a solution obtained by dissolving a specific resin in a solvent with a sodium hydroxide aqueous solution using a potentiometry method to calculate the number of mmol of the acid contained in 1 g of the specific solid and then multiplying this value by the molecular weight of KOH of 56.1.

One kind of the specific resin may be used alone, or two or more kinds thereof may be used.

The content of the specific resin is preferably 2% to 75% by mass, more preferably 5% to 50% by mass, and still more preferably 8% to 25% by mass, with respect to the total solid content of the composition.

[Another Resin]

The composition according to the embodiment of the present invention may contain another resin that does not correspond to the above-described specific resin.

The other resin does not have all of the constitutional units A to C at the same time. The other resin may have one or two kinds of the constitutional units A to C as long as it does not have all of the constitutional units A to C at the same time.

The other resin is preferably an alkali-soluble resin.

Examples of the alkali-soluble resin include a polymer having a high molecular weight, which is an alkali-soluble resin having at least one group (for example, a carboxy group, a phosphate group, a sulfonate group, or the like) that promotes alkali solubility, in a molecule (preferably a molecule having an acrylic copolymer or a styrene-based copolymer as a main chain).

It is preferable that the alkali-soluble resin is soluble in an organic solvent and can be developed with a weak alkaline aqueous solution.

The content of the constitutional unit having a group that promotes alkali solubility is preferably 1 to 70 mol % and more preferably 5 to 40 mol % with respect to all the constitutional units of the alkali-soluble resin.

The alkali-soluble resin is preferably a polymer having a carboxylic acid in the side chain. Examples thereof include a methacrylate copolymer, an acrylic acid copolymer, an itaconic acid copolymer, a crotonic acid copolymer, a maleic acid copolymer, and a partially esterified maleic acid copolymer, as described in the respective publications of JP1984-44615A (JP-S59-44615A), JP1979-34327B (JP-S54-34327B), JP1983-12577B (JP-S58-12577B), JP1979-25957B (JP-S54-25957B), JP1984-53836A (JP-S59-53836A), and JP1984-71048A (JP-S59-71048A), as well as an acidic cellulose derivative having a carboxylic acid in a side chain and a polymer having a hydroxyl group, to which an acid anhydride is added, and preferred examples thereof include a polymer having a high molecular weight, which has a (meth)acryloyl group in a side chain.

The other resin (preferably the alkali-soluble resin) is preferably a copolymer of (meth)acrylic acid and another monomeric substance copolymerizable with the (meth)acrylic acid.

Examples of the other monomeric substance copolymerizable with (meth)acrylic acid include (meth)acrylic acid esters, crotonic acid esters, vinyl esters, maleic acid diesters, fumaric acid diesters, itaconic acid diesters, (meth)acrylamides, styrenes, vinyl ethers, vinyl ketones, olefins, maleimides, (meth)acrylonitrile, and an ether dimer represented by Formula ED1 or ED2.

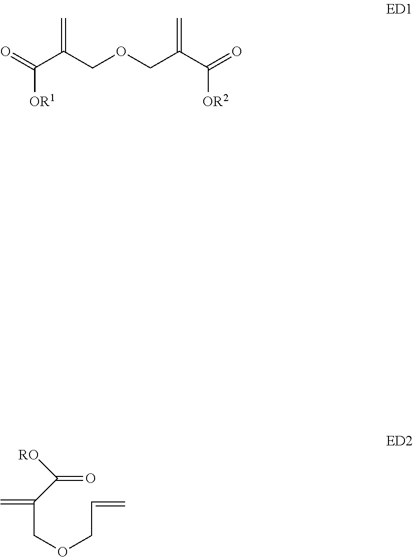

In Formula ED1, R¹ and R² each independently represent a hydrogen atom or a hydrocarbon group having 1 to 25 carbon atoms.

In Formula ED2, R represents a hydrogen atom or an organic group having 1 to 30 carbon atoms. As the specific example of Formula ED2, the description of JP2010-168539A can be referenced.

Examples of the (meth) acrylic acid esters as the other monomeric substance copolymerizable with (meth) acrylic acid include methyl (meth)acrylate, ethyl (meth)acrylate, n-propyl (meth)acrylate, isopropyl (meth)acrylate, n-butyl (meth)acrylate, isobutyl (meth)acrylate, t-butyl (meth)acrylate, amyl (meth)acrylate, n-hexyl (meth)acrylate, cyclohexyl (meth)acrylate, t-butyl cyclohexyl (meth)acrylate, 2-ethylhexyl (meth)acrylate, t-octyl (meth)acrylate, dodecyl (meth)acrylate, octadecyl (meth)acrylate, acetoxyethyl (meth)acrylate, phenyl (meth)acrylate, 2-hydroxyethyl (meth)acrylate, 2-hydroxypropyl (meth)acrylate, 3-hydroxypropyl (meth)acrylate, 4-hydroxybutyl (meth)acrylate, 2-methoxyethyl (meth)acrylate, 2-ethoxyethyl (meth)acrylate, 2-(2-methoxyethoxy)ethyl (meth)acrylate, 3-phenoxy-2-hydroxypropyl (meth)acrylate, 2-chloroethyl (meth)acrylate, glycidyl (meth)acrylate, 3,4-epoxycyclohexylmethyl (meth)acrylate, vinyl (meth)acrylate, 2-phenylvinyl (meth)acrylate, 1-propenyl (meth)acrylate, allyl (meth)acrylate, 2-aryloxyethyl (meth)acrylate, propargyl (meth)acrylate, benzyl (meth)acrylate, diethylene glycol monomethyl ether (meth)acrylate, diethylene glycol monoethyl ether (meth)acrylate, triethylene glycol monomethyl ether (meth)acrylate, triethylene glycol monoethyl ether (meth)acrylate, polyethylene glycol monomethyl ether (meth)acrylate, polyethylene glycol monoethyl ether (meth)acrylate, β-phenoxyethoxyethyl (meth)acrylate, nonylphenoxy polyethylene glycol (meth)acrylate, dicyclopentenyl (meth)acrylate, dicyclopentenyloxyethyl (meth)acrylate, trifluoroethyl (meth)acrylate, octafluoropentyl (meth)acrylate, perfluorooctylethyl (meth)acrylate, dicyclopentanyl (meth)acrylate, tribromophenyl (meth)acrylate, tribromophenyloxyethyl (meth)acrylate, and γ-butyrolactone (meth)acrylate.

In addition, the other resin (preferably the alkali-soluble resin) may have the above-described constitutional unit corresponding to the constitutional unit A.

For example, a method of introducing the constitutional unit A described regarding the specific resin into a copolymer of (meth)acrylic acid and another monomeric substance copolymerizable with (meth)acrylic acid can be carried out, whereby the constitutional unit A can be introduced into other resin (preferably, the alkali-soluble resin).

In a case where the constitutional unit A is contained in the other resin (preferably, the alkali-soluble resin), the content thereof is preferably 1 to 70 mol % and more preferably 5 to 30 mol % with respect to all the constitutional units of the other resin (preferably, the alkali-soluble resin).

In addition, the other resin (preferably the alkali-soluble resin) may be a cardo resin having a cardo skeleton.

Examples of the cardo resin include V-259ME (manufactured by NIPPON STEEL & SUMITOMO METAL CORPORATION).

The weight-average molecular weight (Mw) of the other resin (preferably the alkali-soluble resin) is preferably 5,000 or more and more preferably 10,000 to 300,000.

The number-average molecular weight (Mn) of the other resin (preferably the alkali-soluble resin) is preferably 1,000 or more and more preferably 2,000 to 250,000. The dispersivity (weight-average molecular weight/number-average molecular weight) is preferably 1.1 to 10 and more preferably 1.2 to 5.

The other resin (preferably the alkali-soluble resin) may be, for example, any of a random polymer, a block polymer, or a graft polymer.

Examples of the other resin (preferably the alkali-soluble resins) include the compounds described in paragraphs 0162 to 0175 of JP2007-277514A.

One kind of the other resin (preferably the alkali-soluble resin) may be used alone, or two or more kinds thereof may be used.

In a case where the other resin (preferably the alkali-soluble resin) is contained in the composition, the content thereof is preferably 0.1% to 40% by mass, more preferably 0.5% to 30% by mass, and still more preferably 1% to 10% by mass, with respect to the total solid content of the composition.

[Dispersion Aid]

The composition may contain a dispersion aid.

The dispersion aid is a component other than the above-described resin (the specific resin and the other resin), which is a component that can suppress the aggregation and/or the precipitation of a component that is present in the composition in a solid state, such as a pigment.

Examples of the dispersion aid include a pigment derivative.

In addition, it is also preferable that the dispersion aid has one or more (for example, 1 to 6 and preferably 2 to 4) dialkylamino groups. The alkyl groups in the dialkylamino group each independently have preferably 1 to 6 carbon atoms.

In addition, it is also preferable that the dispersion aid has one or more (for example, 1 to 10 and preferably 2 to 8) aromatic rings. The aromatic rings may be each independently a monocyclic ring or a polycyclic ring or may be fused with a non-aromatic ring. The number of ring member atoms of the aromatic ring is, for example, 5 to 15.

The content of the dispersion aid is preferably 0.0001% to 10% by mass, more preferably 0.001% to 8% by mass, and still more preferably 0.003% to 4% by mass, with respect to the total solid content of the composition.

[Pigment]

The composition according to the embodiment of the present invention contains a pigment.

Examples of the pigment include an inorganic pigment and an organic pigment.

The pigment preferably contains one or two or more selected from the group consisting of, for example, a black pigment, a white pigment, and a chromatic pigment, and more preferably contains at least a black pigment.

The content of the black pigment is preferably 0% to 100% by mass, more preferably 51% to 100% by mass, and still more preferably 90% to 100% by mass, with respect to the total mass of the pigment.

Specific examples of the pigment include black pigments such as carbon black, titanium black (titanium nitride, titanium oxynitride, lower order titanium oxide, and the like), zirconium nitride, zirconium oxynitride, vanadium nitride, vanadium oxynitride, niobium nitride, and, niobium oxynitride; and oxides of metals such as iron, cobalt, aluminum, cadmium, lead, copper, titanium, magnesium, chromium, zinc, and antimony, and metal complex salts.

Among them, the composition preferably contains, as the pigment, one or more selected from the group consisting of carbon black, titanium black, zirconium nitride, and zirconium oxynitride.

In addition to those described above, examples thereof include, as an organic pigment or an inorganic pigment, the following pigments.
Color Index (C.I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214 (all, yellow pigments);
C. I. Pigment Orange 2, 5, 13, 16, 17:1, 31, 34, 36, 38, 43, 46, 48, 49, 51, 52, 55, 59, 60, 61, 62, 64, 71, 73 (all, orange pigments);
C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 270, 272, 279 (all, red pigments);
C. I. Pigment Green 7, 10, 36, 37, 58, 59 (all, green pigments);
C. I. Pigment Violet 1, 19, 23, 27, 32, 37, 42, 58, 59 (all, purple pigments);
C. I. Pigment Blue 1, 2, 15, 15:1, 15:2, 15:3, 15:4, 15:6, 16, 22, 60, 64, 66, 79, 80 (all, blue pigments); and
C. I. Pigment White 6, 18, 21 (all, white pigments)

In addition, as the green pigment, a halogenated zinc phthalocyanine pigment having an average number of halogen atoms in the molecule of 10 to 14, an average number of bromine atoms in one molecule of 8 to 12, and an average number of chlorine atoms in one molecule of 2 to 5 can also be used. Specific examples thereof include the compound described in WO2015/118720A.

In addition, as the blue pigment, an aluminum phthalocyanine compound having a phosphorus atom can also be used. Specific examples thereof include the compounds described in paragraphs 0022 to 0030 of JP2012-247591A and paragraph 0047 of JP2011-157478A.

In addition, examples of the white pigment also include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide.

In addition, examples of the black pigment include lactam black (Irgaphor Black S 0100 CF or the like, manufactured by BASF SE).

In addition, an infrared absorbing pigment can also be used as the pigment. The infrared absorbing pigment is not particularly limited, and for example, a known infrared absorbing pigment is used. It is preferably a diiminium compound, a squarylium compound, a cyanine compound, a phthalocyanine compound, a naphthalocyanine compound, a quaterrylene compound, an aminium compound, an iminium compound, an azo compound, an anthraquinone compound, a porphyrin compound, a pyrrolo pyrrole compound, an oxonol compound, a croconium compound, a hexaphyrin compound, a metal dithiol compound, a copper compound, a tungsten compound, or a metal boride, more preferably a diiminium compound, a squarylium compound, a cyanine compound, a phthalocyanine compound, a naphthalocyanine compound, a quaterrylene compound, a pyrrolo pyrrole compound, a metal dithiol compound, a copper compound, or a tungsten compound, still more preferably a squarylium compound, a cyanine compound, a phthalocyanine compound, or a pyrrolo pyrrole compound, and particularly preferably a squarylium compound or a pyrrolo pyrrole compound.

In addition, examples of the infrared absorbing pigment include infrared absorbing pigments such as the infrared absorbing agents described in JP2009-263614A, JP2011-068731A, and WO2015/166873A.

The infrared absorbing pigment is preferably a compound having absorption in a wavelength range of 700 to 2,000 nm, and more preferably a compound having a maximal absorption wavelength in a wavelength range of 700 to 2,000 nm.

The volume average particle diameter of the pigment is not particularly limited; however, it is preferably 0.01 to 0.1 μm and more preferably 0.01 to 0.05 μm.

One kind of pigment may be used alone, or two or more kinds thereof may be used.

The content of the pigment is 15% by mass or more and preferably 30% by mass or more with respect to the total solid content of the composition. The content is preferably 90% by mass or less and more preferably 60% by mass or less.

In addition, the content is preferably 48% by mass or more from the viewpoint of obtaining a cured film having a higher color value.

[Photopolymerization Initiator]

The composition may contain a photopolymerization initiator.

The photopolymerization initiator is not particularly limited as long as it has an ability to initiate polymerization, and can be appropriately selected from known photopolymerization initiators. For example, it is preferably a compound having photosensitivity to a ray in a range from an ultraviolet range to a visible range. In addition, the photoradical polymerization initiator may be a compound that produces an active radical by any action with a photo-excited sensitizing agent.

From the viewpoint of curability and sensitivity, the photopolymerization initiator is preferably a photoradical polymerization initiator, and more preferably a compound having an oxime structure.

Examples of the photopolymerization initiator include a halogenated hydrocarbon derivative (a compound having a triazine skeleton, a compound having an oxadiazole skeleton, or the like), an acylphosphine compound, a hexaarylbiimidazole, an oxime compound, an organic peroxide, a thio compound, a ketone compound, an aromatic onium salt, an α-hydroxyketone compound, and an α-aminoketone compound.

From the viewpoint of exposure sensitivity, the photopolymerization initiator is preferably at least one compound selected from the group consisting of a trihalomethyltriazine compound, a benzyldimethyl ketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, and a 3-aryl-substituted coumarin compound, more preferably at least one compound selected from the group consisting of an oxime compound, an α-hydroxyketone compound, an α-aminoketone compound, and an acylphosphine compound, and still more preferably an oxime compound.

Regarding the photopolymerization initiator, the description of paragraphs 0065 to 0111 of JP2014-130173A and paragraphs 0274 to 0306 of JP2013-029760A can be referred to, the contents of which are incorporated in the present specification.

Examples of the commercially available product of the α-hydroxyketone compound include Omnirad-184, Omnirad-1173, Omnirad-500, Omnirad-2959, and Omnirad-127 (all, manufactured by IGM Resins B.V.).

Examples of the commercially available product of the α-aminoketone compound include Omnirad-907, Omnirad-369, Omnirad-379, and Omnirad-379EG (all, manufactured by IGM Resins B.V.).

Examples of the commercially available product of the acylphosphine compound include Omnirad-819 and Omnirad-TPO (all, manufactured by BASF SE).

Examples of the oxime compound include the compound described in JP2001-233842A, the compound described in JP2000-080068A, the compound described in JP2006-342166A, the compound described in J. C. S. Perkin II (1979, pp. 1653-1660), the compound described in J. C. S. Perkin II (1979, pp. 156-162), the compound described in Journal of Photopolymer Science and Technology (1995, pp. 202-232), the compound described in JP2000-66385A, the compound described in JP2000-80068A, the compound described in JP2004-534797A, the compound described in JP2006-342166A, the compound described in JP2017-019766A, the compound described in JP6065596B, the compound described in WO2015/152153A, and the compound described in WO2017/051680A.

Specific examples of the oxime compound include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-(4-toluenesulfonyloxy)iminobutan-2-one, and 2-ethoxycarbonyloxyimino-1-phenylpropan-1-one.

Examples of the commercially available product of the oxime compound include IRGACURE-OXE01, IRGACURE-OXE02, IRGACURE-OXE03, and IRGACURE-OXE04 (all, manufactured by BASF SE), TRONLY TR-PBG-304, TRONLY TR-PBG-309, and TRONLY TR-PBG-305 (manufactured by CHANGZHOU TRONLY NEW ELECTRONIC MATERIALS CO., LTD.), ADEKA ARKLS NCI-930, ADEKA ARKLS NCI-831, and ADEKA OPTOMER N-1919 (the photopolymerization initiator 2 of JP2012-14052A) (all, manufactured by ADEKACorporation), and Omnirad-1312, Omnirad-1313, and Omnirad-1314 (all, manufactured by IGM Resins B.V.).

In addition, examples of the oxime compound other than those described above include the compound described in JP2009-519904A, in which an oxime is linked to the N position of a carbazole ring; the compound described in U.S. Pat. No. 7,626,957B, in which a hetero substituent is introduced at a benzophenone moiety; the compounds described in JP2010-015025A and US2009/292039A, in which a nitro group is introduced into a dye moiety; the ketooxime compound described in WO2009/131189A; the compound described in U.S. Pat. No. 7,556,910B, which contains a triazine skeleton and an oxime skeleton in the same molecule; and the compound described in JP2009-221114A, which has the absorption maximum at a wavelength of 405 nm and has good sensitivity to a g-line light source.

An oxime compound having a fluorene ring may be used as the photopolymerization initiator. Specific examples of the oxime compound having a fluorene ring include the compound described in JP2014-137466A. The content thereof is incorporated in the present specification.

An oxime compound having a benzofuran skeleton may be used as the photopolymerization initiator. Specific examples thereof include the compounds OE-01 to OE-75 described in WO2015/036910A.

As the photopolymerization initiator, an oxime compound having a skeleton in which at least one benzene ring of the carbazole ring is a naphthalene ring may be used. Examples of such an oxime compound include the compound disclosed in WO2013/083505A.

An oxime compound having a fluorine atom may be used as the photopolymerization initiator. Examples of the oxime compound having a fluorine atom include the compound described in JP2010-262028A, the compounds 24 and 36 to 40 described in JP2014-500852A, and the compound (C-3) described in JP2013-164471A. The content thereof is incorporated in the present specification.

An oxime compound having a nitro group can be used as the photopolymerization initiator. It is also preferable that the oxime compound having a nitro group is a dimer. Examples of the oxime compound having a nitro group include the compounds described in paragraphs 0031 to 0047 of JP2013-114249A and paragraphs 0008 to 0012 and 0070 to 0079 of JP2014-137466A, the compounds described in paragraphs 0007 to 0025 of JP4223071B, and ADEKA ARKLS NCI-831 (manufactured by ADEKA Corporation).

Specific examples of the oxime compound are shown below.

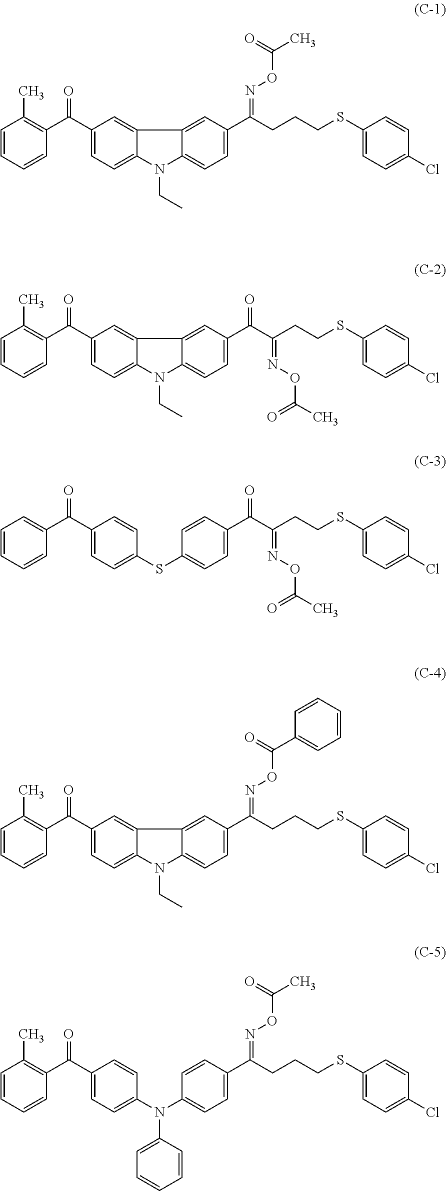 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1]

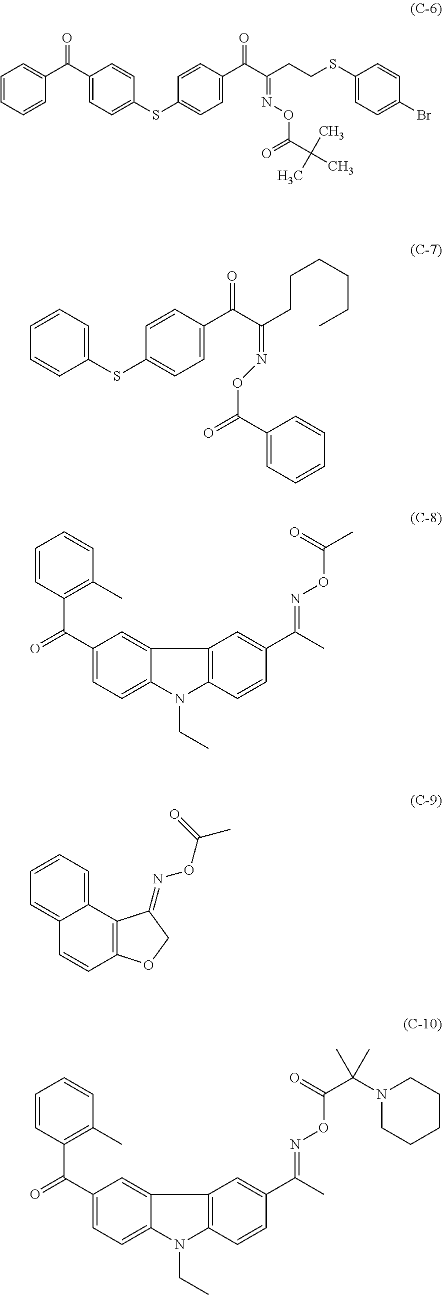 [SMILES: CC(C)(C)C(=O)O/N=C(\CCSc1ccc(Br)cc1)C(=O)c1ccc(Sc2ccc(C(=O)c3ccccc3)cc2)cc1 ; CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21]

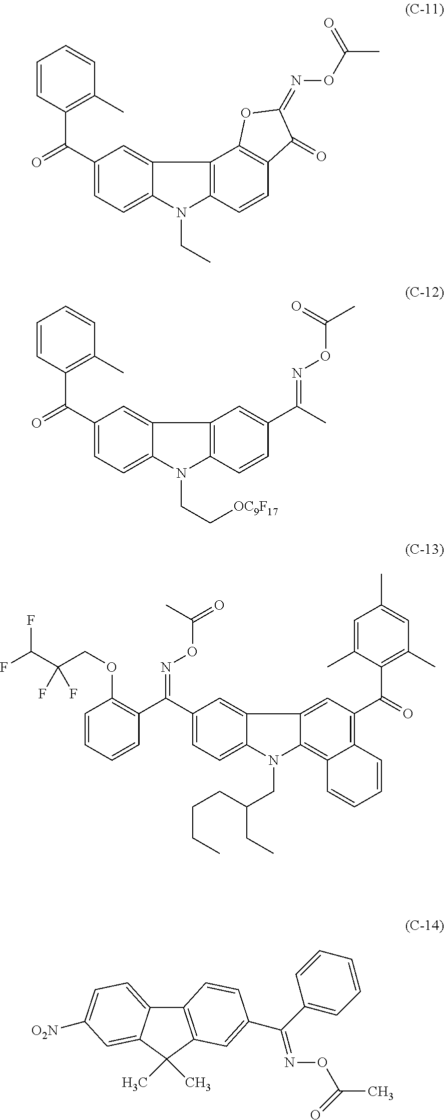

The oxime compound is preferably a compound having a maximal absorption wavelength in a wavelength range of 350 to 500 nm and more preferably a compound having a maximal absorption wavelength in a wavelength range of 360 to 480 nm. In addition, the oxime compound is preferably a compound having high absorbance at wavelengths of 365 nm and 405 nm.

From the viewpoint of sensitivity, the molar absorption coefficient of the oxime compound at a wavelength of 365 nm or 405 nm is preferably 1,000 to 300,000 mol⁻¹·L·cm⁻¹, more preferably 2,000 to 300,000 mol⁻¹·L·cm⁻¹, and still more preferably 5,000 to 200,000 mol⁻¹·L·cm⁻¹. The molar absorption coefficient of a compound can be measured using a known method. For example, a method of carrying out measurement at a concentration of 0.01 g/L using an ethyl acetate solvent with an ultraviolet-visible spectrophotometer (Cary-5 spectrophotometer manufactured by Varian Medical Systems, Inc.) can be mentioned.

As the photopolymerization initiator, a bifunctional or trifunctional or higher functional photopolymerization initiator may be used. Specific examples of such a photopolymerization initiator include dimers of the oxime compounds described in JP2010-527339A, JP2011-524436A, WO2015/004565A, paragraphs 0412 to 0417 of JP2016-532675A, and paragraphs 0039 to 0055 of WO2017/033680A, as well as the compound (E) and the compound (G) described in JP2013-522445A and Cmpd 1 to 7 described in WO2016/034963A.

One kind of photopolymerization initiator may be used alone, or two or more kinds thereof may be used.

In a case where the photopolymerization initiator is contained in the composition, the content thereof is preferably 0.1% to 50% by mass, more preferably 0.5% to 30% by mass, and still more preferably 1% to 20% by mass, with respect to the total solid content of the composition.

[Polymerization Inhibitor]

The composition may contain a polymerization inhibitor from the viewpoint of storage stability.

Examples of the polymerization inhibitor include 2,2,6,6-tetramethylpiperidine-1-oxyl, 4-hydroxy-2,2,6,6-tetramethylpiperidine-1-oxyl, hydroquinone, p-methoxyphenol, di-tert-butyl-p-cresol, pyrogallol, tert-butyl catechol, benzoquinone, 4,4′-thiobis(3-methyl-6-tert-butylphenol), 2,2′-methylenebis(4-methyl-6-tert-butylphenol), and an N-nitrosophenylhydroxyamine salt (an ammonium salt, a primary cerium salt, or the like).

From the viewpoint of storage stability, a compound having an N-oxyl radical structure is also preferable.

In addition, from the viewpoint of curability and pattern shape, the polymerization inhibitor may be a compound that does not have an aromatic ring.

It is noted that the polymerization inhibitor may also function as an antioxidant.

From the viewpoint of curability and pattern shape, the molecular weight of the polymerization inhibitor is preferably 200 or less, more preferably 180 or less, still more preferably 160 or less, and particularly preferably 120 or more and 160 or less.

One kind of polymerization inhibitor may be used alone, or two or more kinds thereof may be used.

In a case where the polymerization inhibitor is contained in the composition, the content thereof is preferably 0.00001% to 1% by mass, more preferably 0.0001% to 0.5% by mass, and still more preferably 0.001% to 0.1% by mass, with respect to the total solid content of the composition.

[Polymerizable Compound]

The composition may contain a polymerizable compound.

The polymerizable compound is a compound different from the specific resin.

The polymerizable compound that can be used in the present specification is preferably an ethylenically unsaturated compound (a compound having an ethylenically unsaturated group such as a (meth)acryloyl group, a vinyl group, and/or a styryl group), and more preferably a compound having a terminally ethylenically unsaturated group (a (meth)acryloyl group, a vinyl group, or a styryl group).

The polymerizable compound preferably has one or more ethylenically unsaturated groups, more preferably 2 to 10 ethylenically unsaturated groups, and still more preferably 3 to 6 ethylenically unsaturated groups.

As such a compound group, known compounds can be used without particular limitation.

The polymerizable compound may be, for example, a monomer, a prepolymer (a dimer, a trimer, an oligomer, or the like), or a mixture or copolymer thereof.

Examples of the monomer and the copolymer thereof include unsaturated carboxylic acids (for example, acrylic acid, methacrylic acid, itaconic acid, crotonic acid, isocrotonic acid, and maleic acid), and esters and amides thereof.

Among them, the polymerizable compound is preferably an ester of an unsaturated carboxylic acid and an aliphatic polyhydric alcohol compound, or amides of an unsaturated carboxylic acid and an aliphatic polyvalent amine compound.

In addition, examples of the polymerizable compound also include addition reaction products between unsaturated carboxylic acid esters or amides, having a nucleophilic substituent such as a hydroxyl group, an amino group, or a mercapto group, and monofunctional or polyfunctional isocyanates or epoxy compounds; and dehydration condensation reaction products between unsaturated carboxylic acid esters or amides, having a nucleophilic substituent such as a hydroxyl group, an amino group, or a mercapto group, and a monofunctional or polyfunctional carboxylic acid.

Examples of the polymerizable compound also include addition reaction products between unsaturated carboxylic acid esters or amides, having an electrophilic substituent such as an isocyanate group or an epoxy group, and monofunctional or polyfunctional alcohols, amines, or thiols; and substitution reaction products between unsaturated carboxylic acid esters or amides, having an eliminable substituent such as a halogen group or a tosyloxy group, and monofunctional or polyfunctional alcohols, amines, or thiols.

In addition, for example, a compound group in which the unsaturated carboxylic acid is replaced with unsaturated phosphonic acid, styrene, vinyl ether, or the like may be used as the polymerizable compound.

Examples of the ester of the aliphatic polyhydric alcohol compound and the unsaturated carboxylic acid include ethylene glycol diacrylate, triethylene glycol diacrylate, 1,3-butanediol diacrylate, tetramethylene glycol diacrylate, propylene glycol diacrylate, neopentyl glycol diacrylate, trimethylolpropane triacrylate, trimethylolpropanetri(acryloyloxypropyl)ether, trimethylolethane triacrylate, hexanediol diacrylate, 1,4-cyclohexanediol diacrylate, tetraethylene glycol diacrylate, pentaerythritol diacrylate, pentaerythritol triacrylate, pentaerythritol tetraacrylate, dipentaerythritol diacrylate, dipentaerythritol pentaacrylate, dipentaerythritol hexaacrylate, sorbitol triacrylate, sorbitol tetraacrylate, sorbitol pentaacrylate, sorbitol hexaacrylate, tri(acryloyloxyethyl)isocyanurate, a polyester acrylate oligomer, isocyanuric acid EO-modified triacrylate, tetramethylene glycol dimethacrylate, triethylene glycol dimethacrylate, neopentyl glycol dimethacrylate, trimethylolpropane trimethacrylate, trimethylolethane trimethacrylate, ethylene glycol dimethacrylate, 1,3-butanediol dimethacrylate, hexanediol dimethacrylate, pentaerythritol dimethacrylate, pentaerythritol trimethacrylate, pentaerythritol tetramethacrylate, dipentaerythritol dimethacrylate, dipentaerythritol pentamethacrylate, dipentaerythritol hexamethacrylate, sorbitol trimethacrylate, sorbitol tetramethacrylate, bis[p-(3-methacryloxy-2-hydroxypropoxy)phenyl]dimethylmethane, and bis-[p-(methacryloxyethoxy)phenyl]dimethylmethane.

Further, as the polymerizable compound, it is also possible to use, for example, a urethane-based addition polymerizable compound produced by using an addition reaction between an isocyanate and a hydroxyl group. Specifically, examples thereof include a vinyl urethane compound having two or more polymerizable vinyl groups in one molecule, which is obtained by adding a vinyl monomer having a hydroxyl group, represented by Formula (I), to a polyisocyanate compound having two or more isocyanate groups in one molecule, which is described in JP1973-41708B (JP-S48-41708B).

CH₂═C(R)COOCH₂CH(R′)OH (I)

(Here, R and R′ represent H or CH₃.)

In addition, as the polymerizable compound, it is also possible to use the urethane acrylates as described in JP1976-37193A (JP-S51-37193A), JP1990-32293B (JP-H2-32293B), and JP1990-16765B (JP-H2-16765B); the urethane compounds having an ethylene oxide-based skeleton, which are described in the respective publications of JP1983-49860B (JP-S58-49860B), JP1981-17654B (JP-S56-17654B), JP1987-39417B (JP-S62-39417B), and JP-1987-39418B (JP-S62-39418B); and the addition polymerizable compounds having an amino structure or a sulfide structure in a molecule, which are described in JP1988-277653A (JP-S63-277653A), JP1988-260909A (JP-S63-260909A), and JP1989-105238A (JP-H1-105238A).

Examples of the polymerizable compound include the compounds described in paragraphs 0178 to 0190 of JP2007-277514A.

Among the above, the polymerizable compound is preferably a compound represented by Formula (Z-6).

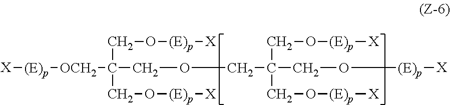

In Formula (Z-6), E's each independently represent —(CH₂)_{y}—CH₂—O—, —(CH₂)_{y}—CH(CH₃O—, —(CH₂)_{y}—CH₂—CO—O—, —(CH₂)_{y}—CH(CH₃)CO—O—, —CO—(CH₂)_{y}—CH₂—O—, —CO—(CH₂)_{y}—CH(CH₃O—, —CO—(CH₂)_{y}—CH₂—CO—O—, or —CO—(CH₂)_{y}—CH(CH₃)—CO—O—. In these groups, the bonding position on the right side is preferably a bonding position on the X side.
y's each independently represent an integer of 1 to 10.
X's each independently represent a (meth)acryloyl group or a hydrogen atom.
p's each independently represent an integer of 0 to 10.
q represents an integer of 0 to 3.

In Formula (Z-6), the total number of (meth)acryloyl groups is preferably (3+2 q) or (4+2 q).
p is preferably an integer of 0 to 6 and more preferably an integer of 0 to 4.

The total of each p is preferably 0 to (40+20 q), more preferably 0 to (16+8 q), and still more preferably 0 to (12+6 q).

In addition to those described above, a compound in which q in Formula (Z-6) is 0 and one of four groups represented by “—O-(E)ₚ-X” is replaced with a methyl group may be used as the polymerizable compound.

The molecular weight of the polymerizable compound (the weight-average molecular weight in a case having a molecular weight distribution) is preferably 80 or more and less than 1,000.

In a case where the polymerizable compound is contained in the composition, the content thereof is preferably 1% to 90% by mass, more preferably 5% to 50% by mass, and still more preferably 15% to 35% by mass, with respect to the total solid content of the composition.

[Surfactant]

The composition may contain a surfactant.

The surfactant contributes to the improvement in the coatability of the composition.

Examples of the surfactant include a fluorine-based surfactant, a nonionic surfactant, a cationic surfactant, an anionic surfactant, and a silicone-based surfactant.

Examples of the fluorine-based surfactant include MEGAFACE F171, MEGAFACE F172, MEGAFACE F173, MEGAFACE F176, MEGAFACE F177, MEGAFACE F141, MEGAFACE F142, MEGAFACE F143, MEGAFACE F144, MEGAFACE R30, MEGAFACE F437, MEGAFACE F475, MEGAFACE F479, MEGAFACE F482, MEGAFACE F554, MEGAFACE F780, and MEGAFACE F781F (all, produced by DIC Corporation); FLUORAD FC430, FLUORAD FC431, and FLUORAD FC171 (all, produced by Sumitomo 3M Limited); SURFLON S-382, SURFLON SC-101, SURFLON SC-103, SURFLON SC-104, SURFLON SC-105, SURFLON SC 1068, SURFLON SC-381, SURFLON SC-383, SURFLON S 393, and SURFLON KH-40 (all, produced by ASAHI GLASS CO., LTD.); and PF636, PF656, PF6320, PF6520, and PF7002 (produced by OMNOVA Solutions Inc.).

As the fluorine-based surfactant, a block polymer can also be used, and specific examples thereof include the compound described in JP2011-89090A.

Examples of the silicone-based surfactant include KF-6001 (manufactured by Shin-Etsu Chemical Co., Ltd.) and BYK-333 (manufactured by BYK Japan KK).

One kind of surfactant may be used alone, or two or more kinds thereof may be used.

In a case where the surfactant is contained in the composition, the content thereof is preferably 0.001% to 20% by mass, more preferably 0.003% to 15% by mass, and still more preferably 0.005% to 10% by mass, with respect to the total solid content of the composition.

[Solvent]

The composition contains a solvent.

Examples of the solvent include water and an organic solvent.

Examples of the organic solvent include acetone, methyl ethyl ketone, cyclohexane, ethyl acetate, ethylene dichloride, tetrahydrofuran, toluene, ethylene glycol monomethyl ether, ethylene glycol monoethyl ether, ethylene glycol dimethyl ether, propylene glycol monomethyl ether, propylene glycol monoethyl ether, acetyl acetone, cyclohexanone, cyclopentanone, diacetone alcohol, ethylene glycol monomethyl ether acetate, ethylene glycol ethyl ether acetate, ethylene glycol monoisopropyl ether, ethylene glycol monobutyl ether acetate, 3-methoxypropanol, methoxymethoxy ethanol, diethylene glycol monomethyl ether, diethylene glycol monoethyl ether, diethylene glycol dimethyl ether, diethylene glycol diethyl ether, propylene glycol monomethyl ether acetate, propylene glycol monoethyl ether acetate, 3-methoxypropyl acetate, N,N-dimethylformamide, dimethyl sulfoxide, γ-butyrolactone, butyl acetate, methyl lactate, N-methyl-2-pyrrolidone, and ethyl lactate.

One kind of the solvent may be used alone, or two or more kinds thereof may be used.

The content of the solvent is preferably an amount such that the total solid content of the composition is 10% to 90% by mass, more preferably an amount such that the solid content is 15% to 80% by mass, and still more preferably an amount such that the solid content is 20% to 50% by mass.

The content of the solvent is preferably 10% to 90% by mass, more preferably 20% to 85% by mass, and still more preferably 50% to 80% by mass, with respect to the total mass of the composition.

[Other Components]

The composition may contain other components other than those described above.

Examples of the other components include a dye, a sensitizing agent, a co-sensitizer, a fluorine-based organic compound, a filler other than the pigment, an adhesion accelerator, an antioxidant, an ultraviolet absorbing agent, and an aggregation inhibitor.

[Production Method for Composition]

A preparation method for the composition is not particularly limited, and the composition can be obtained, for example, by mixing each component contained in the composition by a known method.

For example, the composition may be obtained as a pigment dispersion liquid in which a pigment, a specific resin, a solvent, a dispersion aid to be added as desired, a polymerization inhibitor to be added as desired, and the like are mixed.

In addition, in a case where the composition contains an additional component in addition to the components contained in the pigment dispersion liquid, the composition may be prepared by adding the additional component to the pigment dispersion liquid, followed by mixing. As the additional component, a pigment, a specific resin, a solvent, a dispersion aid, and/or a polymerization inhibitor, which are different from those contained in the pigment dispersion liquid, may be further added.

In addition, for the purpose of removing foreign substances, reducing defects, or the like, the composition or a component to be used in the preparation of the composition may be filtered through a filter. Regarding the filter, any filter can be used without particular limitation as long as it is used in the related art for the filtration use applications or the like.

[Manufacturing of Cured Film]

A composition layer formed from the composition according to the embodiment of the present invention is cured to obtain a cured film (including a patterned cured film).

The manufacturing method for a cured film is not particularly limited; however, it preferably includes the following steps.
Composition layer forming step
Exposure step
Development step

Hereinafter, each step will be described.

[Composition Layer Forming Step]

In the composition layer forming step, prior to exposure, the composition is applied on a support or the like to form a layer (composition layer) of the composition. As the support, it is possible to use, for example, a substrate (for example, a substrate containing an Si atom such as a silicon substrate or a glass substrate) or a substrate for a solid-state imaging element on which an imaging element (a light-receiving element) such as a CCD or CMOS is provided on the substrate. In addition, in order to improve adhesion with the upper layer, prevent the diffusion of substances, and planarize the surface of the substrate, an undercoat layer may be provided on the support, as needed.

As a method for applying the composition onto the support, for example, various coating methods such as a slit coating method, an ink jet method, a spin coating method, a cast coating method, a roll coating method, and a screen printing method can be applied. The film thickness of the composition layer in a dry state is preferably 0.1 to 10 m, more preferably 0.2 to 5 μm, and still more preferably 0.2 to 3 μm. The composition layer applied on the support can be dried (pre-baked) at a temperature of 50° C. to 140° C. for 10 to 300 seconds using a hot plate, an oven, or the like.

[Exposure Step]

In the exposure step, the composition layer (the dried film) formed in the composition layer forming step is exposed by irradiation with actinic rays or radiation, and the composition layer irradiated with light is cured.

In the method of light irradiation, it is preferable to carry out light irradiation through a photo mask having a patterned opening portion.

The exposure is preferably carried out by irradiation with radiation. The radiation, which can be used during the exposure, is preferably ultraviolet rays such as a g-line, an h-line, or an i-line, and a light source is preferably a high-pressure mercury lamp. The irradiation intensity is preferably 5 to 1,500 mJ/cm² and more preferably 10 to 1,000 mJ/cm².

In a case where the composition contains a thermal polymerization initiator, the composition layer may be heated in the above exposure step. The heating temperature is not particularly limited; however, it is preferably 80° C. to 250° C. In addition, the heating time is preferably 30 to 300 seconds.

It is noted that in a case where the composition layer is heated in the exposure step, the exposure step may serve as a post-heating step which will be described later. In other words, in a case where the composition layer is heated in the exposure step, the method of manufacturing a cured film may not include the post-heating step.

[Development Step]

The development step is a step of developing the exposed composition layer to form a cured film. By this step, the composition layer in a portion which is not irradiated with light in the exposure step is eluted, only a photo-cured portion remains, and thus a patterned cured film can be obtained.

The kind of developer used in the development step is not particularly limited; however, an alkali developer which does not damage the underlying imaging element and circuit or the like is desirable.

The development temperature is, for example, 20° C. to 30° C.

The development time is, for example, 20 to 90 seconds. In order to more efficiently remove the residues, in recent years, the development may be carried out for 120 to 180 seconds. Furthermore, in order to further improve residue removability, a step of shaking off the developer every 60 seconds and further supplying a fresh developer may be repeated several times.

The alkali developer is preferably an alkaline aqueous solution which is prepared by dissolving an alkaline compound in water so that the concentration thereof is 0.001% to 10% by mass (preferably 0.01% to 5% by mass).

Examples of the alkaline compound include sodium hydroxide, potassium hydroxide, sodium carbonate, sodium silicate, sodium metasilicate, aqueous ammonia, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among them, an organic base is preferable).

It is noted that in a case where the alkaline compound is used as an alkali developer, the alkaline compound is generally subjected to a washing treatment with water after development.

[Post-Baking]

It is also preferable to carry out a heating treatment (post-baking) after the exposure step. The post-baking is a heating treatment after development for completing the curing. The heating temperature is preferably 240° C. or lower and more preferably 220° C. or lower. The lower limit thereof is not particularly limited; however, it is preferably 50° C. or more and more preferably 100° C. or more, in consideration of efficient and effective treatment.

The post-baking can be carried out continuously or batchwise by using a heating unit such as a hot plate, a convection oven (hot-air circulating dryer), and a high frequency heater.

It is also preferable to carrying out post-baking in an atmosphere of a low oxygen concentration. The oxygen concentration is preferably 19% by volume or less, more preferably 15% by volume or less, still more preferably 10% by volume or less, particularly preferably 7% by volume or less, and most preferably 3% by volume or less. The lower limit thereof is not particularly limited; however, it is practically equal to or higher than 10 ppm by volume.

In addition, the curing may be completed by ultraviolet (UV) irradiation instead of the post-baking with heating described above.

In this case, the composition described above preferably further contains a UV curing agent. The UV curing agent is preferably a UV curing agent which can be cured at a wavelength shorter than 365 nm which is an exposure wavelength of a polymerization initiator added for a lithography step by ordinary i-line exposure. Examples of the UV curing agent include Omnirad 2959 manufactured by IGM Resins B.V. In a case where UV irradiation is carried out, the composition layer is preferably a material which is cured at a wavelength of 340 nm or less. The lower limit value of the wavelength is not particularly limited; however, it is generally 220 nm or more. In addition, the exposure amount of the UV irradiation is preferably 100 to 5,000 mJ/cm², more preferably 300 to 4,000 mJ/cm², and still more preferably 800 to 3,500 mJ/cm². The UV curing step is preferably carried out after the exposure step, in order to more effectively carry out low-temperature curing. As an exposure light source, an ozoneless mercury lamp is preferably used.

[Physical Properties of Cured Film and Application of Cured Film]

[Physical Properties of Cured Film]

In the cured film formed from the composition according to the embodiment of the present invention, the optical density (OD) per 1.5 μm film thickness in a wavelength range of 400 to 1,100 nm is preferably 2.0 or more and more preferably 3.0 or more. It is noted that although the upper limit value thereof is not particularly limited, it is, in general, preferably 10 or less.

In a case where the optical density is 2.0 or more, it can be said that the cured film formed from the composition has a high color value.

It is noted that in the present specification, the description that the optical density per film thickness of 1.5 μm in a wavelength range of 400 to 1,100 nm is 2.0 or more means that an optical density per film thickness of 1.5 μm in the entire wavelength range of 400 to 1,200 nm is 2.0 or more.

In addition, the cured film (the light shielding film) preferably has good light shielding properties against light in the infrared region, and the optical density per film thickness of 1.5 μm in the light having a wavelength of 940 nm is preferably more than 2.0 and more preferably more than 3.0. It is noted that although the upper limit value thereof is not particularly limited, it is, in general, preferably 10 or less.

By the way, even in the state of the composition layer (the dried film) in which the composition is applied and dried, the film thickness and the optical density generally do not change significantly as compared with the state of the cured film which has been subsequently exposed and cured. In such a case, the optical density of the composition layer (the dried film) may be measured by the above-described measuring method, and the obtained value may be used as the optical density of the cured film.

The film thickness of the cured film is preferably 0.1 to 4.0 μm and more preferably 1.0 to 2.5 μm. The cured film may be thinner or thicker than the above range depending on the application.

The reflectivity of the cured film is preferably lower than 8%, more preferably lower than 6%, and still more preferably lower than 4%. The lower limit thereof is 0% or more.

The reflectivity mentioned here is obtained from the reflectivity spectrum obtained by causing light having a wavelength of 400 to 1,100 nm to be incident at an incidence angle of 5° using a VAR unit of a spectrometer V7200 (product name) manufactured by JASCO Corporation. Specifically, the reflectivity of light having a wavelength at which the maximum reflectivity is exhibited in a wavelength range of 400 to 1,100 nm is taken as the reflectivity of the cured film.

In addition, the cured film is suitable for a light shielding member and a light shielding film as well as an antireflection member and an antireflection film of an optical filter and a module that are used in portable instruments such as a personal computer, a tablet PC, a mobile phone, a smartphone, and a digital camera; office automation (OA) instruments such as a printer composite machine and a scanner; industrial instruments such as a surveillance camera, a barcode reader, an automated teller machine (ATM), a high-speed camera, and an instrument having a personal authentication function using face image authentication or biometric authentication; in-vehicle camera instruments; medical camera instruments such as an endoscope, a capsule endoscope, and a catheter; and a biological sensor, a biosensor, a military reconnaissance camera, a camera for a three-dimensional map, a camera for observing weather and sea, a camera for a land resource exploration, and space instruments such as an exploration camera for the astronomy of the space and a deep space target.

The cured film can also be used in use applications to a micro light emitting diode (LED), a micro organic light emitting diode (OLED), and the like. The cured film is suitable for an optical filter and an optical film which are used in the micro LED and the micro OLED as well as a member which imparts a light shielding function or an antireflection function. Examples of the micro LED and the micro OLED include the examples described in JP2015-500562A and JP2014-533890A.

The cured film is also suitable as an optical film used in a quantum dot sensor and a quantum dot solid-state imaging element. Moreover, the cured film is suitable as a member which imparts a light-shielding function or an antireflection function. Examples of the quantum dot sensor and the quantum dot solid-state imaging element include the examples described in US2012/37789A and WO2008/131313A.

[Light Shielding Film, Optical Element, Solid-State Imaging Element, and Solid-State Imaging Device]

It is also preferable that the cured film according to the embodiment of the present invention is used as a so-called light shielding film. It is also preferable that such a light shielding film is used in a solid-state imaging element.

As described above, the cured film formed from the light shielding composition according to the embodiment of the present invention has excellent light shielding properties and low reflection properties.

Furthermore, the light shielding film is one of the preferable applications in the cured film according to the embodiment of the present invention, and the light shielding film according to the embodiment of the present invention can be manufactured in the same manner as the method of manufacturing a cured film. Specifically, a light shielding film can be manufactured by applying the composition to a substrate to form a composition layer and carrying out exposure and development on the composition layer.

The present invention also includes an invention of an optical element. The optical element according to the embodiment of the present invention is an optical element including the above-described cured film (light shielding film). Examples of the optical element include an optical element that is used in an optical instrument such as a camera, binoculars, a microscope, and a semiconductor exposure device.

Among them, as the optical element, a solid-state imaging element mounted on a camera or the like is preferable.

In addition, the solid-state imaging element according to the embodiment of the present invention is a solid-state imaging element including the cured film (light shielding film) according to the embodiment of the present invention.

Examples of the form in which the solid-state imaging element according to the embodiment of the present invention includes the cured film (the light shielding film) include a form in which a plurality of photodiodes and light-receiving elements consisting of polysilicon or the like, which constitute a light-receiving area of a solid-state imaging element (a CCD image sensor, a CMOS image sensor, or the like), are provided on a substrate, and the cured film is provided on a surface side (for example, a portion other than light-receiving parts and/or pixels for adjusting color) of a support on which the light-receiving elements are formed or on a side opposite to the surface on which the light-receiving elements are formed.

The solid-state imaging device is equipped with the above-described solid-state imaging element.

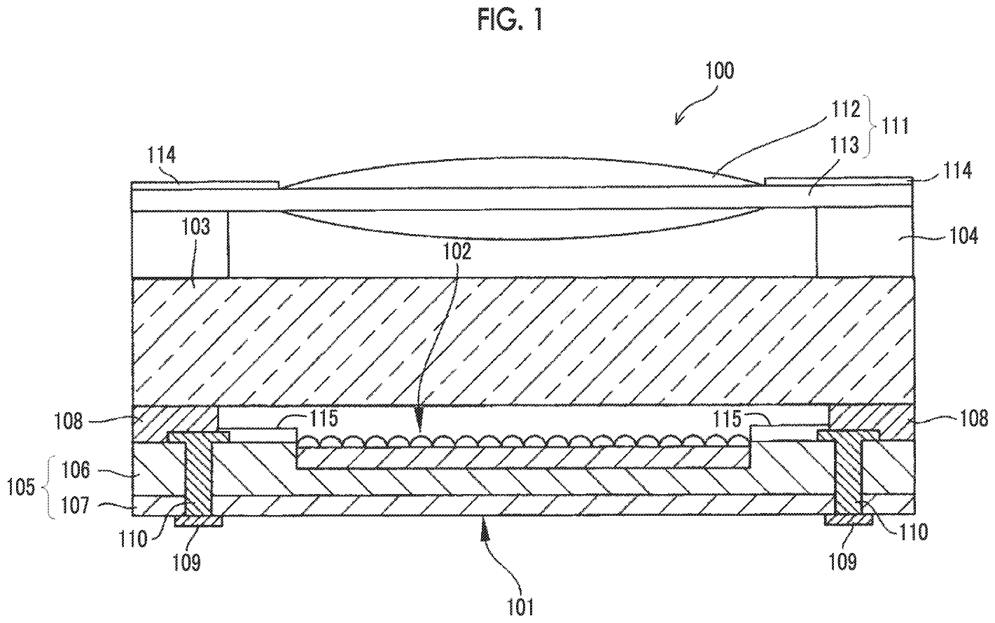

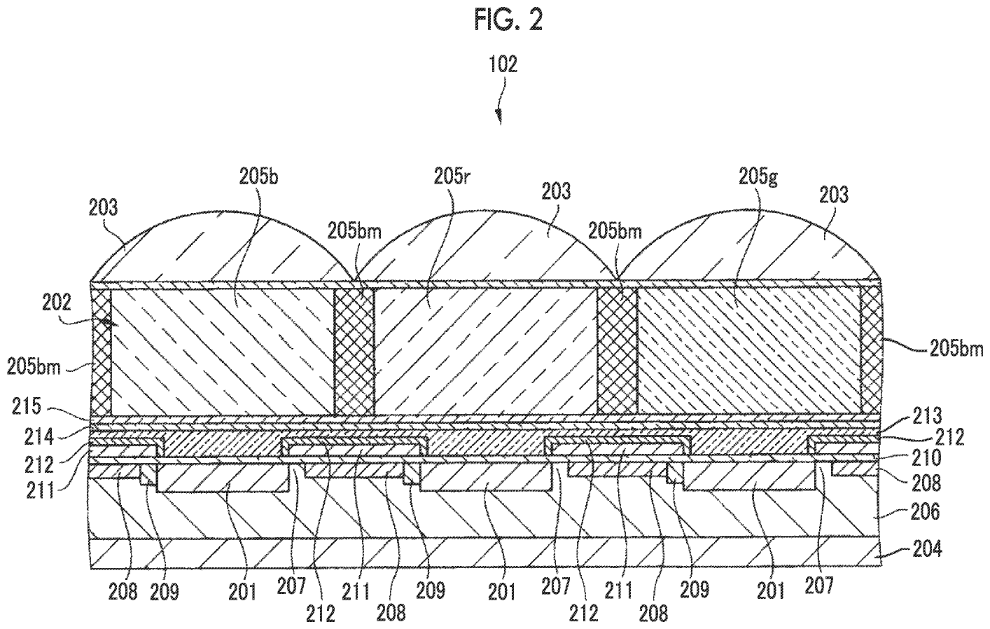

Examples of the configurations of the solid-state imaging device and the solid-state imaging element will be described with reference to FIGS. 1 and 2. In FIGS. 1 and 2, some parts are magnified in disregard of the thickness ratio and/or the width ratio between the parts so that the respective parts are clearly displayed.

FIG. 1 is a schematic cross-sectional view illustrating an example of the configuration of the solid-state imaging device including the solid-state imaging element according to the embodiment of the present invention.

As illustrated in FIG. 1, a solid-state imaging device 100 includes a rectangular solid-state imaging element 101 and a transparent cover glass 103 which is held above the solid-state imaging element 101 and seals the solid-state imaging element 101. Further, on the cover glass 103, a lens layer 111 is superposably provided through a spacer 104. The lens layer 111 includes a support 113 and a lens material 112. The lens layer 111 may have a configuration in which the support 113 and the lens material 112 are integrally formed. In a case where stray light is incident on the peripheral edge region of the lens layer 111, due to the diffusion of light, an effect of light condensation on the lens material 112 is weakened, and thus the light reaching an imaging unit 102 is reduced. In addition, noise is also generated due to the stray light. For this reason, a light shielding film 114 is provided in the peripheral edge region of the lens layer 111 so that light is shielded. The cured film according to the embodiment of the present invention can also be used as the light shielding film 114.

The solid-state imaging element 101 carries out photoelectric conversion on an optical image formed on the imaging unit 102 serving as a light-receiving surface of the solid-state imaging element 101, and outputs the converted optical image as an image signal. The solid-state imaging element 101 includes a laminated substrate 105 obtained by laminating two sheets of substrates. The laminated substrate 105 consists of a chip substrate 106 and a circuit board 107 which have the same size and a rectangular shape, and the circuit board 107 is laminated on the rear surface of the chip substrate 106.

As a material of the substrate used as the chip substrate 106, for example, known materials can be used.

The imaging unit 102 is provided in the central part of the surface of the chip substrate 106. In addition, a light shielding film 115 is provided in the peripheral edge region of the imaging unit 102. By shielding stray light incident on the peripheral edge region by the light shielding film 115, the generation of a dark current (noise) from a circuit in the peripheral edge region can be prevented. The cured film according to the embodiment of the present invention is preferably used as the light shielding film 115.

A plurality of electrode pads 108 are provided at an edge part of the surface of the chip substrate 106. The electrode pads 108 are electrically connected to the imaging unit 102 through a signal wire (a bonding wire can also be used) (not shown) provided on the surface of the chip substrate 106.

On the rear surface of the circuit board 107, external connection terminals 109 are provided at positions approximately below the electrode pads 108, respectively. The external connection terminals 109 are respectively connected to the electrode pads 108 through a through-electrode 110 vertically passing through the laminated substrate 105. Moreover, the external connection terminals 109 are connected to a control circuit controlling the driving of the solid-state imaging element 101, an image processing circuit carrying out image processing on an imaging signal output from the solid-state imaging element 101, and the like through a wiring line (not shown).

FIG. 2 shows a schematic cross-sectional view of the imaging unit 102. As illustrated in FIG. 2, the imaging unit 102 includes the parts, such as a light-receiving element 201, a color filter 202, and a micro lens 203, which are provided on a substrate 204. The color filter 202 has a blue pixel 205b, a red pixel 205r, a green pixel 205g, and a black matrix 205bm. The cured film according to the embodiment of the present invention may be used as the black matrix 205bm.

As the material of the substrate 204, for example, the same material as that of the chip substrate 106 can be used. On the surface layer of the substrate 204, a p-well layer 206 is formed. In the p-well layer 206, the light-receiving elements 201, which consist of an n-type layer and generate and accumulate signal charges by photoelectric conversion, are formed to be arranged in the form of square grids.

On one lateral side of each light-receiving element 201, through a reading gate part 207 on the surface layer of the p-well layer 206, a vertical electric charge transfer path 208 consisting of an n-type layer is formed. In addition, on the other lateral side of each light-receiving element 201, through an element separation region 209 consisting of a p-type layer, a vertical electric charge transfer path 208 belonging to the adjacent pixel is formed. The reading gate part 207 is a channel region for the signal charges accumulated in the light-receiving element 201 to be read out toward the vertical electric charge transfer path 208.

On the surface of the substrate 204, a gate insulating film 210 consisting of an oxide-nitride-oxide (ONO) film is formed. On the gate insulating film 210, vertical electric charge transfer electrodes 211 consisting of polysilicon or amorphous silicon are formed to cover the portions which are approximately immediately above the vertical electric charge transfer path 208, the reading gate part 207, and the element separation region 209. The vertical electric charge transfer electrodes 211 function as driving electrodes for driving the vertical electric charge transfer path 208 and carrying out charge transfer, and as reading electrodes for driving the reading gate part 207 and reading out signal charges. The signal charges are transferred to a horizontal electric charge transfer path and an output part (floating diffusion amplifier), which are not shown in the drawing, in this order from the vertical electric charge transfer path 208, and then output as voltage signals.

On each of the vertical electric charge transfer electrodes 211, a light shielding film 212 is formed to cover the surface of the electrode. The light shielding film 212 has an opening portion at a position immediately above the light-receiving element 201 and shields a region other than the opening portion from light. The cured film according to the embodiment of the present invention may be used as the light shielding film 212.

On the light shielding film 212, a transparent interlayer, which consists of an insulating film 213 consisting of borophosphosilicate glass (BPSG), an insulating film (passivation film) 214 consisting of P—SiN, and a planarization film 215 consisting of a transparent resin or the like, is provided. The color filter 202 is formed on the interlayer.

[Image Display Device]

An image display device according to the embodiment of the present invention is equipped with the cured film according to the embodiment of the present invention.

Examples of the form in which the image display device includes a cured film include a form in which a cured film is used as a black matrix and a color filter including such a black matrix is used in an image display device.

<Black Matrix>

It is also preferable that the cured film according to the embodiment of the present invention is contained in the black matrix. The black matrix may be included a color filter, a solid-state imaging element, and an image display device such as a liquid crystal display device in some cases.

Examples of the black matrix include those described above; a black rim provided in the peripheral edge part of an image display device such as a liquid crystal display device; a lattice-formed and/or stripe-like black portion between pixels of red, blue, and green; and a dot-like and/or linear black pattern for shielding a thin film transistor (TFT) from light. The definition of the black matrix is described in, for example, “Glossary of liquid crystal display manufacturing device”, written by Yasuhira KANNO, 2nd edition, NIKKAN KOGYO SHIMBUN, LTD., 1996, p. 64.

In order to improve the display contrast, and to prevent image quality deterioration resulting from current leakage of light in a case of an active matrix driving-type liquid crystal display device using a thin film transistor (TFT), the black matrix preferably has high light shielding properties (the optical density OD is equal to or higher than 3).

As the method of manufacturing the black matrix, for example, the black matrix can be manufactured in the same manner as the method of manufacturing the cured film. Specifically, by applying the composition onto a substrate to form a composition layer and carrying out exposure and development on the composition layer, a patterned cured film (a black matrix) can be manufactured. Moreover, the film thickness of the cured film used as the black matrix is preferably 0.1 to 4.0 μm.

The material of the substrate preferably has a light transmittance equal to or greater than 80% for visible light (wavelength of 400 to 800 nm). Examples of such a material include: glass such as soda lime glass, alkali-free glass, quartz glass, and borosilicate glass; and plastic such as a polyester-based resin and a polyolefin-based resin, and from the viewpoints of chemical resistance and heat resistance, alkali-free glass, quartz glass, or the like is preferable.

<Color Filter>

It is also preferable that the cured film according to the embodiment of the present invention is included in a color filter.

Examples of the form in which the color filter includes the cured film include a color filter comprising a substrate and the above-described black matrix. That is, examples thereof include a color filter comprising colored pixels of red, green, and blue which are formed in the opening portion of the black matrix formed on a substrate.

The color filter including a black matrix (cured film) can be manufactured, for example, according to the following method.

First, in an opening portion of a patterned black matrix formed on a substrate, a coating film (composition layer) of a composition containing each of pigments corresponding to the respective colored pixels of the color filter is formed. It is noted that it is possible to use, for example, a known composition as the composition for each color. In addition, in the composition described in the present specification, it is also preferable to use, as the composition for each color, a composition containing a coloring agent (a pigment or the like) corresponding to each pixel.

Subsequently, the composition layer is subjected to exposure through a photo mask having a pattern corresponding to the opening portion of the black matrix. Next, colored pixels can be formed in the opening portion of the black matrix by removing non-exposed portions by a development treatment, and then carrying out baking. In a case where the series of operations are carried out using, for example, a composition for each color containing each of red, green, and blue pigments, a color filter having red, green, and blue pixels can be manufactured.

In addition, examples of another form in which the color filter includes a cured film include a color filter including a substrate, a black matrix, and colored pixels of red, green, and blue formed in an opening portion of the black matrix, where at least a part of the colored pixels is a cured film according to the embodiment of the present invention. In this case, the black matrix may be another one other than the cured film according to the embodiment of the present invention.

<Liquid Crystal Display Device>

It is also preferable that the cured film according to the embodiment of the present invention is included in a liquid crystal display device. Examples of the form in which the liquid crystal display device includes the cured film include a form in which a liquid crystal display device includes the color filter described above.

Examples of the liquid crystal display device according to the present embodiment include a form in which a liquid crystal display device comprises a pair of substrates disposed to face each other and a liquid crystal compound sealed in the space between the substrates. The substrates are as described above, for example, as the substrate for a black matrix.

Examples of a specific form of the liquid crystal display device include a laminate including polarizing plate/substrate/color filter/transparent electrode layer/alignment film/liquid crystal layer/alignment film/transparent electrode layer/thin film transistor (TFT) element/substrate/polarizing plate/backlight unit in this order from the user side.

It is noted that examples of the liquid crystal display device include the liquid crystal display devices described in “Electronic display device (written by Akio SASAKI, Kogyo Chosakai Publishing Co., Ltd., published in 1990)”, “Display device (written by Sumiaki IBUKI, Sangyo Tosho Publishing Co., Ltd., published in 1989)”, or the like. Moreover, examples thereof include the liquid crystal display device described in “Next-Generation Liquid Crystal Display Technology (edited by Tatsuo UCHIDA, Kogyo Chosakai Publishing Co., Ltd., published in 1994)”.

[Infrared Sensor]

It is also preferable that the cured film according to the embodiment of the present invention is included in an infrared sensor.

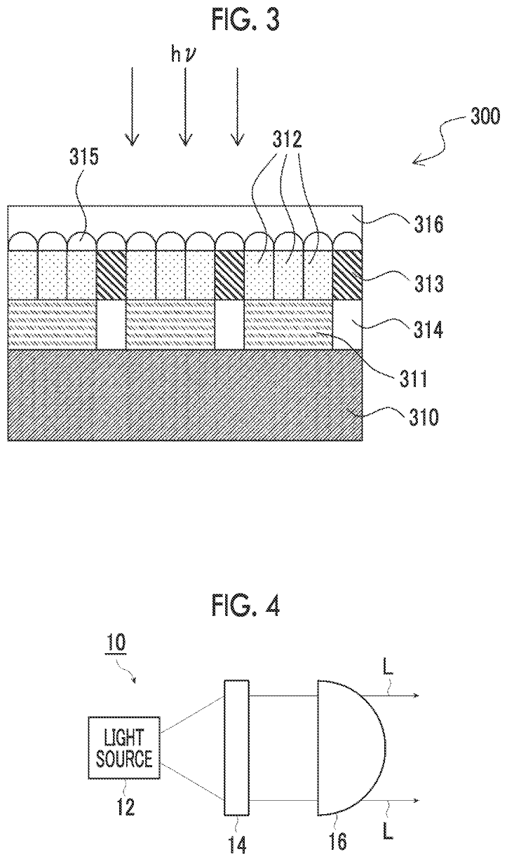

The infrared sensor according to the embodiment will be described with reference to FIG. 3. FIG. 3 is a schematic cross-sectional view illustrating an example of the configuration of an infrared sensor comprising the cured film according to the embodiment of the present invention. An infrared sensor 300 illustrated in FIG. 3 includes a solid-state imaging element 310.

An imaging region provided on the solid-state imaging element 310 is configured by combining an infrared absorption filter 311 and a color filter 312 according to the embodiment of the present invention.

The infrared absorption filter 311 is a film which transmits light (for example, light having a wavelength of 400 to 700 nm) in the visible light range and shields light (for example, light having a wavelength of 800 to 1,300 nm, preferably light having a wavelength of 900 to 1,200 nm, and more preferably light having a wavelength of 900 to 1,000 nm) in the infrared range, and a cured film containing an infrared absorbing agent (the form of the infrared absorbing agent is as described above) as a pigment can be used.

The color filter 312 is a color filter in which pixels transmitting or absorbing light having a specific wavelength in the visible light range are formed, for example, a color filter in which pixels of red (R), green (G), and blue (B) are formed, or the like is used, and the form thereof is as described above.

Between an infrared transmitting filter 313 and the solid-state imaging element 310, a resin film 314 (for example, a transparent resin film or the like), which is capable of transmitting light having the wavelength transmitted through the infrared transmitting filter 313, is disposed.

The infrared transmitting filter 313 is a filter which has visible light shielding properties and transmits infrared rays having a specific wavelength, and the cured film according to the embodiment of the present invention can be used, which contains a coloring agent (for example, a perylene compound and/or a bisbenzofuranone compound) absorbing light in a visible light range, and an infrared absorbing agent (for example, a pyrrolo pyrrole compound, a phthalocyanine compound, a naphthalocyanine compound, a polymethine compound, or the like). It is preferable that, for example, the infrared transmitting filter 313 shields light having a wavelength of 400 to 830 nm and transmits light having a wavelength of 900 to 1,300 nm.

On the incidence ray hv side of the color filter 312 and the infrared transmitting filter 313, micro lenses 315 are arranged. A planarization film 316 is formed to cover the micro lenses 315.

In the form illustrated in FIG. 3, the resin film 314 is disposed; however, the infrared transmitting filter 313 may be formed instead of the resin film 314. That is, on the solid-state imaging element 310, the infrared transmitting filter 313 may be formed.

In the form illustrated in FIG. 3, the film thickness of the color filter 312 is the same as the film thickness of the infrared transmitting filter 313, but both the film thicknesses may be different from each other.

In the form illustrated in FIG. 3, the color filter 312 is provided to be closer to the incidence ray hv side than the infrared absorption filter 311, but the order of the infrared absorption filter 311 and the color filter 312 may be switched so that the infrared absorption filter 311 is provided to be closer to the incidence ray hv side than the color filter 312.

In the form illustrated in FIG. 3, the infrared absorption filter 311 and the color filter 312 are laminated to be adjacent to each other, but both the filters are not necessarily adjacent to each other, and another layer may be provided between the filters. The cured film according to the embodiment of the present invention can be used as a light shielding film on an end part of the surface and/or a lateral surface of the infrared absorption filter 311, and in a case of being used in an interior wall of a device of an infrared sensor, the internal reflection and/or the unintended incidence of light on the light-receiving part can be prevented and thus sensitivity can be improved.

According to the infrared sensor, image information can be simultaneously taken in, and thus motion sensing or the like by which a subject whose movement is to be detected is recognized can be carried out. In addition, according to the infrared sensor, distance information can be obtained, and thus images including 3D information and the like can also be captured. Furthermore, the infrared sensor can also be used as a biometric authentication sensor.

Next, a solid-state imaging device to which the above-described infrared sensor is applied will be described.

The solid-state imaging device has a lens optical system, a solid-state imaging element, an infrared light emitting diode, and the like. Furthermore, regarding each of the configurations of the solid-state imaging device, reference can be made to paragraphs 0032 to 0036 of JP2011-233983A, the contents of which are incorporated into the specification of the present application.

[Headlight Unit]

It is also preferable that the cured film according to the embodiment of the present invention is included, as the light shielding film, in a headlight unit for a vehicle such as an automobile. The cured film according to the embodiment of the present invention, which is included in the headlight unit as the light shielding film, is preferably formed in a patterned manner to shield at least a part of light emitted from a light source.

The headlight unit according to the embodiment will be described with reference to FIG. 4 and FIG. 5. FIG. 4 is a schematic view illustrating an example of the configuration of the headlight unit, and FIG. 5 is a schematic perspective view illustrating an example of the configuration of a light shielding unit of the headlight unit.

As illustrated in FIG. 4, a headlight unit 10 includes a light source 12, a light shielding unit 14, and a lens 16, and the light source 12, the light shielding unit 14, and the lens 16 are arranged in this order.

As illustrated in FIG. 5, the light shielding unit 14 has a base body 20 and a light shielding film 22.

In the light shielding film 22, a patterned opening portion 23 for applying light emitted from the light source 12 into a specific shape is formed. A light distribution pattern emitted from the lens 16 is determined by the shape of the opening portion 23 of the light shielding film 22. The lens 16 projects light L from the light source 12, which has passed through the light shielding unit 14. In a case where a specific light distribution pattern can be radiated from the light source 12, the lens 16 is not necessarily required. The lens 16 is appropriately determined according to an irradiation distance and an irradiation range of the light L.

In addition, the configuration of the base body 20 is not particularly limited as long as the substrate can hold the light shielding film 22. However, the base body 20 is preferably not deformed by the heat of the light source 12, and it is, for example, made of glass.

An example of the light distribution pattern is illustrated in FIG. 5, which is not limited thereto.

In addition, the number of the light sources 12 is also not limited to one, and the light sources may be arranged, for example, in a row or in a matrix. In a case where a plurality of light sources are provided, for example, one light shielding unit 14 may be provided for one light source 12. In this case, the respective light shielding film 22 of a plurality of light shielding units 14 may all have the same pattern or may have different patterns.

The light distribution pattern based on the pattern of the light shielding film 22 will be described.

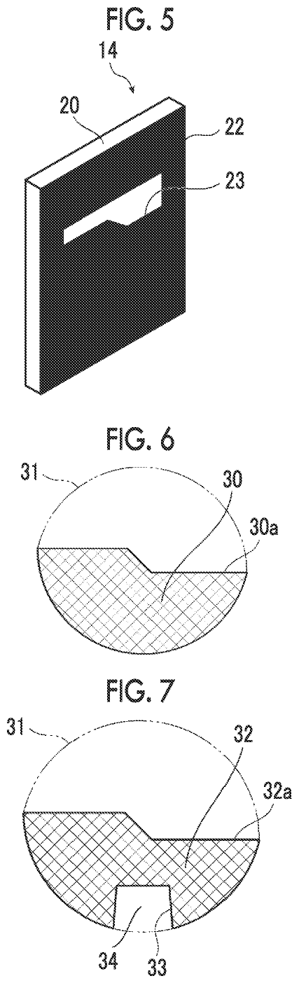

FIG. 6 is a schematic view illustrating an example of the light distribution pattern formed by the headlight unit, and FIG. 7 is a schematic view illustrating another example of the light distribution pattern formed by the headlight unit. It is noted that a light distribution pattern 30 illustrated in FIG. 6 and a light distribution pattern 32 illustrated in FIG. 7 both indicate a region irradiated with light. Further, a region 31 illustrated in FIG. 6 and a region 31 illustrated in FIG. 7 both indicate an irradiation region irradiated by the light source 12 (see FIG. 4) in a case where the light shielding film 22 is not provided.

Due to the pattern of the light shielding film 22, the intensity of light is sharply reduced at an edge 30a, for example, as in the light distribution pattern 30 illustrated in FIG. 6. The light distribution pattern 30 illustrated in FIG. 6 is, for example, a pattern in which light is not flashed at an oncoming vehicle in a case of left-side traveling.

In addition, as in the light distribution pattern 32 illustrated in FIG. 7, a pattern in which a part of the light distribution pattern 30 illustrated in FIG. 6 is notched can also be used. Also in this case, similar to the light distribution pattern 30 illustrated in FIG. 6, the intensity of light is sharply reduced at an edge 32a, and the pattern is, for example, a pattern in which light is not flashed at an oncoming vehicle in a case of left-side traveling. Further, the intensity of light is sharply reduced even at a notched portion 33. Therefore, in a region 34 corresponding to the notched portion 33, a mark indicating a state where the road is curved, inclined upward, inclined downward, or the like can be displayed. This makes it possible to improve safety during night-time traveling.

It is noted that the light shielding unit 14 is not limited to being fixedly disposed between the light source 12 and the lens 16, and a configuration in which the light shielding unit 14 is allowed to enter between the light source 12 and the lens 16, as necessary, by a driving mechanism (not shown) to obtain a specific light distribution pattern may be adopted.

In addition, in the light shielding unit 14, a shade member capable of shielding the light from the light source 12 may be formed. In this case, a configuration in which the shade member is allowed to enter between the light source 12 and the lens 16, as necessary, by the driving mechanism (not shown) to obtain a specific light distribution pattern may be adopted.

### EXAMPLES

Hereinbelow, the present invention will be described in more detail with reference to Examples. The materials, the amounts and proportions of the materials used, the details of treatments, the procedure of treatments, and the like shown in the following Examples can be appropriately modified as long as the gist of the present invention is maintained. Accordingly, the scope of the present invention will not be restrictively interpreted by the following Examples.

In the present example, in a case where the adding amount, the content, or the like of the component is simply indicated as “parts” or “%”, it means “parts by mass” or “% by mass” unless otherwise specified.

[Production of Composition]

Hereinafter, a production method for the composition (the coloring composition) will be described.

[Production of Resin]

First, the following raw materials were used to produce a resin (a specific resin and a comparative resin) by a method described later.

<Raw Material Used in Production of Resin>

(Solvent)

The following solvents were used in the production of the resin.
PGMEA: Propylene glycol monomethyl ether acetate
Cyclopentanone

(Monomer)

The following monomers were used in the production of the resin.

Monomer 1
A-1: ARONIX M-5300, ω-carboxy-polycaprolactone monoacrylate (manufactured by Toagosei Co., Ltd.)
A-2: Light Ester HO-MS, 2-methacryloyloxyethyl succinic acid (manufactured by Kyoeisha Chemical Co., Ltd.)
A-3: Acrylic acid
A-4: PCEA, β-carboxyethyl acrylate (manufactured by DAICEL-ALLNEX Ltd.)
A-5: Vinyl benzoic acid (manufactured by Tokyo Chemical Industry Co., Ltd.)
A-6: Methacryloyloxyethyl phthalic acid (manufactured by SHIN-NAKAMURA CHEMICAL Co., Ltd.)
A-7: Methacrylate
A-8: Vinyl sulfonic acid (manufactured by Tokyo Chemical Industry Co., Ltd.)
A-9: Vinyl phosphonic acid (manufactured by Tokyo Chemical Industry Co., Ltd.)
A-10: 4-(4-(acrylolyloxy)butoxy)benzoic acid

Monomer 2
B-1: Synthetic product according to the following synthesis example B1
B-2: Synthetic product according to the following synthesis example B2
B-3: Blemmer PSE1300 (manufactured by NOF Corporation), stearoxypolyethylene glycol monomethacrylate
B-4: Blemmer 75 ANEP-600 (manufactured by NOF Corporation), nonylphenoxy(ethylene glycol-polypropylene glycol)monoacrylate
B-5: Blemmer 50 POEP800B (manufactured by NOF Corporation), octoxy polyethylene glycol-polypropylene glycol monomethacrylate

### Synthesis Example B1 (synthesis of B-1)

A synthesis method for a monomer B-1 (also simply referred to as “B-1”) containing a constitutional unit consisting of an oxyalkylene carbonyl group will be described below.

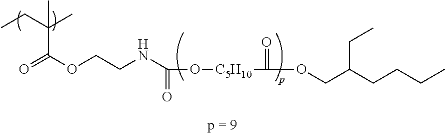

E-caprolactone (1,256.62 parts) and 2-ethyl-1-hexanol (143.38 parts) were introduced into the flask to obtain a mixture. Next, the mixture was stirred while blowing nitrogen.

Next, monobutyltin oxide (0.63 parts) was added to the mixture, and the obtained mixture was heated to 90° C. After 6 hours, 1H-nuclear magnetic resonance (NMR) was used to confirm that a signal derived from 2-ethyl-1-hexanol in the mixture disappeared, and then the mixture was heated to 110° C. The polymerization reaction was continued at 110° C. for 2 hours under nitrogen, and then it was confirmed that a signal derived from ε-caprolactone disappeared by 1H-NMR, the temperature was subsequently decreased to 80° C., and 2,6-di-t-butyl-4-methylphenol (0.78 parts) was added to the mixture. Then, further, 2-methacryloyloxyethyl isocyanate (174.15 parts) was added dropwise to the obtained mixture over 30 minutes. One hour after the completion of the dropwise addition, the disappearance of a signal derived from 2-methacryloyloxyethyl isocyanate (MOI) was confirmed by 1H-NMR, and then propylene glycol monomethyl ether acetate (PGMEA) (1,575.57 parts) was added to the mixture to obtain a monomer (a macromonomer) B-1 solution having a concentration of 50% by mass. The structure of the monomer B-1 was confirmed by 1H-NMR. The weight-average molecular weight of the obtained monomer B-1 was 3,000.

### Synthesis Example B2 (Synthesis of B-2)

A synthesis method for a monomer B-2 (also simply referred to as “B-2”) containing a constitutional unit consisting of an oxyalkylene carbonyl group will be described below.

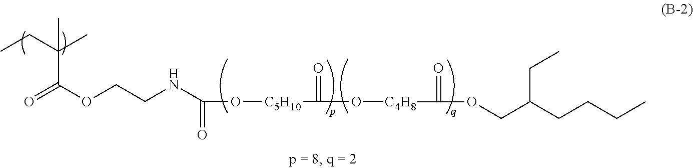

### Synthesis of B-2

ε-caprolactone (243.45 parts, corresponding to a cyclic compound), 6-valerolactone (60.86 parts, corresponding to a cyclic compound), and 2-ethyl-1-hexanol (35.69 parts, corresponding to a ring-opening polymerization initiator) were introduced in a flask to obtain a mixture. Next, the mixture was stirred while blowing nitrogen.

Next, monobutyltin oxide (0.156 parts) was added to the mixture, and the obtained mixture was heated to 90° C. After 6 hours, 1H-nuclear magnetic resonance (NMR) was used to confirm that a signal derived from 2-ethyl-1-hexanol in the mixture disappeared, and then the mixture was heated to 110° C. The polymerization reaction was continued at 110° C. for 12 hours under nitrogen, and then it was confirmed that signals derived from ε-caprolactone and 6-valerolactone disappeared by 1H-NMR, the temperature was subsequently decreased to 80° C., and 2,6-di-t-butyl-4-methylphenol (0.19 parts) was added to the mixture. Then, further, 2-methacryloyloxyethyl isocyanate (42.52 parts) was added dropwise to the obtained mixture over 30 minutes. One hour after the completion of the dropwise addition, the disappearance of a signal derived from 2-methacryloyloxyethyl isocyanate (MOI) was confirmed by 1H-NMR, and then propylene glycol monomethyl ether acetate (PGMEA) (382.87 parts) was added to the mixture to obtain a monomer (a macromonomer) B-2 solution having a concentration of 50% by mass. The structure of the monomer B-2 was confirmed by 1H-NMR. The weight-average molecular weight of the obtained monomer B-2 was 3,000.

Monomer 3
C-1: 4-vinyl phenol (manufactured by FUJIFILM Wako Pure Chemical Corporation)
C-2: 4-vinyl catechol
C-3: 4-hydroxyphenyl methacrylate (manufactured by Showa Denko K.K.)
C-4: 6-vinylnaphthalen-2-ol
C-5: 7-hydroxy-2-naphthyl acrylate

Monomer 4
D-1: Benzyl methacrylate (manufactured by Tokyo Chemical Industry Co., Ltd.)
D-2: 4-t-butylcyclohexyl methacrylate, Blemmer TBCHMA (manufactured by NOF Corporation)
D-3: 2-ethylhexyl methacrylate (manufactured by Tokyo Chemical Industry Co., Ltd.)
D-4: Acrylic Ester HO (2-hydroxyethyl methacrylate, manufactured by Mitsubishi Chemical Corporation)

(Reactive Compound)

The following reactive compounds were used in the production of the resin.
E-1: 4HBAGE, 4-hydroxybutyl acrylate glycidyl ether (manufactured by Nihon Kasei CO., LTD.)
E-2: 3,4-epoxycyclohexylmethyl acrylate (manufactured by Daicel Corporation)
E-3: glycidyl acrylate (manufactured by Tokyo Chemical Industry Co., Ltd.)
E-4: GMA, glycidyl methacrylate (manufactured by Tokyo Chemical Industry Co., Ltd.)
E-5: Allyl glycidyl ether (manufactured by Tokyo Chemical Industry Co., Ltd.)
E-6: Karenz AOI (2-isocyanatoethyl acrylate, manufactured by Showa Denko K.K.)
E-7: Karenz MOI (2-isocyanatoethyl methacrylate, manufactured by Showa Denko K.K.)

(Catalyst)

The following catalysts were used in the production of the resin.
F-1: Dimethyldodecylamine (manufactured by Tokyo Chemical Industry Co., Ltd.)
F-2: Dimethylbutylamine (manufactured by Tokyo Chemical Industry Co., Ltd.)
F-3: Dimethylbenzylamine (manufactured by Tokyo Chemical Industry Co., Ltd.)
F-4: Tetrabutylammonium bromide (manufactured by Tokyo Chemical Industry Co., Ltd.)
F-5: Dimethylaminoethylphenol (manufactured by Tokyo Chemical Industry Co., Ltd.)
F-6: Neostan U-600 (Bismuth tris(2-ethylhexanoate), manufactured by Nitto Kasei Co., Ltd.)

(Polymerization Inhibitor)

The following polymerization inhibitors were used in the production of the resin.
G-1: 2,2,6,6,-tetramethylpiperidin 1-oxyl (TEMPO)
G-2: 4-hydroxy-2,2,6,6,-tetramethylpiperidin 2-oxyl (4-hydroxy-TEMPO)
G-3: p-methoxyphenol

<Synthesis of Resin>

(Synthesis of Resin PA-1)

A monomer B-1 solution (24.0 parts (PGMEA: 12.0 parts, B-1: 12.0 parts)) having a concentration (a content of solid content) of 50% by mass, ω-carboxy-polycaprolactone monoacrylate (82.0 parts, A-1), 4-vinyl phenol (6.0 parts, C-1), and PGMEA (221.3 parts) were introduced into a three-necked flask to obtain a mixture.

The mixture was stirred while blowing nitrogen. Next, the mixture was warmed to 75° C. while allowing nitrogen to flow into the flask. Next, dodecyl mercaptan (1.88 parts) and then 2,2′-azobis(methyl 2-methylpropionate) (0.47 parts, hereinafter, also referred to as “V-601”) were added to the mixture to initiate the polymerization reaction.

After heating the mixture at 75° C. for 2 hours, V-601 (0.47 parts) was further added to the mixture. After 2 hours, V-601 (0.47 parts) was further added to the mixture, the temperature of the mixture was raised to 90° C., and stirring was carried out for 3 hours. The polymerization reaction was completed by the above operation.

After completion of the reaction, dimethyldodecylamine (3.12 parts, F-1) and 2,2,6,6,-tetramethylpiperidin 1-oxyl (TEMPO, 0.72 parts, G-1) were added thereto in air, and then 4-hydroxybutyl acrylate glycidyl ether (17.8 parts, E-1) was added dropwise thereto.

After completion of the dropwise addition, the reaction was continued in the air at 90° C. for 48 hours, and the completion of the reaction was confirmed by measuring the acid value, thereby obtaining a 34% by mass solution of a resin PA-1.

The obtained resin PA-1 had a weight-average molecular weight of 25,400 and an acid value of 105.8 mgKOH/mg.

(Synthesis of Resin PA-14)

A monomer B-1 solution (21.0 parts (PGMEA: 10.5 parts, B-1: 10.5 parts)) having a concentration (a content of solid content) of 50% by mass, methacrylic acid (25.0 parts, A-7), 2-hydroxyethyl methacrylate (16.0 parts, D-4), benzyl methacrylate (42.5 parts, D-1), 4-vinyl phenol (6.0 parts, C-1), and PGMEA (222.8 parts) was introduced into a three-necked flask to obtain a mixture.

The mixture was stirred while blowing nitrogen. Next, the mixture was warmed to 75° C. while allowing nitrogen to flow into the flask. Next, dodecyl mercaptan (2.39 parts) and then 2,2′-azobis(methyl 2-methylpropionate) (0.6 parts, hereinafter, also referred to as “V-601”) were added to the mixture to initiate the polymerization reaction.

After heating the mixture at 75° C. for 2 hours, V-601 (0.6 parts) was further added to the mixture. After 2 hours, V-601 (0.6 parts) was further added to the mixture, the temperature of the mixture was raised to 90° C., and stirring was carried out for 3 hours. The polymerization reaction was completed by the above operation.

After completion of the reaction, Neostan U-600 (manufactured by Nitto Kasei Co., Ltd.) (0.56 parts, F-6) and 2,2,6,6,-tetramethylpiperidin 1-oxyl (TEMPO, 0.60 parts, G-1) were added thereto in air, and then 2-isocyanatoethylacrylate (16.4 parts, E-6) was added dropwise thereto.

After completion of the dropwise addition, the reaction was continued in the air at 60° C. for 24 hours to obtain a 40% by mass solution of a resin PA-14.

The obtained resin PA-14 had a weight-average molecular weight of 18,600 and an acid value of 71.5 mgKOH/mg.

(Synthesis of Resin Other than Resins PA-1 and PA-14)

Resins PA-2 to PA-13, PA-15 to PA-17, and PZ-1 to PZ-2 were synthesized with reference to the synthesis method of the above-described resin.

The resins PA-1 to PA-17 correspond to the specific resins (resins having structural units A to C), and the resins PZ-1 and PZ-2 are comparative resins that do not correspond to the specific resins.

It is noted that in the synthesized polymer at the time of the completion of the polymerization reaction (at the time before the addition of the reactive compound) in the synthesis of each resin, the ratio of the content of the constitutional unit derived from each monomer to the total mass of the polymer was substantially the same as the mass ratio of each monomer added during the synthesis.

The following table shows the adding amount (% by mass) of each component in a case where the total adding amount of the monomer, reactive compound, catalyst, and polymerization inhibitor used in the synthesis of the resins PA-1 to PA-17 and PZ-1 to PZ-2 is set to 100% by mass.

It is noted that dodecyl mercaptan and V-601 were also added in a case of synthesizing any resins, and the adding amounts thereof were appropriately adjusted so that a resin to be obtained had the desired weight-average molecular weight shown in the table.

In the table, the column of “Amount (%)” indicates the adding amount (% by mass) of each component. It is noted that the values described in this column are rounded values, and thus it is permissible that the total “amount (%)” of each of components of each resin does not reach 100%.

In the table, the column of “C═C value (mmol/g)” indicates the ethylenically unsaturated bond value of each resin. The C═C value was measured by the method described in the specification.

The column of “Salt structure type crosslinkable unit ratio (mol %)” indicates the content (mol %) of the constitutional unit represented by Formula 6 with respect to 100 mol % of the constitutional unit A in each resin. The “salt structure type crosslinkable unit ratio (mol %)” was obtained as a calculated value. Specifically, it was confirmed that the tertiary amine catalysts (F-1 to F-3 and F-5) used in the synthesis of the resin were not detected in the resin solution after the synthesis of the resin was completed, whereby it was determined that the tertiary amine catalyst was incorporated into the resin and became a constitutional element of the salt structure crosslinkable unit (the constitutional unit represented by Formula 6). That is, assuming that the same number of salt structure type crosslinkable units (constitutional units represented by Formula 6) as the number of molecules of the tertiary amine catalyst used in the synthesis of the resin was formed, the “salt structure type crosslinkable unit ratio (mol %)” was calculated.

The “acid value (mgKOH/g)” of each resin was determined by the neutralization titration using a sodium hydroxide aqueous solution. Specifically, it was determined by titrating a solution obtained by dissolving the obtained resin in a solvent with a sodium hydroxide aqueous solution using a potentiometry method to calculate the number of mmol of the acid contained in 1 g of the resin solid, and then multiplying this value by the molecular weight of KOH of 56.1.

The Mw (weight-average molecular weight) of each resin was calculated by a gel permeation chromatography (GPC) measurement under the following measurement conditions.
Apparatus: HLC-8220GPC (manufactured by Tosoh Corporation)
Detector: Differential refractometer (RI detector)
Pre-column TSK GUARD COLUMN MP (XL) 6 mm×40 mm (manufactured by Tosoh Corporation)
Sample side column: The following 4 columns are directly connected (all manufactured by Tosoh Corporation)
TSK-GEL Multipore-HXL-M 7.8 mm×300 mm
Reference side column: Same as sample side column
Constant-temperature tank temperature: 40° C.
Mobile phase: Tetrahydrofuran
Flow rate of sample side mobile phase: 1.0 mL/min
Flow rate of reference side mobile phase: 0.3 mL/min
Sample concentration: 0.1% by mass
Sample injection amount: 100 μL
Data collection time: 16 to 46 minutes after sample injection
Sampling pitch: 300 msec

It is noted that the weight-average molecular weight at the time when the macromonomer was synthesized was also determined by the same method.

TABLE 1

| | | | | | | | | | Reactive | | |
|---|---|---|---|---|---|---|---|---|---|---|---|
| | Monomer 1 | | Monomer 2 | | Monomer 3 | | Monomer 4 | | compound | | Catalyst |
| | | Amount | | Amount | | Amount | | Amount | | Amount | Kind |
| | Kind | (%) | Kind | (%) | Kind | (%) | Kind | (%) | Kind | (%) | (%) |
| PA-1 | A-1 | 67.4 | B-1 | 9.9 | C-1 | 4.9 | | | E-1 | 14.6 | F-1 |
| PA-2 | A-1 | 63.3 | B-2 | 10.0 | C-1 | 10.0 | | | E-1 | 13.7 | F-1 |
| PA-3 | A-2 | 51.0 | B-1 | 6.0 | C-1 | 5.1 | D-1 | 20.1 | E-1 | 13.2 | F-2 |
| | | | B-3 | 2.9 | | | | | | | |
| PA-4 | A-3 | 15.4 | B-1 | 9.0 | C-1 | 5.1 | D-1 | 55.9 | E-1 | 12.7 | F-3 |
| PA-5 | A-4 | 44.6 | B-2 | 8.0 | C-2 | 5.1 | D-2 | 26.7 | E-2 | 11.8 | F-1 |
| | | | B-4 | 1.0 | | | | | | | |
| PA-6 | A-5 | 32.2 | B-1 | 7.0 | C-3 | 5.4 | D-3 | 42.5 | E-3 | 8.3 | F-5 |
| | | | B-5 | 2.4 | | | | | | | |
| PA-7 | A-6 | 51.5 | B-1 | 9.0 | C-3 | 5.2 | D-3 | 20.2 | E-1 | 12.2 | F-3 |
| PA-8 | A-7 | 13.7 | B-2 | 9.0 | C-1 | 5.1 | D-1 | 52.8 | E-1 | 12.6 | F-2 |
| | A-8 | 5.1 | | | | | | | | | |
| PA-9 | A-7 | 15.8 | B-1 | 9.2 | C-1 | 5.3 | D-1 | 55.8 | E-4 | 10.3 | F-2 |
| | A-9 | 1.8 | | | | | | | | | |
| PA-10 | A-10 | 68.5 | B-1 | 10.0 | C-3 | 5.0 | | | E-1 | 14.0 | F-5 |
| PA-11 | A-1 | 66.5 | B-1 | 9.7 | C-1 | 4.6 | | | E-1 | 14.4 | F-4 |
| PA-12 | A-1 | 66.1 | B-1 | 9.7 | C-1 | 4.8 | | | E-1 | 14.0 | F-1 |
| PA-13 | A-3 | 16.4 | B-1 | 8.6 | C-1 | 4.9 | D-1 | 47.2 | E-1 | 13.2 | F-5 |
| | A-10 | 4.9 | | | | | | | | | |
| PA-14 | A-7 | 21.3 | B-1 | 8.9 | C-1 | 5.1 | D-1 | 36.2 | E-6 | 13.9 | F-6 |
| | | | | | | | D-4 | 13.6 | | | |
| PA-15 | A-7 | 21.0 | B-1 | 8.8 | C-1 | 5.0 | D-1 | 35.6 | E-7 | 15.1 | F-6 |
| | | | | | | | D-4 | 13.4 | | | |
| PA-16 | A-1 | 67.4 | B-1 | 9.9 | C-4 | 4.9 | | | E-1 | 14.6 | F-1 |
| PA-17 | A-1 | 67.4 | B-1 | 9.9 | C-5 | 4.9 | | | E-1 | 14.6 | F-1 |
| PZ-1 | A-7 | 15.0 | | | | | D-1 | 85.0 | | | |
| PZ-2 | A-7 | 17.7 | | | | | D-1 | 70.8 | E-5 | 7.5 | F-4 |

| | | | | | | | Salt structure |
|---|---|---|---|---|---|---|---|
| | | Polymerization | | | Acid | | type |
| | Catalyst | inhibitor | | | value | | crosslinkable |
| | Amount | | Amount | | (mgKOH/ | C═C value | unit ratio |
| | (%) | Kind | (%) | Mw | g) | (mmol/g) | (mol %) |
| PA-1 | 2.6 | G-1 | 0.6 | 25400 | 105.8 | 0.7 | 16.7 |
| PA-2 | 2.4 | G-2 | 0.6 | 29300 | 115.4 | 0.7 | 16.7 |
| PA-3 | 1.1 | G-1 | 0.6 | 21100 | 109.7 | 0.7 | 16.0 |
| PA-4 | 1.4 | G-1 | 0.6 | 18700 | 105.4 | 0.6 | 16.0 |
| PA-5 | 2.2 | G-2 | 0.6 | 19800 | 132.3 | 0.7 | 16.0 |
| PA-6 | 1.7 | G-3 | 0.6 | 23600 | 100.6 | 0.7 | 16.0 |
| PA-7 | 1.3 | G-1 | 0.6 | 32000 | 84.9 | 0.6 | 16.0 |
| PA-8 | 1.0 | G-1 | 0.6 | 18000 | 90.2 | 0.6 | 16.0 |
| PA-9 | 1.2 | G-1 | 0.6 | 16500 | 98.5 | 0.7 | 16.0 |
| PA-10 | 1.9 | G-2 | 0.6 | 24200 | 120.8 | 0.7 | 16.0 |
| PA-11 | 4.2 | G-1 | 0.6 | 17400 | 102.9 | 0.8 | 0.0 |
| PA-12 | 4.8 | G-1 | 0.6 | 22000 | 99.3 | 0.7 | 32.0 |
| PA-13 | 4.1 | G-1 | 0.6 | 19800 | 107.1 | 0.7 | 38.0 |
| PA-14 | 0.5 | G-1 | 0.5 | 18600 | 71.5 | 0.8 | 0.0 |
| PA-15 | 0.5 | G-2 | 0.5 | 19100 | 70.8 | 0.8 | 0.0 |
| PA-16 | 2.6 | G-1 | 0.6 | 22600 | 100.4 | 0.7 | 16.7 |
| PA-17 | 2.6 | G-1 | 0.6 | 19400 | 98.9 | 0.7 | 16.7 |
| PZ-1 | | | | 16600 | 94.3 | 0.0 | 0.0 |
| PZ-2 | 3.4 | G-1 | 0.6 | 15300 | 78.9 | 0.7 | 0.0 |

[Components of Composition]

Hereinafter, each component used in the preparation of the composition will be shown.

<Resin>

The resins PA-1 to PA-17 and PZ-1 to PZ-2, which were produced by the above-described method, were used in the production of the composition.

It is noted that in the production of the composition, the resin was used not as a solution containing the resin but as the resin itself (solid content).

<Another Resin>

As another resin, the following components were used in the production of the composition.
P1: A resin having the following structure. The numerical value added to the main chain is the molar ratio. Mw=11,000.
P2: A resin having the following structure. The numerical value added to the main chain is the molar ratio. Mw=30,000.
P3: Cardo resin V-259ME (manufactured by NIPPON STEEL & SUMITOMO METAL CORPORATION)

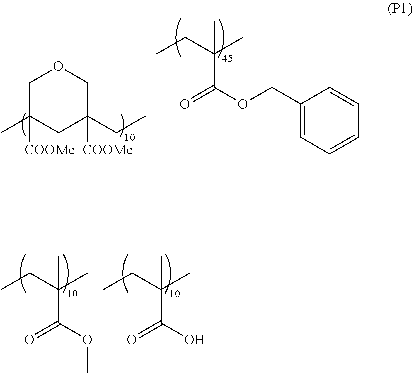

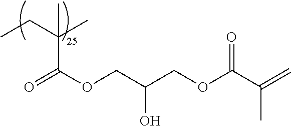

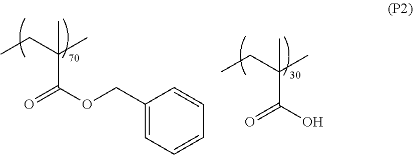

<Photopolymerization Initiator>

As the photopolymerization initiator, the following components were used in the production of the composition.
I1: IRGACURE OXE02 (manufactured by BASF SE)
I2: IRGACURE OXE03 (manufactured by BASF SE)
I3: IRGACURE OXE04 (manufactured by BASF SE)
14: NCI-831 (manufactured by ADEKA Corporation)
I5: Omnirad 1312 (manufactured by IGM Resins B.V)
I6: Omnirad 1314 (manufactured by IGM Resins B.V)
I7: Omnirad 1316 (manufactured by IGM Resins B.V)

<Polymerizable Compound>

As the polymerizable compound, the following components were used in the production of the composition.
M1: A compound represented by Formula (M) shown below, a+b+c=3
M2: A compound represented by Formula (M) shown below, a+b+c=4
M3: A compound represented by Formula (M3) shown below
M4: A compound (mixture) represented by Formula (M4) shown below

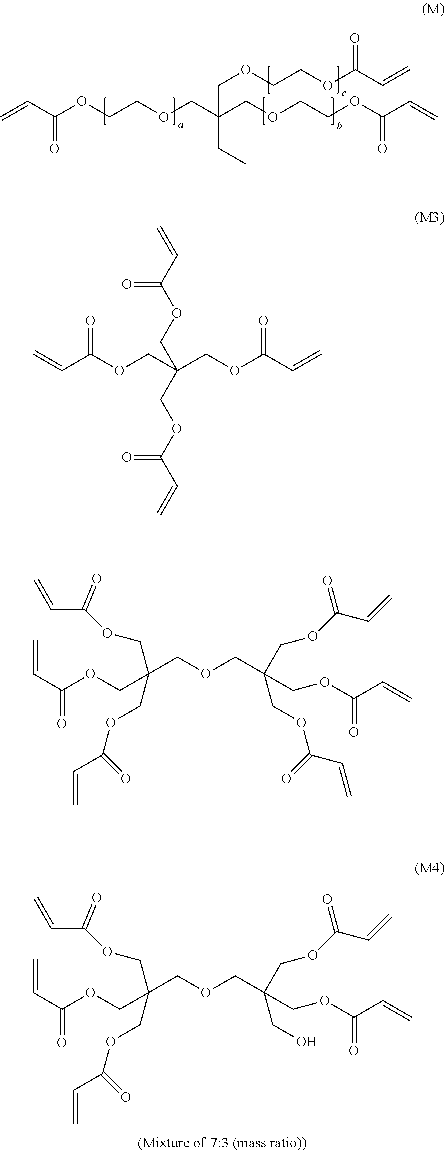

<Surfactant>

As the surfactant, the following components were used in the production of the composition.
H1: MEGAFACE F-781F (manufactured by DIC Corporation)
H2: KF-6001 (manufactured by Shin-Etsu Chemical Co., Ltd.)
H3: BYK-333 (manufactured by BYK Japan KK)

<Pigment>

As the pigment, the following components were used in the production of the composition.
TiON: Titanium oxynitride
TiN: Titanium nitride
ZrN: Zirconium nitride
ZrON: Zirconium oxynitride
CB: Carbon black
TiO₂: Titanium oxide
Irgaphor Black: Irgaphor Black S0100CF (manufactured by BASF SE)
PR254: C.I. Pigment Red 254
PR264: C.I. Pigment Red 264
PY139: C.I. Pigment Yellow 139
PY150: C.I. Pigment Yellow 150
PB15: 6: C.I. Pigment Blue 15: 6
PV23: C.I. Pigment Violet 23
PG58: C.I. Pigment Green 58
PG36: C.I. Pigment Green 36
PY185: C.I. Pigment Yellow 185
K1: A compound having the following structure

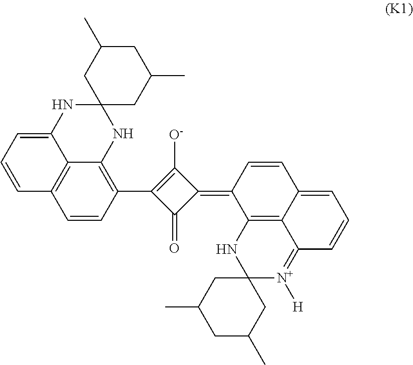 [SMILES: CC1CC(C)CC2(C1)Nc1cccc3ccc(C4=C([O-])/C(=c5\ccc6cccc7c6c5NC5(CC(C)CC(C)C5)[NH+]=7)C4=O)c(c13)N2]

<Dispersion Aid>

As the dispersion aid, the following components were used in the production of the composition.
B-1 and B-2: Compounds having the following structures.

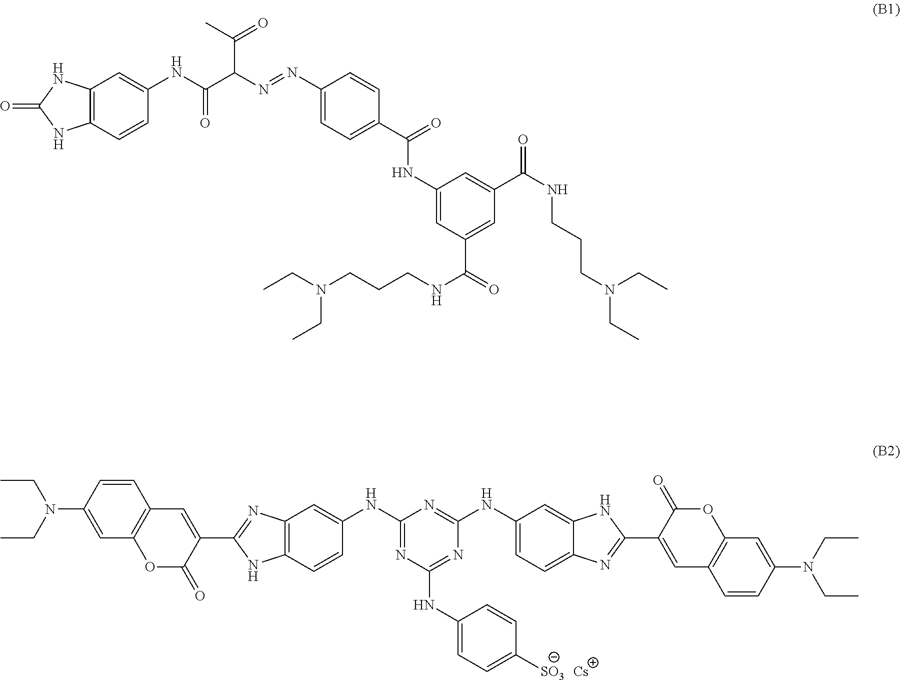

<Polymerization Inhibitor>

As the polymerization inhibitor, the following components were used in the production of the composition.
G-1: 2,2,6,6,-tetramethylpiperidin 1-oxyl (TEMPO)
G-2: 4-hydroxy-2,2,6,6,-tetramethylpiperidin 2-oxyl (4-hydroxy-TEMPO)

### Solution

As the solvent, cyclopentanone and/or propylene glycol monomethyl ether acetate (PGMEA) was used in the production of the composition.

[Production Method for Composition]

A composition was prepared by the method shown below.

That is, first, a part of the components to be contained in a composition was mixed to produce a pigment dispersion liquid, and then the obtained pigment dispersion liquid and other components were mixed to form a composition (a coloring composition).

<Production of Pigment Dispersion Liquid>

The components shown in the table below were mixed according to the mass ratios shown in the table, 230 parts by mass of zirconia beads having a diameter of 0.3 mm were subsequently added to the resultant mixture, a dispersion treatment was carried out for 5 hours using a paint shaker, and the beads were separated by filtration, whereby a pigment dispersion liquid was produced.

TABLE 2

| | Pigment | | Resin | | Polymerization inhibitor | | Solvent | |
|---|---|---|---|---|---|---|---|---|
| | | Part by | | Part by | | Part by | | Part by |
| | Kind | mass | Kind | mass | Kind | mass | Kind | mass |
| BK-1 | TiON | 26.0 | PA-1 | 7.87 | G-1 | 0.03 | Cyclopentanone | 63.0 |
| BK-2 | TiN | 26.0 | PA-1 | 7.87 | G-1 | 0.03 | Cyclopentanone | 63.0 |
| BK-3 | TiON/ZrN | 7.8/18.2 | PA-1 | 7.87 | G-2 | 0.03 | Cyclopentanone | 63.0 |
| BK-4 | TiON | 26.0 | PA-2 | 7.87 | G-2 | 0.03 | Cyclopentanone | 63.0 |
| BK-5 | TiON/ZrN | 7.8/18.2 | PA-2 | 7.87 | G-2 | 0.03 | Cyclopentanone | 63.0 |
| BK-6 | TiON | 26.0 | PA-3 | 7.87 | G-1 | 0.03 | Cyclopentanone | 63.0 |
| BK-7 | TiN/ZrON | 7.8/18.2 | PA-3 | 7.87 | G-1 | 0.03 | Cyclopentanone | 63.0 |
| BK-8 | TiON | 26.0 | PA-4 | 7.87 | G-1 | 0.03 | Cyclopentanone | 63.0 |
| BK-9 | CB | 26.0 | PA-4 | 7.87 | G-1 | 0.03 | Cyclopentanone | 63.0 |
| BK-10 | TiON | 26.0 | PA-5 | 7.87 | G-1 | 0.03 | Cyclopentanone | 63.0 |
| BK-11 | TiN | 26.0 | PA-6 | 7.87 | G-1 | 0.03 | Cyclopentanone | 63.0 |
| BK-12 | TiN/ZrN | 7.8/18.2 | PA-7 | 7.87 | G-1 | 0.03 | Cyclopentanone | 63.0 |
| BK-13 | TiON | 26.0 | PA-8 | 7.87 | G-1 | 0.03 | Cyclopentanone | 63.0 |
| BK-14 | TiON | 26.0 | PA-9 | 7.87 | G-1 | 0.03 | Cyclopentanone | 63.0 |
| BK-15 | TiON | 26.0 | PA-10 | 7.87 | G-2 | 0.03 | Cyclopentanone | 63.0 |
| BK-16 | TiON | 26.0 | PA-11 | 7.87 | G-1 | 0.03 | Cyclopentanone | 63.0 |
| BK-17 | TiON | 26.0 | PA-12 | 7.87 | G-1 | 0.03 | Cyclopentanone | 63.0 |
| BK-18 | TiON | 26.0 | PA-13 | 7.87 | G-1 | 0.03 | Cyclopentanone | 63.0 |
| BK-19 | TiON/ZrON | 7.8/18.2 | PA-14 | 7.87 | G-1 | 0.03 | Cyclopentanone | 63.0 |
| BK-20 | TiON | 26.0 | PA-15 | 7.87 | G-1 | 0.03 | Cyclopentanone | 63.0 |
| BK-21 | CB | 26.0 | PZ-1 | 7.87 | G-1 | 0.03 | Cyclopentanone | 63.0 |
| BK-22 | CB | 26.0 | PZ-2 | 7.87 | G-1 | 0.03 | Cyclopentanone | 63.0 |

TABLE 3

| | | | | | | | Polymerization | | | |
|---|---|---|---|---|---|---|---|---|---|---|
| | Pigment | | Dispersion aid | | Resin | | inhibitor | | Solvent | |
| (Continued | | Part by | | Part by | | Part by | | Part by | | Part by |
| from Table 2) | Kind | mass | Kind | mass | Kind | mass | Kind | mass | Kind | mass |
| BK-23 | TiON | 26.0 | | | PA-16 | 7.87 | G-1 | 0.03 | PGMEA | 63.0 |
| BK-24 | TiON | 26.0 | | | PA-17 | 7.87 | G-2 | 0.03 | Cyclopentanone | 63.0 |
| R-1 | PR254 | 12.0 | B1 | 1.4 | PA-1 | 4.20 | G-1 | 0.01 | PGMEA | 82.4 |
| R-2 | PR254 | 12.0 | B1 | 1.4 | PA-1 | 4.20 | G-1 | 0.01 | PGMEA | 82.4 |
| R-3 | PR254/ | 8.3/3.7 | B1 | 2.3 | PA-1 | 4.40 | G-1 | 0.01 | PGMEA | 81.3 |
| | PY139 | | | | | | | | | |
| R-4 | PR264 | 12.0 | B1 | 1.4 | PA-1 | 4.20 | G-1 | 0.01 | PGMEA/ | 41.2/ |
| | | | | | | | | | Cyclopentanone | 41.2 |
| R-5 | PR254 | 12.0 | B2 | 1.4 | PA-1 | 4.20 | G-1 | 0.01 | PGMEA | 82.4 |
| Y-1 | PY139 | 11.0 | B1 | 1.6 | PA-1 | 4.40 | G-1 | 0.01 | PGMEA | 83.0 |
| Y-2 | PY150 | 11.0 | B1 | 1.6 | PA-3 | 4.40 | G-1 | 0.01 | Cyclopentanone | 83.0 |
| B-1 | PB15:6/ | 10.0/ | | | PA-1 | 5.38 | G-1 | 0.01 | PGMEA | 83.0 |
| | PV23 | 2.6 | | | | | | | | |
| G-1 | PG58/ | 9.2/ | B1 | 1.2 | PA-1 | 4.95 | G-1 | 0.01 | PGMEA | 82.3 |
| | PY185 | 2.3 | | | | | | | | |
| G-2 | PG58/ | 6.2/ | B1 | 1.2 | PA-1 | 4.95 | G-1 | 0.01 | PGMEA | 82.3 |
| | PG36/ | 3.0/ | | | | | | | | |
| | PY185 | 2.3 | | | | | | | | |
| IR-1 | K1 | 11.0 | B1 | 1.6 | PA-1 | 6.00 | G-1 | 0.01 | PGMEA | 81.4 |
| BK-25 | Irgaphor | 26.0 | | | PA-1 | 7.87 | G-1 | 0.03 | PGMEA/ | 31.5/ |
| | Black | | | | | | | | Cyclopentanone | 31.5 |
| W-1 | TiO2 | 38.4 | | | PA-1 | 11.60 | G-1 | 0.03 | PGMEA | 50.0 |

<Preparation of Composition>

The pigment dispersion liquid produced by the above-described method was mixed with additional components to form a composition.

That is, the components shown in the table below were mixed according to the mass ratio shown in the table to prepare a composition (a coloring composition).

In the table, the column of “Pigment concentration in solid content (% by mass)” indicates the content (% by mass) of the pigment in each composition with respect to the total solid content contained in the composition.

TABLE 4

| | | | | | | | | | | | | | Pigment |
|---|---|---|---|---|---|---|---|---|---|---|---|---|---|
| | | | | | | | | | | | | | concen- |
| | Pigment dispersion | | | | Photopolymerization | | Polymerizable | | | | | | tration |
| | liquid | | Another resin | | initiator | | compound | | Surfactant | | Solvent | | in solid |
| | | Part by | | Part by | | Part by | | Part by | | Part by | | Part by | content |
| | Kind | mass | Kind | mass | Kind | mass | Kind | mass | Kind | mass | Kind | mass | (% by mass) |
| Example 1 | BK-1 | 72.3 | P1 | 0.4 | I2 | 2.0 | M1 | 4.8 | H1 | 0.02 | Cyclopentanone | 13.9 | 60 |
| Example 2 | BK-1 | 58.4 | P1 | 5.4 | I1 | 1.4 | M2 | 6.7 | H1 | 0.02 | Cyclopentanone | 17.1 | 46 |
| Example 3 | BK-2 | 72.3 | P1 | 0.4 | I2 | 2.0 | M1 | 4.8 | H1 | 0.02 | Cyclopentanone | 13.9 | 60 |
| Example 4 | BK-3 | 72.3 | P1 | 0.4 | I2 | 2.0 | M1 | 4.8 | H1 | 0.02 | Cyclopentanone | 13.9 | 60 |
| Example 5 | BK-4 | 72.3 | P2 | 0.4 | I3 | 2.0 | M4 | 4.8 | H1 | 0.02 | Cyclopentanone | 13.9 | 60 |
| Example 6 | BK-5 | 72.3 | P2 | 0.4 | I3 | 2.0 | M4 | 4.8 | H1 | 0.02 | Cyclopentanone | 13.9 | 60 |
| Example 7 | BK-6 | 72.3 | P1 | 0.4 | I2 | 2.0 | M1 | 4.8 | H1 | 0.02 | Cyclopentanone | 13.9 | 60 |
| Example 8 | BK-7 | 72.3 | P1 | 0.4 | I2 | 2.0 | M1 | 4.8 | H1 | 0.02 | Cyclopentanone | 13.9 | 60 |
| Example 9 | BK-8 | 72.3 | P2 | 0.4 | I2 | 2.0 | M3 | 4.8 | H1 | 0.02 | Cyclopentanone | 13.9 | 60 |
| Example 10 | BK-9 | 72.3 | P2 | 0.4 | I2 | 2.0 | M3 | 4.8 | H1 | 0.02 | Cyclopentanone | 13.9 | 60 |
| Example 11 | BK-10 | 72.3 | P2 | 0.4 | I1 | 2.0 | M1 | 4.8 | H1 | 0.02 | Cyclopentanone | 13.9 | 60 |
| Example 12 | BK-11 | 72.3 | P1 | 0.4 | I3 | 2.0 | M2 | 4.8 | H1 | 0.02 | Cyclopentanone | 13.9 | 60 |
| Example 13 | BK-12 | 72.3 | P2 | 0.4 | I3 | 2.0 | M1 | 4.8 | H1 | 0.02 | Cyclopentanone | 13.9 | 60 |
| Example 14 | BK-13 | 72.3 | P1 | 0.4 | I1 | 2.0 | M1 | 4.8 | H1 | 0.02 | Cyclopentanone | 13.9 | 60 |
| Example 15 | BK-14 | 72.3 | P1 | 0.4 | I1 | 2.0 | M4 | 4.8 | H1 | 0.02 | Cyclopentanone | 13.9 | 60 |
| Example 16 | BK-15 | 72.3 | P1 | 0.4 | I2 | 2.0 | M4 | 4.8 | H1 | 0.02 | Cyclopentanone | 13.9 | 60 |
| Example 17 | BK-16 | 72.3 | P2 | 0.4 | I3 | 2.0 | M2 | 4.8 | H1 | 0.02 | Cyclopentanone | 13.9 | 60 |
| Example 18 | BK-17 | 72.3 | P1 | 0.4 | I2 | 2.0 | M3 | 4.8 | H1 | 0.02 | Cyclopentanone | 13.9 | 60 |
| Example 19 | BK-18 | 72.3 | P1 | 0.4 | I2 | 2.0 | M3 | 4.8 | H1 | 0.02 | Cyclopentanone | 13.9 | 60 |
| Example 20 | BK-19 | 72.3 | P1 | 0.4 | I1 | 2.0 | M1 | 4.8 | H1 | 0.02 | Cyclopentanone | 13.9 | 60 |
| Example 21 | BK-20 | 72.3 | P2 | 0.4 | I1 | 2.0 | M2 | 4.8 | H1 | 0.02 | Cyclopentanone | 13.9 | 60 |
| Comparative | BK-21 | 72.3 | P1 | 0.4 | I1 | 2.0 | M1 | 4.8 | H1 | 0.02 | Cyclopentanone | 13.9 | 60 |
| Example 1 | | | | | | | | | | | | | |
| Comparative | BK-22 | 72.3 | P1 | 0.4 | I1 | 2.0 | M1 | 4.8 | H1 | 0.02 | Cyclopentanone | 13.9 | 60 |
| Example 2 | | | | | | | | | | | | | |

TABLE 5

| | | | | | | | | | | | | | Pigment |
|---|---|---|---|---|---|---|---|---|---|---|---|---|---|
| | Pigment | | | | Photopoly- | | | | | | | | concen- |
| | dispersion | | | | merization | | Polymerizable | | | | | | tration |
| (Continued | liquid | | Another resin | | initiator | | compound | | Surfactant | | Solvent | | in solid |
| from | | Part by | Kind | Part by | | Part by | | Part by | | Part by | | Part by | content |
| Table 4) | Kind | mass | mass | mass | Kind | mass | Kind | mass | Kind | mass | Kind | mass | (% by mass) |
| Example 22 | BK-23 | 72.3 | P1 | 0.4 | I2 | 2.0 | M1 | 4.8 | H1 | 0.02 | Cyclopentanone | 13.9 | 60 |
| Example 23 | BK-24 | 72.3 | P3 | 0.4 | I2 | 2.0 | M1 | 4.8 | H1 | 0.02 | Cyclopentanone | 13.9 | 60 |
| Example 24 | BK-1 | 72.3 | P1 | 0.4 | I1/I2 | 0.5/1.5 | M1 | 4.8 | H1 | 0.02 | Cyclopentanone | 13.9 | 60 |
| Example 25 | BK-3 | 72.3 | P1 | 0.4 | I2 | 2.0 | M2/M4 | 1.8/3.0 | H1 | 0.02 | Cyclopentanone | 13.9 | 60 |
| Example 26 | BK-6 | 72.3 | P1 | 0.4 | I2 | 2.0 | M2/M4 | 1.8/3.0 | H1 | 0.02 | Cyclopentanone/ | 7.0/7.0 | 60 |
| | | | | | | | | | | | PGMEA | | |
| Example 27 | BK-1 | 72.3 | P1 | 0.4 | I1/I2 | 0.5/1.5 | M1 | 4.8 | H1 | 0.02 | PGMEA | 13.9 | 60 |
| Example 28 | BK-1 | 72.3 | P1 | 0.4 | I1 | 2.0 | M4 | 4.8 | H2 | 0.02 | PGMEA | 13.9 | 60 |
| Example 29 | BK-1 | 24.0 | P1 | 12.4 | I1 | 1.4 | M4 | 9.8 | H2 | 0.02 | PGMEA | 43.9 | 20 |
| Example 30 | BK-1/R-1 | 72.3/0.5 | P1 | 0.4 | I2 | 2.0 | M1 | 4.8 | H1 | 0.02 | Cyclopentanone | 13.9 | 60 |
| Example 31 | BK-1/R-2 | 72.3/0.5 | P1 | 0.4 | I2 | 2.0 | M1 | 4.8 | H1 | 0.02 | Cyclopentanone | 13.9 | 60 |
| Example 32 | BK-1/R-3 | 72.3/0.5 | P1 | 0.4 | I1/I2 | 0.5/1.5 | M1 | 4.8 | H3 | 0.02 | PGMEA | 13.9 | 60 |
| Example 33 | BK-2/R-4 | 72.3/0.5 | P1 | 0.4 | I2 | 2.0 | M1 | 4.8 | H1 | 0.02 | Cyclopentanone | 13.9 | 60 |
| Example 34 | BK-11/R-5 | 72.3/0.5 | P1 | 0.4 | I4 | 2.0 | M1 | 4.8 | H1 | 0.02 | Cyclopentanone | 13.9 | 60 |
| Example 35 | BK-1/Y-1 | 72.3/0.5 | P1 | 0.4 | I2 | 2.0 | M2/M4 | 1.8/3.0 | H2 | 0.02 | Cyclopentanone | 13.9 | 60 |
| Example 36 | BK-7/Y-2 | 72.3/0.5 | P1 | 0.4 | I2/I5 | 1.5/0.5 | M1 | 4.8 | H1 | 0.02 | Cyclopentanone | 13.9 | 60 |
| Example 37 | BK-11/B-1 | 72.3/0.5 | P1 | 0.4 | I2 | 2.0 | M1 | 4.8 | H1 | 0.02 | Cyclopentanone/ | 7.0/7.0 | 60 |
| | | | | | | | | | | | PGMEA | | |
| Example 38 | BK-1/G-1 | 72.3/0.5 | P1 | 0.4 | I1/I2 | 0.5/1.5 | M1 | 4.8 | H3 | 0.02 | Cyclopentanone | 13.9 | 60 |
| Example 39 | BK-1/G-2 | 72.3/0.5 | P1 | 0.4 | I7 | 2.0 | M1 | 4.8 | H1 | 0.02 | Cyclopentanone | 13.9 | 60 |
| Example 40 | BK-1/IR-1 | 72.3/0.5 | PI | 0.4 | I2/I6 | 1.5/0.5 | M1 | 4.8 | H1 | 0.02 | PGMEA | 13.9 | 60 |
| Example 41 | BK-1/BK-25 | 72.3/0.5 | P1 | 0.4 | I2 | 2.0 | M1 | 4.8 | H1 | 0.02 | PGMEA | 13.9 | 60 |
| Example 42 | BK-1/W-1 | 72.3/0.5 | P1 | 0.4 | I2 | 2.0 | M1 | 4.8 | H1 | 0.02 | PGMEA | 13.9 | 60 |
| Comparative | BK-22 | 17.9 | P1 | 12.8 | I1 | 1.4 | M4 | 13.4 | H2 | 0.02 | Cyclopentanone | 48.8 | 14 |
| Example 3 | | | | | | | | | | | | | |

[Evaluation]

The composition of each example produced by the method described above was evaluated.

[Test]

A test method in the evaluation is shown below.

<Evaluation of Pattern Adhesiveness>

The composition was applied onto an 8-inch silicon wafer sprayed in advance with hexamethyldisilazane using a spin coater so that the film thickness after drying was 1.5 am, followed by being subjected to pre-baking at 100° C. for 120 seconds. As a result, a coated substrate which had a substrate (a silicon wafer) and, on the substrate, a film (a composition layer) consisting of the composition, was obtained.

An i-line stepper exposure device FPA-i5+(manufactured by CANON INC.) was used to expose the composition layer at a wavelength of 365 nm and an exposure amount of 50 to 1,700 mJ/cm², through a mask having a 1.1 μm square island pattern.

After the exposure, an alkali developer CD-2000 (manufactured by FUJIFILM Electronic Materials Co., Ltd.) was used to carry out development under the conditions of 25° C. and 40 seconds. Then, rinsing was carried out with running water for 30 seconds, and then spray drying was carried out to obtain a pattern (a patterned cured film).

The obtained pattern (the island patterns) having each of the various sizes was observed from above the pattern by using a scanning electron microscope (S-9220, manufactured by Hitachi, Ltd.), and the pattern size was measured. It is noted that the larger the exposure amount at the time of exposure was, the larger size the formed pattern had.

In addition, the adhesiveness was evaluated using an optical microscope. Based on the pattern size in a case where all the patterns were closely attached to each other, the adhesiveness of the patterns formed from each composition was evaluated according to the following five stages.

An evaluation 2 or higher is preferable, and evaluations 4 and 5 are evaluated to have excellent performance.
5: Adhesion occurs in a range of a 0.9 μm square or more and less than a 1.0 μm square.
4: Adhesion occurs in a range of a 1.0 μm square or more and less than a 1.05 μm square.
3: Adhesion occurs in a range of a 1.05 μm square or more and less than a 1.1 μm square.
2: Adhesion occurs in a range of a 1.1 μm square or more and less than a 1.2 μm square.
1: Adhesion does not occur unless being a case of a 1.2 μm square or more.

<Evaluation of Development Residue Suppressibility (Residue Suppressibility in Non-Exposed Portion)>

Each composition of each Example or Comparative Example was applied onto a glass substrate using spin coating and dried to form a composition layer having a film thickness of 1.0 μm. The spin coating condition was such that first, the rotation speed was set to 300 rotations per minute (rpm) for 5 seconds, and then set to 800 rpm for 20 seconds. The drying condition was set to 100° C. for 80 seconds.

An i-line stepper exposure device FPA-3000i5+(manufactured by CANON INC.) was used to irradiate the composition layer obtained as described above with light of a wavelength of 365 nm and an exposure amount of 10 to 1,600 mJ/cm², through a pattern mask having a line-and-space of 1 μm. Next, a developer of 60% by mass of CD-2000 (manufactured by FUJIFILM Electronic Materials Co., Ltd.) was used to develop the exposed composition layer under the conditions of 25° C. and 60 seconds to obtain a patterned cured film. Then, the patterned cured film was rinsed with running water for 20 seconds and then subjected to air drying.

The exposed cured film (a pattern having a line width of 1.0 μm) obtained at an exposure amount at which a pattern line width after development was 1.0 μm was heated together with the glass substrate in an oven at 220° C. for 1 hour. After heating the cured film, the number of residues present on the glass substrate in the region (non-exposed portion) not irradiated with the light in the exposure step was observed with a scanning electron microscope (SEM, magnification: 20,000 times) to evaluate the residue in the non-exposed portion. The evaluation was carried out according to the following criteria. It is noted that in practical use, an evaluation 3 or higher is preferable, and evaluations 4 and 5 are evaluated to have excellent performance.
5: A pattern was formed, and no residue was observed in the non-exposed portion.
4: A pattern was formed, and 1 to 3 residues were observed in a 1.0 μm square of the non-exposed portion.
3: A pattern was formed, and 4 to 10 residues were observed in a 1.0 μm square of the non-exposed portion.
2: A pattern was formed, and 11 or more residues were observed in a 1.0 μm square of the non-exposed portion.
1: A pattern was not formed due to poor development.

<Measurement of Optical Density>

Each composition was applied onto a transparent base material (a glass substrate) and then dried to form a composition layer having a film thickness of 1.5 μm after drying.

Next, using V-4100F (manufactured by Hitachi High-Tech Corporation), the optical density (OD) of the obtained composition layer with respect to light having a wavelength of 400 to 1,100 nm was evaluated with reference to the following criteria.

OD=−log₁₀(light transmittance (%)/100)
A: The minimum OD of light in a wavelength range of 400 to 1,100 nm is 3.0 or more.
B: The minimum OD of light in a wavelength range of 400 to 1,100 nm is 2.0 or more and less than 3.0.
C: The minimum OD of light in a wavelength range of 400 to 1,100 nm is 1.0 or more and less than 2.0.
D: The minimum OD of light in a wavelength range of 400 to 1,100 nm is less than 1.0.

[Result]

The results of the evaluation and the characteristics of the composition subjected to the test are shown in the table below.

In the table, the column of “Pigment” indicates the kind of the pigment contained in each composition and the content (% by mass) of the pigment with respect to the total solid content of the composition.

The column of “Resin” indicates the kind and characteristics of the specific resin or the comparative resin, which is contained in each resin.

TABLE 6

| | Pigment | | Resin | | | | | |
|---|---|---|---|---|---|---|---|---|
| | | Pigment | | | Salt structure | | | |
| | | concentration | | | type | Evaluation results | | |
| | | in solid | | | crosslinkable | | | Development |
| | | content | | | unit ratio | | | residue |
| | Kind | (% by mass) | Kind | Mw | (mol %) | OD | Adhesiveness | suppressibility |
| Example 1 | TiON | 60 | PA-1 | 25400 | 16.7 | A | 5 | 4 |
| Example 2 | TiON | 46 | PA-1 | 25400 | 16.7 | B | 5 | 5 |
| Example 3 | TiN | 60 | PA-1 | 25400 | 16.7 | A | 5 | 4 |
| Example 4 | TiON/ZrN | 60 | PA-1 | 25400 | 16.7 | A | 5 | 4 |
| Example 5 | TiON | 60 | PA-2 | 29300 | 16.7 | A | 5 | 4 |
| Example 6 | TiON/ZrN | 60 | PA-2 | 29300 | 16.7 | A | 5 | 4 |
| Example 7 | TiON | 60 | PA-3 | 21100 | 16.0 | A | 5 | 4 |
| Example 8 | TiN/ZrON | 60 | PA-3 | 21100 | 16.0 | A | 5 | 4 |
| Example 9 | TiON | 60 | PA-4 | 18700 | 16.0 | A | 5 | 4 |
| Example 10 | CB | 60 | PA-4 | 18700 | 16.0 | A | 2 | 4 |
| Example 11 | TiON | 60 | PA-5 | 19800 | 16.0 | A | 5 | 4 |
| Example 12 | TiN | 60 | PA-6 | 23600 | 16.0 | A | 5 | 4 |
| Example 13 | TiN/ZrN | 60 | PA-7 | 32000 | 16.0 | A | 5 | 4 |
| Example 14 | TiON | 60 | PA-8 | 18000 | 16.0 | A | 5 | 4 |
| Example 15 | TiON | 60 | PA-9 | 16500 | 16.0 | A | 4 | 4 |
| Example 16 | TiON | 60 | PA-10 | 24200 | 16.0 | A | 5 | 4 |
| Example 17 | TiON | 60 | PA-11 | 17400 | 0.0 | A | 5 | 3 |
| Example 18 | TiON | 60 | PA-12 | 22000 | 32.0 | A | 5 | 5 |
| Example 19 | TiON | 60 | PA-13 | 19800 | 38.0 | A | 5 | 5 |
| Example 20 | TiON/ZrON | 60 | PA-14 | 18600 | 0.0 | A | 5 | 3 |
| Example 21 | TiON | 60 | PA-15 | 19100 | 0.0 | A | 4 | 3 |
| Comparative | CB | 60 | PZ-1 | 16600 | 0.0 | A | 1 | 2 |
| Example 1 | | | | | | | | |
| Comparative | CB | 60 | PZ-2 | 15300 | 0.0 | A | 1 | 1 |
| Example 2 | | | | | | | | |

TABLE 7

| | Pigment | | | | | | |
|---|---|---|---|---|---|---|---|
| | | Pigment | Resin | | Evaluation results | | |
| | | concentration in | | Salt structure type | | | Development |
| (Continued | | solid content | | crosslinkable unit | | | residue |
| from Table 6) | Kind | (% by mass) | Kind | ratio (mol %) | OD | Adhesiveness | suppressibility |
| Example 22 | TiON | 60 | PA-16 | 16.7 | A | 5 | 4 |
| Example 23 | TiON | 60 | PA-17 | 16.7 | A | 5 | 4 |
| Example 24 | TiON | 60 | PA-1 | 16.7 | A | 5 | 4 |
| Example 25 | TiON/ZrN | 60 | PA-1 | 16.7 | A | 5 | 4 |
| Example 26 | TiON | 60 | PA-3 | 16.0 | A | 5 | 4 |
| Example 27 | TiON | 60 | PA-1 | 16.7 | A | 5 | 4 |
| Example 28 | TiON | 60 | PA-1 | 16.7 | A | 5 | 4 |
| Example 29 | TiON | 20 | PA-1 | 16.7 | C | 5 | 5 |
| Example 30 | TiON/PR254 | 60 | PA-1 | 16.7 | A | 5 | 4 |
| Example 31 | TiON/PR254 | 60 | PA-1 | 16.7 | A | 5 | 4 |
| Example 32 | TiON | 60 | PA-1 | 16.7 | A | 5 | 4 |
| | PR254/PY139 | | | | | | |
| Example 33 | TiN/PR264 | 60 | PA-1 | 16.7 | A | 5 | 4 |
| Example 34 | TiON/PR254 | 60 | PA-1 | 16.7 | A | 5 | 4 |
| Example 35 | TiON/PY139 | 60 | PA-1 | 16.7 | A | 5 | 4 |
| Example 36 | TiN/ZrON/ | 60 | PA-3 | 16.0 | A | 5 | 4 |
| | PY150 | | | | | | |
| Example 37 | TiON/PB15:6/ | 60 | PA-1 | 16.7 | A | 5 | 4 |
| | PV23 | | | | | | |
| Example 38 | TiON/PG58/ | 60 | PA-1 | 16.7 | A | 5 | 4 |
| | PY185 | | | | | | |
| Example 39 | TiON/PG58/ | 60 | PA-1 | 16.7 | A | 5 | 4 |
| | PG36/PY185 | | | | | | |
| Example 40 | TiON/K1 | 60 | PA-1 | 16.7 | A | 5 | 4 |
| Example 41 | TiON/Irgaphor | 60 | PA-1 | 16.7 | A | 5 | 4 |
| | Black | | | | | | |
| Example 42 | TiON/TiO₂ | 60 | PA-1 | 16.7 | A | 5 | 4 |
| Comparative | CB | 14 | PZ-2 | 0.0 | D | 3 | 3 |
| Example 3 | | | | | | | |

As shown in the table, it has been confirmed that the composition according to the embodiment of the present invention has excellent adhesiveness and makes it possible to form a pattern having a high color value.

In addition, it has been confirmed that the composition according to the embodiment of the present invention is also excellent in development residue suppressibility at the time when a pattern has been formed.

Among the above, it has been confirmed that a pattern having a higher color value can be obtained in a case where the content of the pigment in the composition is 30% by mass or more with respect to the total solid content.

It has been confirmed that a pattern having a still higher color value can be obtained in a case where the content of the pigment in the composition is 48% by mass or more with respect to the total solid content (see the results of Examples 2 and 29, and the like).

It has been confirmed that the adhesiveness of the formed pattern is more excellent in a case where the composition contains, as the pigment, titanium black (titanium nitride and titanium oxynitride), zirconium nitride, or zirconium oxynitride (see the results of Example 10 and the like).

It has been confirmed that in a case where the specific resin contains the constitutional unit represented by Formula 6, the development residue suppressibility and/or the adhesiveness of the formed pattern is more excellent (see the results of Examples 17, 20, and 21, and the like).

It has been confirmed that in a case where the content of the constitutional unit represented by Formula 6 in the specific resin was 20 mol % or more with respect to all the constitutional units A, the development residue suppressibility is still more excellent (see the results of Examples 18 and 19, and the like).

It has been confirmed that in a case where the specific resin contains the constitutional unit represented by Formula 6, the development residue suppressibility and/or the adhesiveness of the formed pattern is more excellent (see the results of Examples 17, 20, and 21, and the like).

It has been confirmed that in a case where the content of the constitutional unit represented by Formula 6 in the specific resin was 20 mol % or more with respect to all the constitutional units A, the development residue suppressibility is still more excellent (see the results of Examples 18 and 19, and the like).

It has been confirmed that in a case where R⁰ in the constitutional unit represented by Formula 1 is a hydrogen atom, the development residue suppressibility and/or the adhesiveness of the formed pattern is more excellent (see the comparison between Example 15 and Examples other than Example 15, in which TiON is used as a pigment and a specific resin in which the salt structure type crosslinkable unit ratio in the specific resin is 16.0 mol % is used).

### EXPLANATION OF REFERENCES

10: headlight unit
12: light source
14: light shielding unit
16: lens
20: base body
22: light shielding film
23: opening portion
30: light distribution pattern
30a: edge
31: region
32: light distribution pattern
32a: edge
33: notched portion
34: region
100: solid-state imaging device
101: solid-state imaging element
102: imaging unit
103: cover glass
104: spacer
105: laminated substrate
106: chip substrate
107: circuit board
108: electrode pad
109: external connection terminal
110: through-electrode
111: lens layer
112: lens material
113: support
114, 115: light shielding film
201: light-receiving element
202: color filter
203: micro lens
204: substrate
205b: blue pixel
205r: red pixel
205g: green pixel
205bm: black matrix
206: p-well layer
207: reading gate part
208: vertical electric charge transfer path
209: element separation region
210: gate insulating film
211: vertical electric charge transfer electrode
212: light shielding film
213, 214: insulating film
215: planarization film
300: infrared sensor
310: solid-state imaging element
311: infrared absorption filter
312: color filter
313: infrared transmitting filter
314: resin film
315: micro lens
316: planarization film

What is claimed is:

1. A coloring composition comprising:
a pigment;
a solvent; and
a resin having a constitutional unit A having a polymerizable group, a constitutional unit B having a phenolic hydroxyl group, and a constitutional unit C having an acidic group,
wherein a content of the pigment is 15% by mass or more with respect to a total solid content of the coloring composition.

2. The coloring composition according to claim 1,
wherein the constitutional unit A is a constitutional unit represented by Formula 1, 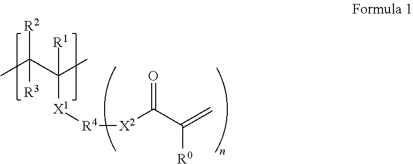
in Formula 1, R¹ to R³ each independently represent a hydrogen atom or an alkyl group,
X¹ represents —COO—, —CONR—, or an arylene group,
R represents a hydrogen atom, an alkyl group, or an aryl group,
R⁴ represents an (n+1)-valent linking group,
X² represents an oxygen atom or —NR^{A}—,
R^{A} represents a hydrogen atom, an alkyl group, or an aryl group,
R⁰ represents a hydrogen atom or an alkyl group, and
n represents an integer of 1 or more.

3. The coloring composition according to claim 1,
wherein the constitutional unit B is a constitutional unit represented by Formula 2, 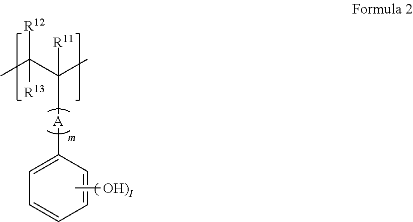
in Formula 2, R¹¹ to R¹³ each independently represent a hydrogen atom or an alkyl group,
A represents —COO—, —CONR′—, —COO—R″—, —CONR′—R″—, or an arylene group, R′ represents a hydrogen atom, an alkyl group, or an aryl group,
R″ represents a divalent linking group,
m represents 0 or 1, and
l represents an integer of 1 to 5.

4. The coloring composition according to claim 1,
wherein the constitutional unit A includes a constitutional unit represented by Formula 3, 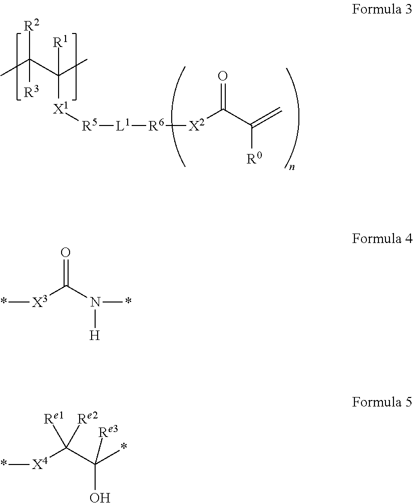
in Formula 3, R¹ to R³ each independently represent a hydrogen atom or an alkyl group,
X¹ represents —COO—, —CONR—, or an arylene group, where R represents a hydrogen atom, an alkyl group, or an aryl group,
R⁵ represents a divalent linking group,
L¹ represents a group represented by Formula 4 or Formula 5,
R⁶ represents an (n+1)-valent linking group,
X² represents an oxygen atom or —NR^{A}—,
R^{A} represents a hydrogen atom, an alkyl group, or an aryl group,
R⁰ represents a hydrogen atom or an alkyl group, and
n represents an integer of 1 or more,
in Formula 4, X³ represents an oxygen atom or —NH—, and
* represents a bonding position,
in Formula 5, X⁴ represents an oxygen atom or —COO—,
R^{e1} to R^{e3} each independently represent a hydrogen atom or an alkyl group,
at least two of R^{e1} to R^{e3} may be bonded to each other to form a ring, and
* represents a bonding position.

5. The coloring composition according to claim 1,
wherein the constitutional unit A includes a constitutional unit represented by Formula 6, 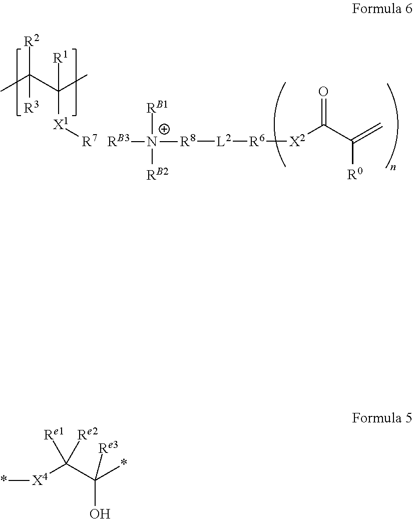
in Formula 6, R¹ to R³ each independently represent a hydrogen atom or an alkyl group,
X¹ represents —COO—, —CONR—, or an arylene group,
R represents a hydrogen atom, an alkyl group, or an aryl group,
R⁷ represents a structure including a group in which one proton is dissociated from an acid group,
R¹ represents a divalent linking group,
L² represents a group represented by Formula 5,
R⁶ represents an (n+1)-valent linking group,
X² represents an oxygen atom or —NR^{A}—,
R^{A} represents a hydrogen atom, an alkyl group, or an aryl group,
n represents an integer of 1 or more,
R^{B1} to R^{B3} each independently represent a hydrogen atom, an alkyl group, or an aryl group, and
R⁰ represents a hydrogen atom or an alkyl group,
in Formula 5, X⁴ represents an oxygen atom or —COO—,
R^{e1} to R^{e3} each independently represent a hydrogen atom or an alkyl group, and
at least two of R^{e1} to R^{e3} may be bonded to each other to form a ring.

6. The coloring composition according to claim 5,
wherein in the constitutional unit A, a content of the constitutional unit represented by Formula 6 is 10 mol % or more.

7. The coloring composition according to claim 1,
wherein the constitutional unit B is a constitutional unit represented by Formula 7, 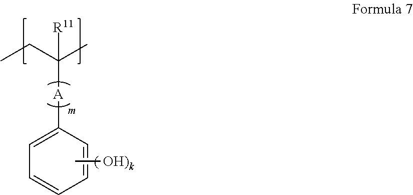
in Formula 7, R¹¹ represents a hydrogen atom or an alkyl group,
A represents —COO—, —CONR′—, —COO—R″—, —CONR′—R″—, or an arylene group,
R′ represents a hydrogen atom, an alkyl group, or an aryl group,
R″ represents a divalent linking group,
m represents 0 or 1, and
k represents an integer of 1 to 3.

8. The coloring composition according to claim 1,
wherein the constitutional unit B is one or more selected from the group consisting of a constitutional unit represented by Formula 8, a constitutional unit represented by Formula 9, and a constitutional unit represented by Formula 10

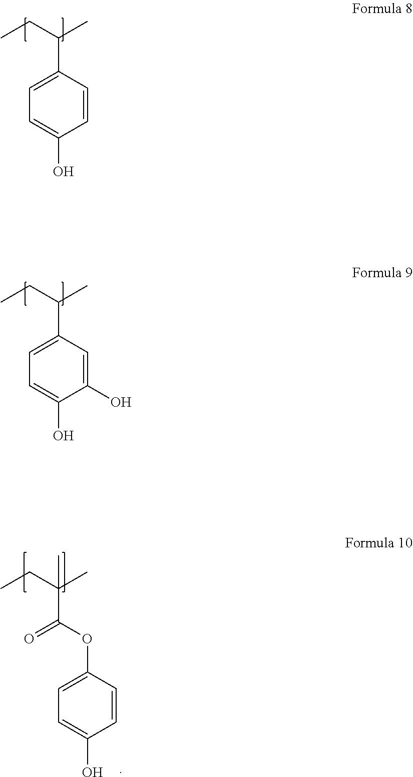

9. The coloring composition according to claim 1,
wherein the pigment includes one or more selected from the group consisting of carbon black, titanium black, zirconium nitride, and zirconium oxynitride.

10. The coloring composition according to claim 1,
wherein the resin further has a constitutional unit D represented by Formula D, 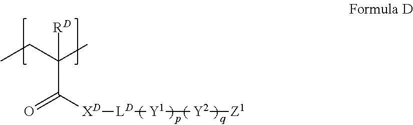
in Formula D, R^{D} represents a hydrogen atom or an alkyl group,
X^{D} represents an oxygen atom or —NR^{C}—,
R^{C} represents a hydrogen atom, an alkyl group, or an aryl group,
L^{D} represents a single bond or a divalent linking group,
Y¹ and Y² each independently represent an alkyleneoxy group or an alkylenecarbonyloxy group,
Z¹ represents an aliphatic hydrocarbon group having 1 to 20 carbon atoms or an aromatic hydrocarbon group having 6 to 20 carbon atoms, and
p and q each independently represent an integer of 0 or more,
provided that a value of p+q is 1 or more.

11. A cured film that is formed from the coloring composition according to claim 1.

12. A light shielding film comprising:
the cured film according to claim 11.

13. A color filter comprising:
the cured film according to claim 11.

14. An optical element comprising:
the cured film according to claim 11.

15. A solid-state imaging element comprising:
the cured film according to claim 11.

16. An infrared sensor comprising:
the cured film according to claim 11.

17. A headlight unit for a vehicle, comprising:
a light source; and
a light shielding unit that shields at least a part of light emitted from the light source,
wherein the light shielding unit includes the cured film according to claim 11.

18. The coloring composition according to claim 2,
wherein the constitutional unit B is a constitutional unit represented by Formula 2, 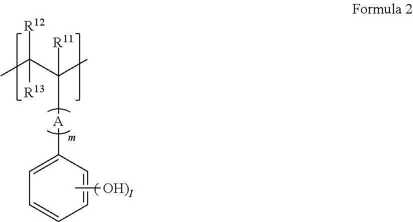
in Formula 2, R¹¹ to R¹³ each independently represent a hydrogen atom or an alkyl group,
A represents —COO—, —CONR′—, —COO—R″—, —CONR′—R″—, or an arylene group, R′ represents a hydrogen atom, an alkyl group, or an aryl group,
R″ represents a divalent linking group,
m represents 0 or 1, and
l represents an integer of 1 to 5.

19. The coloring composition according to claim 2,
wherein the constitutional unit A includes a constitutional unit represented by Formula 3, 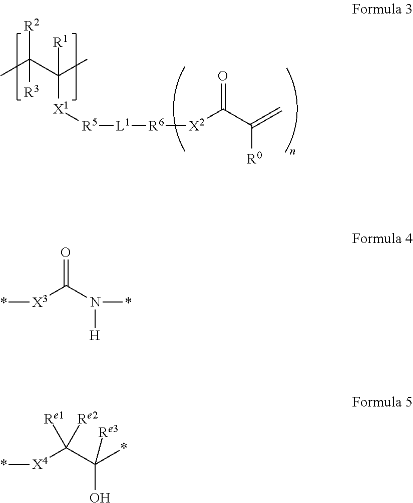
in Formula 3, R¹ to R³ each independently represent a hydrogen atom or an alkyl group,
X¹ represents —COO—, —CONR—, or an arylene group, where R represents a hydrogen atom, an alkyl group, or an aryl group,
R⁵ represents a divalent linking group,
L¹ represents a group represented by Formula 4 or Formula 5,
R⁶ represents an (n+1)-valent linking group,
X² represents an oxygen atom or —NR^{A}—,
R^{A} represents a hydrogen atom, an alkyl group, or an aryl group,
R⁰ represents a hydrogen atom or an alkyl group, and
n represents an integer of 1 or more,
in Formula 4, X³ represents an oxygen atom or —NH—, and
* represents a bonding position,
in Formula 5, X⁴ represents an oxygen atom or —COO—,
R^{e1} to R^{e3} each independently represent a hydrogen atom or an alkyl group,
at least two of R^{e1} to R^{e3} may be bonded to each other to form a ring, and
* represents a bonding position.

20. The coloring composition according to claim 2,
wherein the constitutional unit A includes a constitutional unit represented by Formula 6, 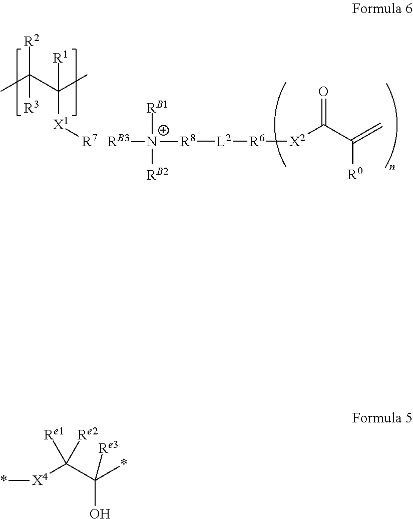
in Formula 6, R¹ to R³ each independently represent a hydrogen atom or an alkyl group,
X¹ represents —COO—, —CONR—, or an arylene group,
R represents a hydrogen atom, an alkyl group, or an aryl group,
R⁷ represents a structure including a group in which one proton is dissociated from an acid group,
R¹ represents a divalent linking group,
L² represents a group represented by Formula 5,
R⁶ represents an (n+1)-valent linking group,
X² represents an oxygen atom or —NR^{A}—,
R^{A} represents a hydrogen atom, an alkyl group, or an aryl group,
n represents an integer of 1 or more,
R^{B1} to R^{B3} each independently represent a hydrogen atom, an alkyl group, or an aryl group, and
R⁰ represents a hydrogen atom or an alkyl group,
in Formula 5, X⁴ represents an oxygen atom or —COO—,
R^{e1} to R^{e3} each independently represent a hydrogen atom or an alkyl group, and
at least two of R^{e1} to R^{e3} may be bonded to each other to form a ring.
